(19) United States
(12) Patent Application Publication
(10) Pub. No.: US 2013/0288404 A1
(43) Pub. Date: Oct. 31, 2013

(54) LIGHT EMITTING ELEMENT MANUFACTURING SYSTEM AND MANUFACTURING METHOD AND LIGHT EMITTING ELEMENT PACKAGE MANUFACTURING SYSTEM AND MANUFACTURING METHOD

(71) Applicant: Masaru Nonomura, Osaka (JP)

(72) Inventor: Masaru Nonomura, Osaka (JP)

(73) Assignee: PANASONIC CORPORATION, Osaka (JP)

(21) Appl. No.: 13/822,489

(22) PCT Filed: Aug. 31, 2012
(86) PCT No.: PCT/JP2012/005534

§ 371 Date: Mar. 12, 2013

(30) Foreign Application Priority Data
Sep. 16, 2011 (JP) 2011-202642
Sep. 16, 2011 (JP) 2011-202643
Sep. 16, 2011 (JP) 2011-202644

(51) Int. Cl. H01L 33/52

(52) U.S. Cl. CPC H01L 33/52
USPC 438/16; 118/696

(57) ABSTRACT

In manufacturing light emitting element packages by coating the top surfaces of LED elements with the resin containing the fluorescent substance, in a resin supplying operation of discharging to supply the resin onto the LED elements in a wafer state, the light emission characteristics of the light that the resin emits when excitation light from a light source part is irradiated onto a light-passing member on which the resin is test supplied for light emission characteristic measurement are measured, and the appropriate resin supply quantity is revised based on the result of the measurement and light emission characteristics prescribed beforehand, to derive an appropriate resin supply quantity of the resin which should be supplied to the LED elements for practical production.

### TECHNICAL FIELD

The invention relates to light emitting element manufacturing systems and manufacturing methods and light emitting element package manufacturing systems and manufacturing methods which manufacture light emitting elements made by coating LED elements with resin including a fluorescent substance and light emitting element packages which are constructed by mounting the light emitting elements on boards.

### BACKGROUND ART

In recent years, LEDs (light emitting diodes), which have superior characteristics such as less power consumption and long lifetime, are widely used as light sources of various illuminating devices. Because primary lights that the LED elements emit are limited to three colors, or red, green and blue at present, to obtain white light that is typically preferable in illumination, a method of obtaining white light by adding and mixing the above-mentioned three primary lights and a method of obtaining quasi-white light by combining a blue LED with fluorescent substance which emits yellow fluorescence whose color is complementary to blue are used. In recent years, the latter method comes to be used widely, and illuminating devices using LED packages which combine blue LEDs with YAG fluorescent substances are used for the backlights of liquid crystal panels and the like (for example, refer to a patent document 1).

In this patent document, after having mounted an LED element on the bottom surface of a concave mounting part whose side wall forms a reflecting surface, by forming a resin packing part by infusing silicone resin or epoxy resin, in which YAG-related fluorescent substance particles are dispersed, in the mounting part, the LED package is constructed. An example is described in which, for the purpose of equalizing the height of the resin packing part in the mounting part after the resin infusion, a surplus resin reservoir is formed to drain and collect surplus resin infused above a prescribed quantity from the mounting part. Thereby, even if the discharging quantity from a dispenser at the time of resin infusion varies, the resin packing part of a prescribed height, which has constant quantity of resin, is formed on the LED element.

### RELATED ART DOCUMENTS

### Patent Documents

Patent document 1: Japan Patent Publication No. 2007-66969

### SUMMARY OF THE INVENTION

### Problem to be Solved by the Invention

However, in the above-mentioned related art example, due to the variation of the light emission wavelength of the individual LED element, there is a problem that the light emission characteristics of the LED package as a finished product vary. That is, the LED element is subject to a manufacturing process in which a plurality of elements are collectively elaborated on a wafer. Due to various kinds of deviation factors in the manufacturing process, for example, the variation of the composition at the time of film formation in the wafer, it cannot be avoided that the light emission characteristics, such as light emission wavelength, of the LED element, which is obtained by dividing the wafer into individual pieces, vary. In the above-mentioned example, because the height of the resin packing part which covers the LED element is set uniformly, the variation of the light emission wavelength in the individual LED elements is just reflected by the variation of the light emission characteristic of the LED package as a finished product, and as a result, defective products, whose characteristics deviate from the quality tolerance range, are forced to increase.

Furthermore, in the traditional art including the above example, because the resin containing the fluorescent substance is coated after the individual LED element has been mounted onto a package board, the resin is so coated that the resin is discharged for each package board. Therefore, in the resin coating device a collection of package boards will become operation objects, so that while area productivity decreased since the device specific area increases, time is needed for the movement of a nozzle for resin coating, which results in a drop of the production efficiency.

Thus, the present invention is intended to provide light emitting element manufacturing systems and manufacturing methods and light emitting element package manufacturing systems and manufacturing methods which manufacture light emitting element packages which are constructed by mounting the light emitting elements on boards so that production yield and area productivity can be improved by equalizing light emission characteristics.

### Means for Solving Problem

A light emitting element manufacturing system of the present invention which manufactures light emitting elements by coating the top surfaces of LED elements with a resin containing a fluorescent substance, comprising a dicing device which divides a LED wafer in which a plurality of the LED elements are elaborated and attached onto a dicing sheet into individual LED elements; an element characteristic measuring part which individually measures the light emission characteristics of the individually divided LED elements in a state of being attached and held onto the dicing sheet to obtain element characteristic information indicating the light emission characteristics of the LED elements; a map data making part which makes map data which associate element position information indicating the position in the LED wafer of the divided LED element with the element characteristic information on the LED element for each of the LED wafers; a resin information supplying unit which supplies information that makes appropriate resin supply quantities of the resin to correspond to the element characteristic information to obtain LED elements which possess prescribed light emission characteristics as resin supply information; a resin supplying device which supplies the resin of appropriate resin supply quantities to obtain prescribed light emission characteristics to the LED elements in a wafer state of being attached onto the dicing sheet, based on the map data and the resin supply information; and a curing device which hardens the resin supplied to the LED elements; wherein the resin supplying device comprises a resin supplying part which discharges the resin in a variable supply quantity to supply to any supply object positions; a supply control part which controls the resin supplying part to make a supplying process for measurement in which the resin is test supplied onto a light-passing member for light emission characteristic measurement, and a supplying process for production in which the resin is supplied onto the LED elements for practical production to be performed; a light source part which emit excitation light to excite the fluorescent substance, a light-passing member carrying part on which a light-passing member on which the resin is test supplied in the supplying process for measurement is carried; a light emission characteristic measuring part which measures the light emission characteristics of the light that the resin, which is supplied onto the light-passing member, emits when the excitation light emitted from the light source part is irradiated to the resin; a supply quantity deriving processor which derives an appropriate resin supply quantity with which the resin should be supplied onto the LED elements for practical production by revising the appropriate resin supply quantity based on the measurement result of the light emission characteristic measuring part and light emission characteristics prescribed beforehand, and a production performing processor which orders the supply control part with the derived appropriate resin supply quantity to make the supplying process for production in which the appropriate resin supply quantity of the resin is supplied on the LED elements to be performed.

A light emitting element manufacturing method of the present invention which manufactures light emitting elements by coating the top surfaces of LED elements with resin containing a fluorescent substance, comprising a dicing step which divides a LED wafer in which a plurality of the LED elements are elaborated and attached onto a dicing sheet into individual LED elements; an element characteristic measuring step which individually measures the light emission characteristics of the individually divided LED elements in a state of being attached and held onto the dicing sheet to obtain element characteristic information indicating the light emission characteristics of the LED elements; a map data making step which makes map data which associate element position information indicating the position in the LED wafer of the divided LED element with the element characteristic information on the LED element for each of the LED wafers; a resin information acquiring step which acquires information that makes appropriate resin supply quantities of the resin to correspond to the element characteristic information to obtain light emitting elements which possess prescribed light emission characteristics as resin supply information, a resin supplying step which supplies the resin of appropriate resin supply quantities to obtain prescribed light emission characteristics to the LED elements in a wafer state of being attached onto the dicing sheet, based on the map data and the resin supply information; and a curing step which hardens the resin supplied to the LED elements; wherein the resin supplying step comprises a supplying step for measurement in which the resin is test supplied on a light-passing member for light emission characteristic measurement by a resin supplying part which discharges the resin in a variable supply quantity; a light-passing member carrying step of carrying the light-passing member onto which the resin is test supplied on a light-passing member carrying part; a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin; a supply quantity deriving step which derives an appropriate resin supply quantity with which the resin should be supplied onto the LED elements for practical production by revising the appropriate resin supply quantity based on the measurement result of the light emission characteristic measuring step and light emission characteristics prescribed beforehand; and a production performing step which orders a supply control part, which control the resin supplying part, with the derived appropriate resin supply quantity to make a supplying process for production in which the appropriate resin supply quantity of the resin is supplied on the LED elements to be performed.

A light emitting element package manufacturing system of the present invention which manufactures light emitting element packages which are constructed by mounting light emitting elements, which are made by coating the top surfaces of LED elements with resin containing a fluorescent substance beforehand, on boards, comprising a dicing device which divides a LED wafer in which a plurality of the LED elements are elaborated and attached onto a dicing sheet into individual LED elements; an element characteristic measuring part which individually measures the light emission characteristics of the individually divided LED elements in a state of being attached and held onto the dicing sheet to obtain element characteristic information indicating the light emission characteristics of the LED elements; a map data making part which makes map data which associate element position information indicating the position in the LED wafer of the divided LED element with the element characteristic information on the LED element for each of the LED wafers, a resin information supplying unit which supplies information that makes appropriate resin supply quantities of the resin to correspond to the element characteristic information to obtain LED elements which possess prescribed light emission characteristics as resin supply information; a resin supplying device which supplies the resin of appropriate resin supply quantities to obtain prescribed light emission characteristics to the LED elements in a wafer state of being attached onto the dicing sheet, based on the map data and the resin supply information; a curing device which makes the light emitting elements to be finished by hardening the resin supplied to the LED elements; and a component mounting device which mounts the light emitting elements on boards; wherein the resin supplying device comprises a resin supplying part which discharges the resin in a variable supply quantity to supply to any supply object positions, a supply control part which controls the resin supplying part to make a supplying process for measurement in which the resin is test supplied onto a light-passing member for light emission characteristic measurement, and a supplying process for production in which the resin is supplied onto the LED elements for practical production to be performed, a light source part which emit excitation light to excite the fluorescent substance, a light-passing member carrying part on which a light-passing member on which the resin is test supplied in the supplying process for measurement is carried, a light emission characteristic measuring part which measures the light emission characteristics of the light that the resin, which is supplied onto the light-passing member, emits when the excitation light emitted from the light source part is irradiated to the resin, a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and a production performing processor which orders the supply control part with the derived appropriate resin supply quantity to make the supplying process for production in which the appropriate resin supply quantity of the resin is supplied on the LED elements to be performed.

A light emitting element package manufacturing method of the present invention which manufactures light emitting element packages which are constructed by mounting light emitting elements, which are made by coating the top surfaces of LED elements with resin containing a fluorescent substance beforehand, on boards, comprising a dicing step which divides a LED wafer in which a plurality of the LED elements are elaborated and attached onto a dicing sheet into individual LED elements; an element characteristic measuring step which individually measures the light emission characteristics of the individually divided LED elements in a state of being attached and held onto the dicing sheet to obtain element characteristic information indicating the light emission characteristics of the LED elements; a map data making step which makes map data which associate element position information indicating the position in the LED wafer of the divided LED element with the element characteristic information on the LED element for each of the LED wafers; a resin information acquiring step which acquires information that makes appropriate resin supply quantities of the resin to correspond to the element characteristic information to obtain light emitting elements which possess prescribed light emission characteristics as resin supply information, a resin supplying step which supplies the resin of appropriate resin supply quantities to obtain prescribed light emission characteristics to the LED elements in a wafer state of being attached onto the dicing sheet, based on the resin supply information and the map data; and a curing step which hardens the resin supplied to the LED elements and a component mounting step which mounts the light emitting elements on boards;

wherein the resin supplying step comprises a supplying step for measurement in which the resin is test supplied on a light-passing member for light emission characteristic measurement by a resin supplying part which discharges the resin in a variable supply quantity, a light-passing member carrying step of carrying the light-passing member onto which the resin is test supplied on a light-passing member carrying part, a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin, a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and a production performing step which orders a supply control part, which control the resin supplying part, with the derived appropriate resin supply quantity to make a supplying process for production in which the appropriate resin supply quantity of the resin is supplied on the LED elements to be performed.

A light emitting element manufacturing system of the present invention which manufactures light emitting elements by coating the top surfaces of LED elements with resin containing a fluorescent substance, comprising: a half cutting device which divides only semiconductor layers constructing the LED elements in an LED wafer in which a plurality of the LED elements are elaborated and attached onto a dicing sheet into individual LED element pieces; an element characteristic measuring part which individually measures the light emission characteristics of the individually divided LED elements in a half cut state that only the semiconductor layers are divided into individual pieces to obtain element characteristic information indicating the light emission characteristics of the LED elements, a map data making part which makes map data which associate element position information indicating the position in the LED wafer of the half cut LED element with the element characteristic information on the LED element for each of the LED wafers; a resin information supplying unit which supplies information that makes appropriate resin supply quantities of the resin to correspond to the element characteristic information to obtain LED elements which possess prescribed light emission characteristics as resin supply information; a resin supplying device which supplies the resin of appropriate resin supply quantities to obtain prescribed light emission characteristics to the LED elements in a half cut state, based on the map data and the resin supply information; a curing device which hardens the resin supplied to the LED elements; and a dicing device which divides the LED wafer after the resin is hardened into individual LED elements; wherein the resin supplying device comprises a resin supplying part which discharges the resin in a variable supply quantity to supply to any supply object positions,

a supply control part which controls the resin supplying part to make a supplying process for measurement in which the resin is test supplied onto a light-passing member for light emission characteristic measurement, and a supplying process for production in which the resin is supplied onto the LED elements for practical production to be performed, a light source part which emit excitation light to excite the fluorescent substance, a light-passing member carrying part on which a light-passing member on which the resin is test supplied in the supplying process for measurement is carried, a light emission characteristic measuring part which measures the light emission characteristics of the light that the resin, which is supplied onto the light-passing member, emits when the excitation light emitted from the light source part is irradiated to the resin, a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and a production performing processor which orders the supply control part with the derived appropriate resin supply quantity to make the supplying process for production in which the appropriate resin supply quantity of the resin is supplied on the LED elements to be performed.

A light emitting element manufacturing method of the present invention which manufactures light emitting elements by coating the top surfaces of LED elements with resin containing a fluorescent substance, comprising: a half cutting step which divides only semiconductor layers constructing the LED elements in an LED wafer in which a plurality of the LED elements are elaborated and attached onto a dicing sheet into individual LED element pieces; an element characteristic measuring step which individually measures the light emission characteristics of the individually divided LED elements in a half cut state that only the semiconductor layers are divided into individual pieces to obtain element characteristic information indicating the light emission characteristics of the LED elements, a map data making step which makes map data which associate element position information indicating the position in the LED wafer of the half cut LED element with the element characteristic information on the LED element for each of the LED wafers; a resin information acquiring step which acquires information that makes appropriate resin supply quantities of the resin to correspond to the element characteristic information to obtain light emitting elements which possess prescribed light emission characteristics as resin supply information, a resin supplying step which supplies the resin of appropriate resin supply quantities to obtain prescribed light emission characteristics to the LED elements in a half cut state, based on the resin supply information and the map data; a curing step which hardens the resin supplied to the LED elements; and a dicing step which divides the LED wafer after the resin is hardened into individual LED elements; wherein the resin supplying step comprises a supplying step for measurement in which the resin is test supplied on a light-passing member for light emission characteristic measurement by a resin supplying part which discharges the resin in a variable supply quantity, a light-passing member carrying step of carrying the light-passing member onto which the resin is test supplied on a light-passing member carrying part, a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin, a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and a production performing step which orders a supply control part, which control the resin supplying part, with the derived appropriate resin supply quantity to make a supplying process for production in which the appropriate resin supply quantity of the resin is supplied on the LED elements to be performed.

A light emitting element package manufacturing system of the present invention which manufactures light emitting element packages which are constructed by mounting light emitting elements, which are made by coating the top surfaces of LED elements with resin containing a fluorescent substance beforehand, on boards, comprising a half cutting device which divides only semiconductor layers constructing the LED elements in an LED wafer in which a plurality of the LED elements are elaborated and attached onto a dicing sheet into individual LED element pieces; an element characteristic measuring part which individually measures the light emission characteristics of the individually divided LED elements in a half cut state that only semiconductor layers are divided into individual pieces to obtain element characteristic information indicating the light emission characteristics of the LED elements; a map data making part which makes map data which associate element position information indicating the position in the LED wafer of the half cut LED element with the element characteristic information on the LED element for each of the LED wafers; a resin information supplying unit which supplies information that makes appropriate resin supply quantities of the resin to correspond to the element characteristic information to obtain LED elements which possess prescribed light emission characteristics as resin supply information; a resin supplying device which supplies the resin of appropriate resin supply quantities to obtain prescribed light emission characteristics to the LED elements in a half cut state, based on the map data and the resin supply information; a curing device which hardens the resin supplied to the LED elements; a dicing device which divides the LED wafer after the resin is hardened into individual light emitting elements; and a component mounting device which mounts the individual light emitting elements on boards; wherein the resin supplying device comprises a resin supplying part which discharges the resin in a variable supply quantity to supply to any supply object positions,

a supply control part which controls the resin supplying part to make a supplying process for measurement in which the resin is test supplied onto a light-passing member for light emission characteristic measurement, and a supplying process for production in which the resin is supplied onto the LED elements for practical production to be performed, a light source part which emit excitation light to excite the fluorescent substance, a light-passing member carrying part on which a light-passing member on which the resin is test supplied in the supplying process for measurement is carried, a light emission characteristic measuring part which measures the light emission characteristics of the light that the resin, which is supplied onto the light-passing member, emits when the excitation light emitted from the light source part is irradiated to the resin, a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and a production performing processor which orders the supply control part with the derived appropriate resin supply quantity to make the supplying process for production in which the appropriate resin supply quantity of the resin is supplied on the LED elements to be performed.

A light emitting element package manufacturing method of the present invention which manufactures light emitting element packages which are constructed by mounting light emitting elements, which are made by coating the top surfaces of LED elements with resin containing a fluorescent substance beforehand, on boards, comprising a half cutting step which divides only semiconductor layers constructing the LED elements in an LED wafer in which a plurality of the LED elements are elaborated and attached onto a dicing sheet into individual LED element pieces; an element characteristic measuring step which individually measures the light emission characteristics of the individually divided LED elements in a half cut state that only the semiconductor layers are divided into individual pieces to obtain element characteristic information indicating the light emission characteristics of the LED elements; a map data making step which makes map data which associate element position information indicating the position in the LED wafer of the half cut LED element with the element characteristic information on the LED element for each of the LED wafers; a resin information acquiring step which acquires information that makes appropriate resin supply quantities of the resin to correspond to the element characteristic information to obtain light emitting elements which possess prescribed light emission characteristics as resin supply information, a resin supplying step which supplies the resin of appropriate resin supply quantities to obtain prescribed light emission characteristics to the LED elements in a half cut state, based on the resin supply information and the map data; a curing step which hardens the resin supplied to the LED elements, a dicing step which divides the LED wafer after the resin is hardened into individual light emitting elements; and a component mounting step which mounts the individual light emitting elements on boards; wherein the resin supplying step comprises a supplying step for measurement in which the resin is test supplied on a light-passing member for light emission characteristic measurement by a resin supplying part which discharges the resin in a variable supply quantity, a light-passing member carrying step of carrying the light-passing member onto which the resin is test supplied on a light-passing member carrying part, a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin, a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and a production performing step which orders a supply control part, which control the resin supplying part, with the derived appropriate resin supply quantity to make a supplying process for production in which the appropriate resin supply quantity of the resin is supplied on the LED elements to be performed.

A light emitting element manufacturing system which manufactures light emitting elements by coating the top surfaces of LED elements with resin containing a fluorescent substance, comprising a dicing device which divides a LED wafer in which a plurality of the LED elements are elaborated and attached onto a dicing sheet into individual LED elements; an element characteristic measuring part which individually measures the light emission characteristics of the individually divided LED elements in a state of being attached and held onto the dicing sheet to obtain element characteristic information indicating the light emission characteristics of the LED elements; a map data making part which makes map data which associate element position information indicating the position in the LED wafer of the divided LED element with the element characteristic information on the LED element for each of the LED wafers; an element rearranging part which rearranges the LED elements with a predetermined array based on the map data onto an element holding surface, a resin information supplying unit which supplies information that makes appropriate resin supply quantities of the resin to correspond to the element characteristic information to obtain LED elements which possess prescribed light emission characteristics as resin supply information; a resin supplying device which supplies the resin of appropriate resin supply quantities to obtain prescribed light emission characteristics to the LED elements held on the element holding surface, based on element array information indicating the array of the LED elements rearranged by the element rearranging part and the resin supply information; and a curing device which hardens the resin supplied to the LED elements; wherein the resin supplying device comprises a resin supplying part which discharges the resin in a variable supply quantity to supply to any supply object positions, a supply control part which controls the resin supplying part to make a supplying process for measurement in which the resin is test supplied onto a light-passing member for light emission characteristic measurement, and a supplying process for production in which the resin is supplied onto the LED elements for practical production to be performed, a light source part which emit excitation light to excite the fluorescent substance, a light-passing member carrying part on which a light-passing member on which the resin is test supplied in the supplying process for measurement is carried, a light emission characteristic measuring part which measures the light emission characteristics of the light that the resin, which is supplied onto the light-passing member, emits when the excitation light emitted from the light source part is irradiated to the resin, a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and a production performing processor which orders the supply control part with the derived appropriate resin supply quantity to make the supplying process for production in which the appropriate resin supply quantity of the resin is supplied on the LED elements to be performed.

A light emitting element manufacturing method of the present invention which manufactures light emitting elements by coating the top surfaces of LED elements with resin containing a fluorescent substance, comprising a dicing step which divides a LED wafer in which a plurality of the LED elements are elaborated and attached onto a dicing sheet into individual LED elements; an element characteristic measuring step which individually measures the light emission characteristics of the individually divided LED elements in a state of being attached and held onto the dicing sheet to obtain element characteristic information indicating the light emission characteristics of the LED elements; a map data making step which makes map data which associate element position information indicating the position in the LED wafer of the divided LED element with the element characteristic information on the LED element for each of the LED wafers, an element rearranging step which rearranges the LED elements with a predetermined array based on the map data onto an element holding surface; a resin information acquiring step which acquires information that makes appropriate resin supply quantities of the resin to correspond to the element characteristic information to obtain LED elements which possess prescribed light emission characteristics as resin supply information; a resin supplying step which supplies the resin of appropriate resin supply quantities to obtain prescribed light emission characteristics to the LED elements held on the element holding surface, based on element array information indicating the array of the LED elements rearranged by the element rearranging step and the resin supply information; and a curing step which hardens the resin supplied to the LED elements; wherein the resin supplying step comprises a supplying step for measurement in which the resin is test supplied on a light-passing member for light emission characteristic measurement by a resin supplying part which discharges the resin in a variable supply quantity, a light-passing member carrying step of carrying the light-passing member onto which the resin is test supplied on a light-passing member carrying part, a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin, a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and a production performing step which orders a supply control part, which control the resin supplying part, with the derived appropriate resin supply quantity to make a supplying process for production in which the appropriate resin supply quantity of the resin is supplied on the LED elements to be performed.

A light emitting element package manufacturing system which manufactures light emitting element packages which are constructed by mounting light emitting elements, which are made by coating the top surfaces of LED elements with resin containing a fluorescent substance beforehand, on boards, comprising a dicing device which divides a LED wafer in which a plurality of the LED elements are elaborated and attached onto a dicing sheet into individual LED elements; an element characteristic measuring part which individually measures the light emission characteristics of the individually divided LED elements in a state of being attached and held onto the dicing sheet to obtain element characteristic information indicating the light emission characteristics of the LED elements; a map data making part which makes map data which associate element position information indicating the position in the LED wafer of the divided LED element with the element characteristic information on the LED element for each of the LED wafers; an element rearranging part which rearranges the LED elements with a predetermined array based on the map data onto an element holding surface, a resin information supplying unit which supplies information that makes appropriate resin supply quantities of the resin to correspond to the element characteristic information to obtain LED elements which possess prescribed light emission characteristics as resin supply information; a resin supplying device which supplies the resin of appropriate resin supply quantities to obtain prescribed light emission characteristics to the LED elements held on the element holding surface, based on element array information indicating the array of the LED elements rearranged by the element rearranging part and the resin supply information; a curing device which makes the light emitting elements to be finished by hardening the resin supplied to the LED elements; and a component mounting device which mounts the light emitting elements on boards, wherein the resin supplying device comprises a resin supplying part which discharges the resin in a variable supply quantity to supply to any supply object positions, a supply control part which controls the resin supplying part to make a supplying process for measurement in which the resin is test supplied onto a light-passing member for light emission characteristic measurement, and a supplying process for production in which the resin is supplied onto the LED elements for practical production to be performed, a light source part which emit excitation light to excite the fluorescent substance, a light-passing member carrying part on which a light-passing member on which the resin is test supplied in the supplying process for measurement is carried, a light emission characteristic measuring part which measures the light emission characteristics of the light that the resin, which is supplied onto the light-passing member, emits when the excitation light emitted from the light source part is irradiated to the resin, a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and a production performing processor which orders the supply control part with the derived appropriate resin supply quantity to make the supplying process for production in which the appropriate resin supply quantity of the resin is supplied on the LED elements to be performed.

A light emitting element package manufacturing method of the present invention which manufactures light emitting element packages which are constructed by mounting light emitting elements, which are made by coating the top surfaces of LED elements with resin containing a fluorescent substance beforehand, on boards, comprising a dicing step which divides a LED wafer in which a plurality of the LED elements are elaborated and attached onto a dicing sheet into individual LED elements; an element characteristic measuring step which individually measures the light emission characteristics of the individually divided LED elements in a state of being attached and held onto the dicing sheet to obtain element characteristic information indicating the light emission characteristics of the LED elements; a map data making step which makes map data which associate element position information indicating the position in the LED wafer of the divided LED element with the element characteristic information on the LED element for each of the LED wafers; an element rearranging step which rearranges the LED elements with a predetermined array based on the map data onto an element holding surface;

a resin information acquiring step which acquires information that makes appropriate resin supply quantities of the resin to correspond to the element characteristic information to obtain LED elements which possess prescribed light emission characteristics as resin supply information; a resin supplying step which supplies the resin of appropriate resin supply quantities to obtain prescribed light emission characteristics to the LED elements held on the element holding surface, based on element array information indicating the array of the LED elements rearranged by the element rearranging step and the resin supply information; a curing step which hardens the resin supplied to the LED elements; and a component mounting step which mounts the light emitting elements on boards; wherein the resin supplying step comprises a supplying step for measurement in which the resin is test supplied on a light-passing member for light emission characteristic measurement by a resin supplying part which discharges the resin in a variable supply quantity; a light-passing member carrying step of carrying the light-passing member onto which the resin is test supplied on a light-passing member carrying part; a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin, a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and a production performing step which orders a supply control part, which control the resin supplying part, with the derived appropriate resin supply quantity to make a supplying process for production in which the appropriate resin supply quantity of the resin is supplied on the LED elements to be performed.

### Effects of the Invention

According to the present invention, in manufacturing light emitting elements by coating the top surfaces of LED elements with the resin containing the fluorescent substance, in the resin supplying operation of discharging to supply the resin onto the LED elements in a wafer state, the light emission characteristics of the light that the resin emits when the excitation light from the light source part is irradiated onto the light-passing member on which the resin is test supplied for light emission characteristic measurement are measured, and the appropriate resin supply quantity is revised based on the result of the measurement and the light emission characteristics prescribed beforehand, to derive an appropriate resin supply quantity of the resin which should be supplied to the LED elements for practical production. Therefore, even if the light emission wavelength of the individual LED element varies, by equalizing the light emission characteristics of the light emitting element, production yield can be improved, and the area productivity of manufacturing devices can be improved.

### BRIEF DESCRIPTION OF THE FIGURES

FIG. 1 is a block diagram which shows the construction of a light emitting element manufacturing system of an embodiment 1 of the present invention.

FIGS. 2(a) and 2(b) are illustrative figures of the construction of an LED wafer which becomes an object of the light emitting element manufacturing system of the embodiment 1 of the present invention.

FIGS. 3(a) and 3(b) are illustrative figures of functions of a dicing device and an element characteristic measuring device in the light emitting element manufacturing system of the embodiment 1 of the present invention.

FIGS. 4(a) and 4(b) are illustrative figures of map data used in the light emitting element manufacturing system of the embodiment 1 of the present invention.

FIG. 5 is an illustrative figure of resin supply information used in the light emitting element manufacturing system of the embodiment 1 of the present invention.

FIGS. 6(a) and 6(b) are illustrative figures of the construction of a resin supplying device in the light emitting element manufacturing system of the embodiment 1 of the present invention.

FIGS. 7(a) and 7(b) are illustrative figures of the functions of the resin supplying device in the light emitting element manufacturing system of the embodiment 1 of the present invention.

FIGS. 8(a) to 8(c) are illustrative figures of a light emission characteristic detecting function which is included in the resin supplying device in the light emitting element manufacturing system of the embodiment 1 of the present invention.

FIGS. 9(a) and 9(b) are illustrative figures of a light emission characteristic detecting function which is included in the resin supplying device in the light emitting element manufacturing system of the embodiment 1 of the present invention.

FIGS. 10(a) and 10(b) are illustrative figures of functions of a curing device and a sorting device in the light emitting element manufacturing system of the embodiment 1 of the present invention.

FIG. 11 is a block diagram which indicates the construction of a control system of the light emitting element manufacturing system of the embodiment 1 of the present invention.

FIG. 12 is a block diagram which shows the construction of a light emitting element package manufacturing system of the embodiment 1 of the present invention.

FIGS. 13(a) and 13(b) are illustrative figures of the construction of light emitting element packages manufactured by the light emitting element package manufacturing system of the embodiment 1 of the present invention.

FIGS. 14(a) to 14(c) are illustrative figures of the construction and functions of a component mounting device in the light emitting element package manufacturing system of the embodiment 1 of the present invention.

FIG. 15 is a flow diagram of manufacturing light emitting element packages in the light emitting element package manufacturing system of the embodiment 1 of the present invention.

FIG. 16 is a flow diagram of a threshold data making process for quality item determination in the light emitting element package manufacturing system of the embodiment 1 of the present invention.

FIGS. 17(a) to 17(c) are illustrative figures of threshold data for quality item determination in the light emitting element package manufacturing system of the embodiment 1 of the present invention.

FIG. 18 is a chromaticity diagram which describes the threshold data for quality item determination the light emitting element package manufacturing system of the embodiment 1 of the present invention.

FIG. 19 is a flow diagram of a resin supplying operation in a light emitting element package manufacturing process of the light emitting element package manufacturing system of the embodiment 1 of the present invention.

FIGS. 20(a) to 20(d) are illustrative figures of the resin supplying operation in the light emitting element package manufacturing process of the light emitting element package manufacturing system of the embodiment 1 of the present invention.

FIGS. 21(a) to 21(d) are illustrative figures of the steps of the light emitting element package manufacturing process of the light emitting element package manufacturing system of the embodiment 1 of the present invention.

FIGS. 22(a) to 22(d) are illustrative figures of the steps of the light emitting element package manufacturing process of the light emitting element package manufacturing system of the embodiment 1 of the present invention.

FIG. 23 is a block diagram which shows the construction of a light emitting element manufacturing system of an embodiment 2 of the present invention.

FIGS. 24(a) and 24(b) are illustrative figures of the construction of an LED wafer which becomes an object of the light emitting element manufacturing system of the embodiment 2 of the present invention.

FIGS. 25(a) and 25(b) are illustrative figures of functions of a dicing device and an element characteristic measuring device in the light emitting element manufacturing system of the embodiment 2 of the present invention.

FIGS. 26(a) and 26(b) are illustrative figures of map data used in the light emitting element manufacturing system of the embodiment 2 of the present invention.

FIG. 27 is an illustrative figure of resin supply information used in the light emitting element manufacturing system of the embodiment 2 of the present invention.

FIGS. 28(a) and 28(b) are illustrative figures of the construction of a resin supplying device in the light emitting element manufacturing system of the embodiment 2 of the present invention.

FIGS. 29(a) and 29(b) are illustrative figures of the functions of the resin supplying device in the light emitting element manufacturing system of the embodiment 2 of the present invention.

FIGS. 30(a) to 30(c) are illustrative figures of a light emission characteristic detecting function which is included in the resin supplying device in the light emitting element manufacturing system of the embodiment 2 of the present invention.

FIGS. 31(a) and 31(b) are illustrative figures of a light emission characteristic detecting function which is included in the resin supplying device in the light emitting element manufacturing system of the embodiment 2 of the present invention.

FIGS. 32(a) and 32(c) are illustrative figures of functions of a curing device and a sorting device in the light emitting element manufacturing system of the embodiment 2 of the present invention.

FIG. 33 is a block diagram which indicates the construction of a control system of the light emitting element manufacturing system of the embodiment 2 of the present invention.

FIG. 34 is a block diagram which shows the construction of a light emitting element package manufacturing system of the embodiment 2 of the present invention.

FIGS. 35(a) and 35(b) are illustrative figures of the construction of light emitting element packages manufactured by the light emitting element package manufacturing system of the embodiment 2 of the present invention.

FIGS. 36(a) to 36(c) are illustrative figures of the construction and functions of a component mounting device in the light emitting element package manufacturing system of the embodiment 2 of the present invention.

FIG. 37 is a flow diagram of manufacturing light emitting element packages in the light emitting element package manufacturing system of the embodiment 2 of the present invention.

FIG. 38 is a flow diagram of a threshold data making process for quality item determination in the light emitting element package manufacturing system of the embodiment 2 of the present invention.

FIGS. 39(a) to 39(c) are illustrative figures of threshold data for quality item determination in the light emitting element package manufacturing system of the embodiment 2 of the present invention.

FIG. 40 is a flow diagram of a resin supplying operation in a light emitting element package manufacturing process of the light emitting element package manufacturing system of the embodiment 2 of the present invention.

FIGS. 41(a) to 41(d) are illustrative figures of the steps of the light emitting element package manufacturing process of the light emitting element package manufacturing system of the embodiment 2 of the present invention.

FIGS. 42(a) to 42(d) are illustrative figures of the steps of the light emitting element package manufacturing process of the light emitting element package manufacturing system of the embodiment 2 of the present invention.

FIG. 43 is a block diagram which shows the construction of a light emitting element manufacturing system of an embodiment 3 of the present invention.

FIGS. 44(a) and 44(b) are illustrative figures of the construction of an LED wafer which becomes an object of the light emitting element manufacturing system of the embodiment 3 of the present invention.

FIGS. 45(a) and 45(b) are illustrative figures of functions of a dicing device and an element characteristic measuring device in the light emitting element manufacturing system of the embodiment 3 of the present invention.

FIGS. 46(a) and 46(b) are illustrative figures of map data used in the light emitting element manufacturing system of the embodiment 3 of the present invention.

FIG. 47 is an illustrative figure of resin supply information used in the light emitting element manufacturing system of the embodiment 3 of the present invention.

FIGS. 48(a) and 48(b) are illustrative figures of the functions of an element rearranging device in the light emitting element manufacturing system of the embodiment 3 of the present invention.

FIGS. 49(a) and 49(b) are illustrative figures of the construction of a resin supplying device in the light emitting element manufacturing system of the embodiment 3 of the present invention.

FIGS. 50(a) and 50(b) are illustrative figures of the functions of the resin supplying device in the light emitting element manufacturing system of the embodiment 3 of the present invention.

FIGS. 51(a) to 51(c) are illustrative figures of a light emission characteristic detecting function which is included in the resin supplying device in the light emitting element manufacturing system of the embodiment 3 of the present invention.

FIGS. 52(a) and 52(b) are illustrative figures of a light emission characteristic detecting function which is included in the resin supplying device in the light emitting element manufacturing system of the embodiment 3 of the present invention.

FIGS. 53(a) and 53(b) are illustrative figures of functions of a curing device and a sorting device in the light emitting element manufacturing system of the embodiment 3 of the present invention.

FIG. 54 is a block diagram which indicates the construction of a control system of the light emitting element manufacturing system of the embodiment 3 of the present invention.

FIG. 55 is a block diagram which shows the construction of a light emitting element package manufacturing system of the embodiment 3 of the present invention.

FIGS. 56(a) and 56(b) are illustrative figures of the construction of light emitting element packages manufactured by the light emitting element package manufacturing system of the embodiment 3 of the present invention.

FIGS. 57(a) to 57(c) are illustrative figures of the construction and functions of a component mounting device in the light emitting element package manufacturing system of the embodiment 3 of the present invention.

FIG. 58 is a flow diagram of manufacturing light emitting element packages in the light emitting element package manufacturing system of the embodiment 3 of the present invention.

FIG. 59 is a flow diagram of a threshold data making process for quality item determination in the light emitting element package manufacturing system of the embodiment 3 of the present invention.

FIGS. 60(a) to 60(c) are illustrative figures of threshold data for quality item determination in the light emitting element package manufacturing system of the embodiment 3 of the present invention.

FIG. 61 is a flow diagram of a resin supplying operation in a light emitting element package manufacturing process of the light emitting element package manufacturing system of the embodiment 3 of the present invention.

FIGS. 62(a) to 62(d) are illustrative figures of the steps of the light emitting element package manufacturing process of the light emitting element package manufacturing system of the embodiment 3 of the present invention.

FIGS. 63(a) to 63(d) are illustrative figures of the steps of the light emitting element package manufacturing process of the light emitting element package manufacturing system of the embodiment 3 of the present invention.

### EMBODIMENTS OF THE INVENTION

### Embodiment 1

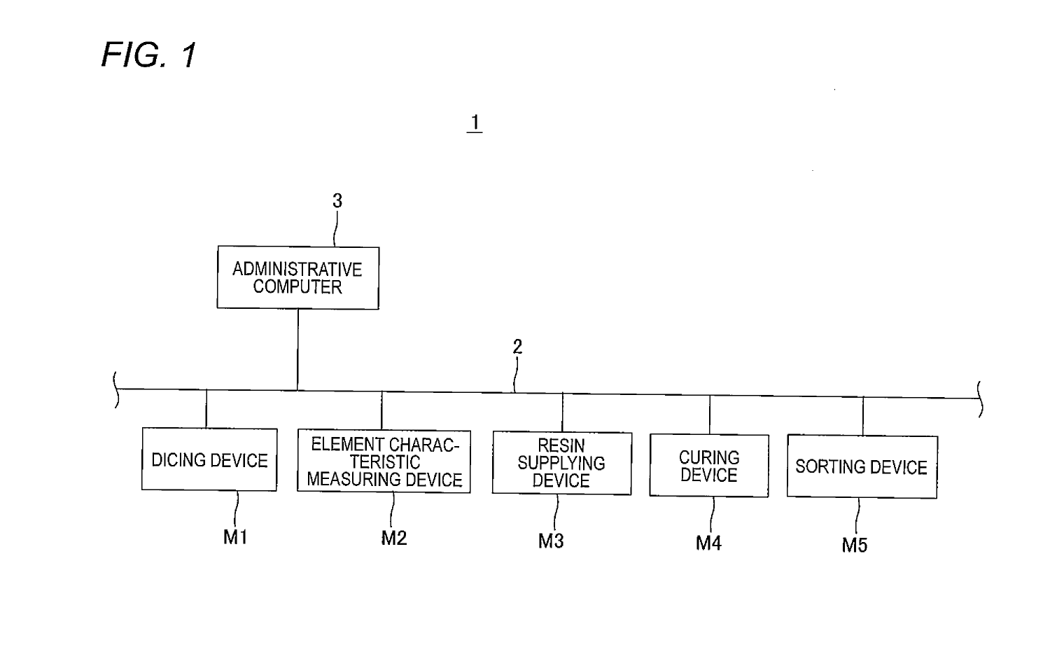

Next, an embodiment 1 of the invention is described with reference to the figures. First, with reference to FIG. 1, the construction of a light emitting element manufacturing system 1 is described. The light emitting element manufacturing system 1 has a function of manufacturing light emitting elements for white illumination which are made by coating the top surface of an LED element that emits blue light with resin including a fluorescent substance that emits yellow excited light whose color is complementary to blue. In this embodiment, as shown in FIG. 1, the light emitting element manufacturing system 1 is so constructed that each of a dicing device M1, an element characteristic measuring device M2, a resin supplying device M3, a curing device M4 and a sorting device M5 is connected by an LAN system 2, and these devices are collectively controlled by an administrative computer 3.

The dicing device M1 divides an LED wafer in which a plurality of LED elements are elaborated and attached onto a dicing sheet into individual LED elements. The element characteristic measuring device M2 is an element characteristic measuring part, and performs operations of measuring individually the light emission characteristics of the individually divided LED elements in a state of being attached and held on the dicing sheet to obtain element characteristic information indicating the light emission characteristics of the LED elements, and making map data which associate the element position information indicating the position in the LED wafer of a divided LED element with the element characteristic information on the LED element for each LED wafer.

The resin supplying device M3, based on the above-mentioned map data, and resin supply information transmitted through the LAN system 2 from the administrative computer 3, namely, the information that makes an appropriate resin supply quantity of the resin containing the fluorescent substance to obtain the LED element that has the regulated light emission characteristics to correspond to the element characteristic information, supplies resin of appropriate resin supply quantities to have the regulated light emission characteristics to the LED elements in a wafer state of being attached onto the dicing sheet. The curing device M4 hardens the resin by heating the LED elements to which the resin is supplied. Thereby, a light emitting element of the construction that the LED element is covered with a resin film of the resin containing the fluorescent substance is formed. The curing device M4, instead of heating to harden the resin, may be constructed to promote the hardening by irradiating UV (ultraviolet rays), or may be constructed to just place the resin as it is to be naturally hardened. The sorting device M5 measures the light emission characteristics of the plurality of light emitting elements attached onto the dicing sheet again, ranks the plurality of light emitting elements into individual predetermined characteristic ranges based on the results of the measurement, and individually transfers to element holding sheets.

In FIG. 1, an example in which the devices from the dicing device M1 to the sorting device M5 are placed in a line to construct a manufacturing line is shown. However, the light emitting element manufacturing system 1 does not necessarily adopt such a line construction, but may be so constructed that the procedural steps are sequentially performed respectively by the devices that are dispersedly placed, as far as the information communication to be described in the following discussion is suitably performed.

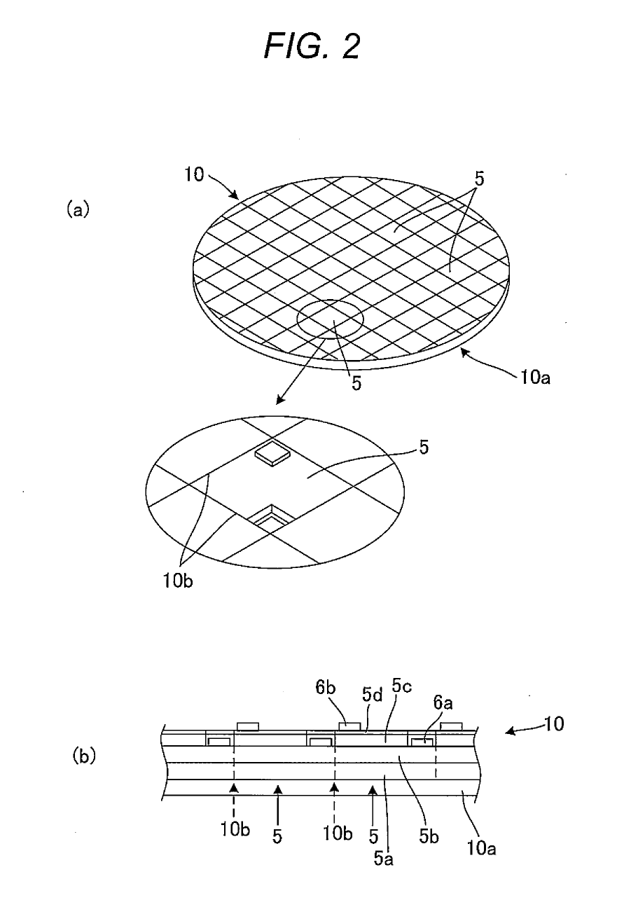

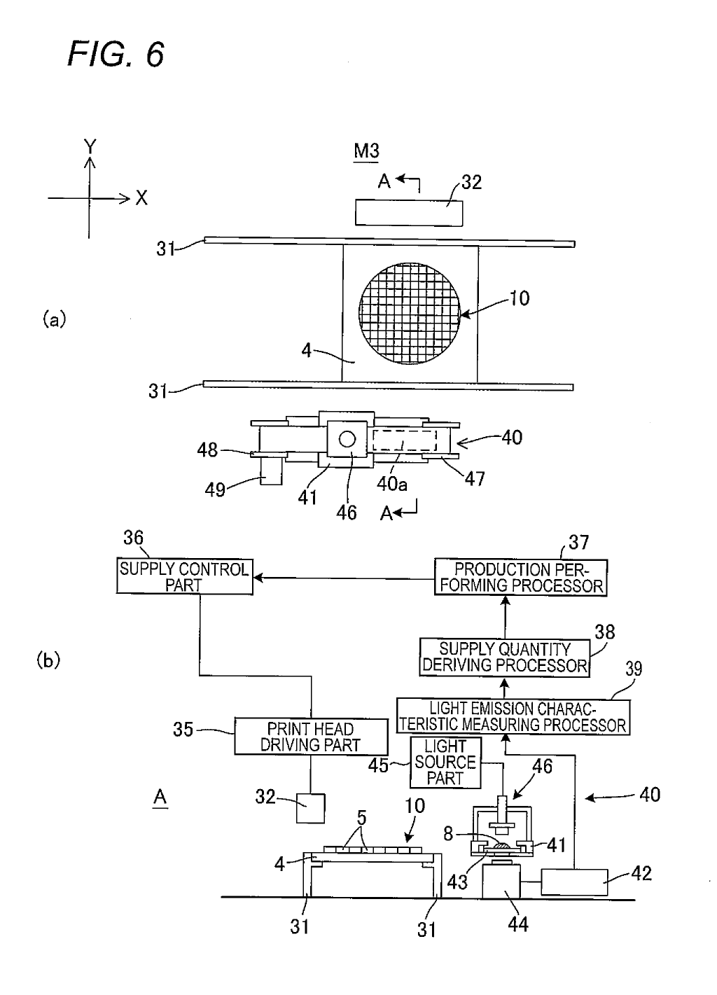

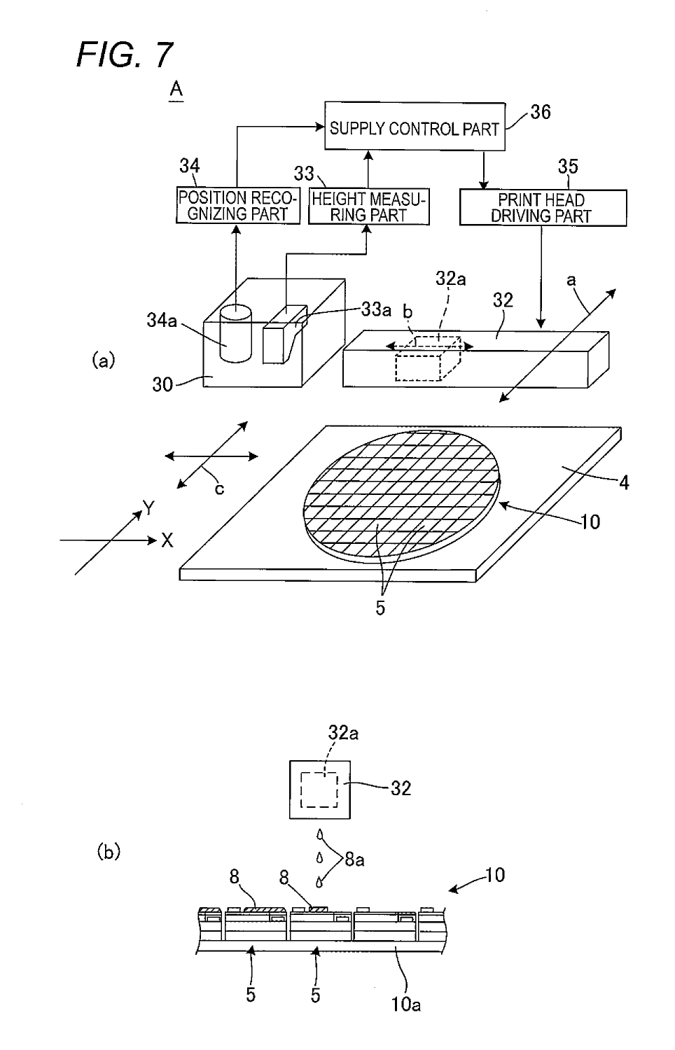

Herein, with reference to FIGS. 2(a) and 2(b), an LED wafer 10 and LED elements 5 on which operations in the light emitting element manufacturing system 1 are performed are described. As shown in FIG. 2(a), in the LED wafer 10, a plurality of LED elements 5 are elaborated in a lattice array, and a dicing sheet 10a is attached onto the under surface of the LED wafer 10. Scribe lines 10b which partition the LED elements 5 are set in the LED wafer 10, and by cutting the LED wafer 10 along the scribe lines 10b, a collection of LED elements 5 in a wafer state that the individual LED elements 5 are held by the dicing sheet 10a is formed. In the steps of the light emitting element manufacturing system 1, in a state that the LED wafer 10 is held within a wafer holder 4 (refer to FIGS. 6(a) to 7(b)), the operations and conveyance are performed.

As shown in FIG. 2(a), the LED element 5 is constructed by laminating an N-type semiconductor 5b and a P-type semiconductor 5c on a sapphire board 5a and covering the surface of the P-type semiconductor 5c with a transparent electrode 5d, and an N-type part electrode 6a and a P-type part electrode 6b for external connections are formed on the N-type semiconductor 5b and the P-type semiconductor 5c, respectively. The LED element 5 is a blue LED, and is adapted to obtain quasi-white light by being combined with resin 8 (refer to FIG. 7(b)) which contains the fluorescent substance that emits yellow fluorescence whose color is complementary to blue. In this embodiment, the resin 8 is supplied by the resin supplying device M3 to the LED elements 5 in the wafer state as described before.

Due to various kinds of deviation factors in the manufacture, for example, the variation of the composition at the time of film formation in the wafer, it cannot be avoided that the light emission characteristics, such as light emission wavelength, of the individually divided LED elements 5 from the wafer state vary. When such an LED element 5 is used as a light emitting element for illumination as it is, the light emission characteristics of the final product vary. To prevent the inferior quality due to the variation of the light emission characteristics, in the present embodiment, the light emission characteristics of the plurality of LED elements 5 are measured by the element characteristic measuring device M2 in a wafer state, element characteristic information that makes each of the LED elements 5 to correspond to data indicating the light emission characteristics of the LED element 5 is prepared, and an appropriate quantity of the resin 8 that corresponds to the light emission characteristics of the LED element 5 is supplied in the supply of the resin. To supply the appropriate quantity of the resin 8, resin supply information to be described below is prepared beforehand.

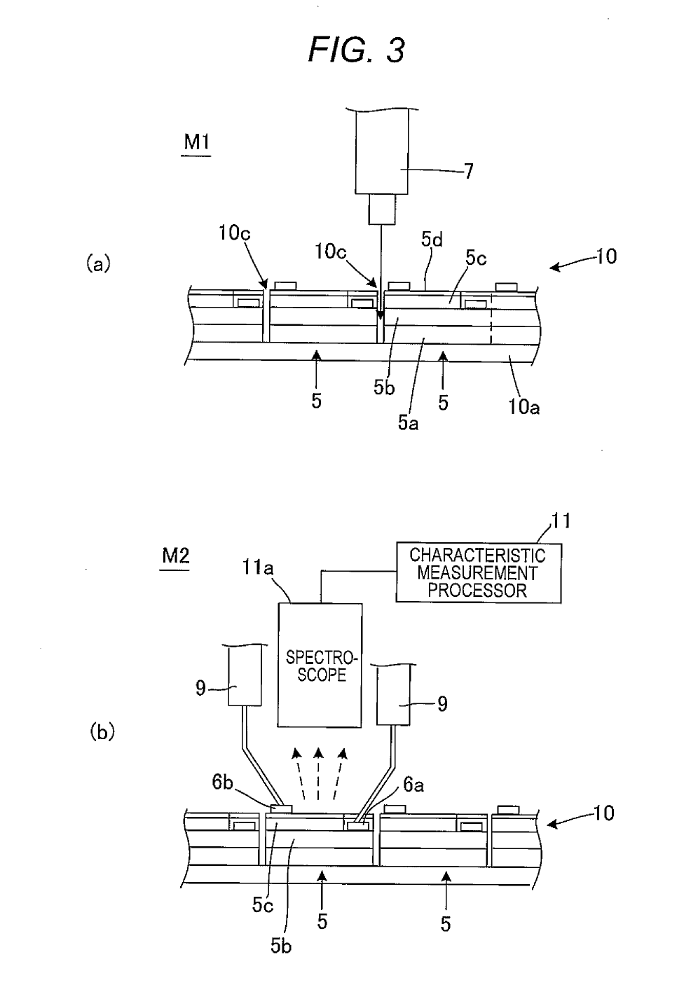

Next, the constructions and functions of the devices constructing the light emitting element manufacturing system 1 are described in the order of steps. First, the LED wafer 10 is sent to the dicing device M1 as shown in FIG. 3(a). When dicing ditches 10c which reach the dicing sheet 10a along the scribe lines 10b are formed in the LED wafer 10 by a laser cutting machine 7, the LED wafer 10 is divided into individual LED elements 5 in each of which the transparent electrode 5d, the P-type semiconductor 5c, the N-type semiconductor 5b, and the sapphire substrate 5a are laminated. Various methods can be used as the unit of the dicing. For example, individual LED elements 5 may be obtained with a method of mechanically cutting with a dicing saw, or by removing only the transparent electrode 5d, the P-type semiconductor 5c and the N-type semiconductor 5b in the thickness direction with a laser beam, and divides the sapphire substrate 5a by flaking to break those embrittled areas formed by the laser beam.

Next, as shown in FIG. 3(b), the LED wafer 10 after the dicing is sent to the element characteristic measuring device M2 where element characteristics indicating the light emission characteristics of the LED element 5 are measured. That is, while a spectroscope 11a is located right above an LED element 5 to be measured among the plurality of LED elements 5 in a wafer state of being attached and held onto the dicing sheet 10a, by making probes of a power supply device 9 touch the N-type part electrode 6a and the P-type part electrode 6b of the LED element 5, power is supplied to the N-type semiconductor 5b and the P-type semiconductor 5c to emit light. Then, a spectroscopic analysis of the light is performed to measure prescribed items such as light emission wavelength or light emission intensity, and the result of the measurement is processed by a characteristic measurement processor 11 so that element characteristic information indicating the light emission characteristics of the LED element 5 is obtained. This element characteristic measurement is performed sequentially for all the LED elements 5 constructing the LED wafer 10.

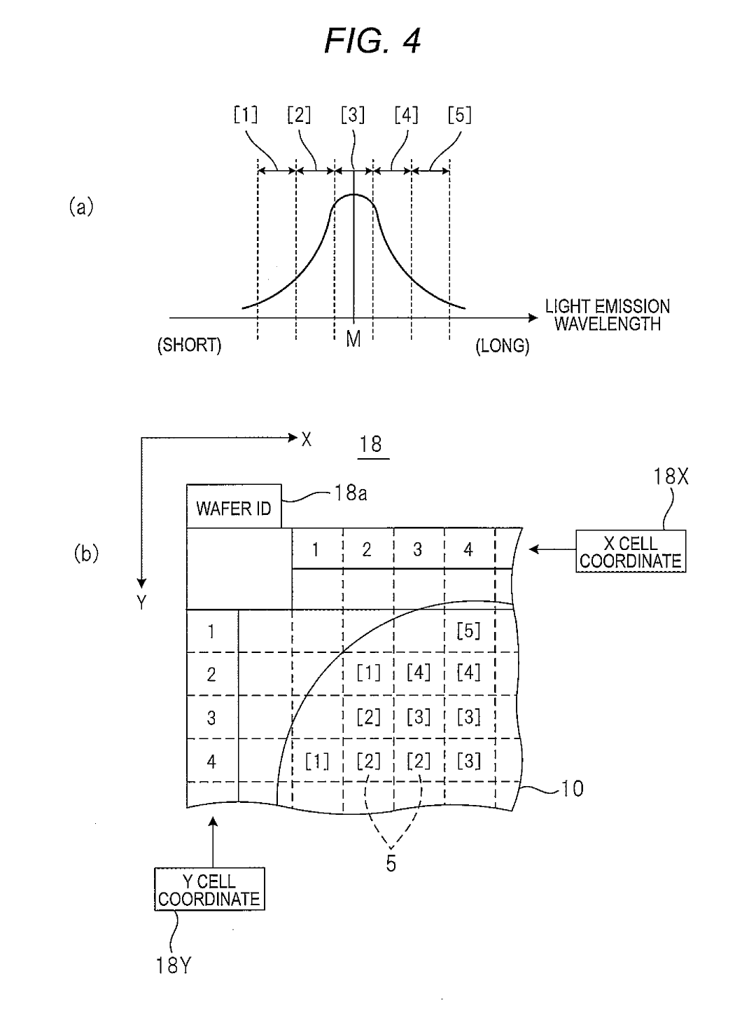

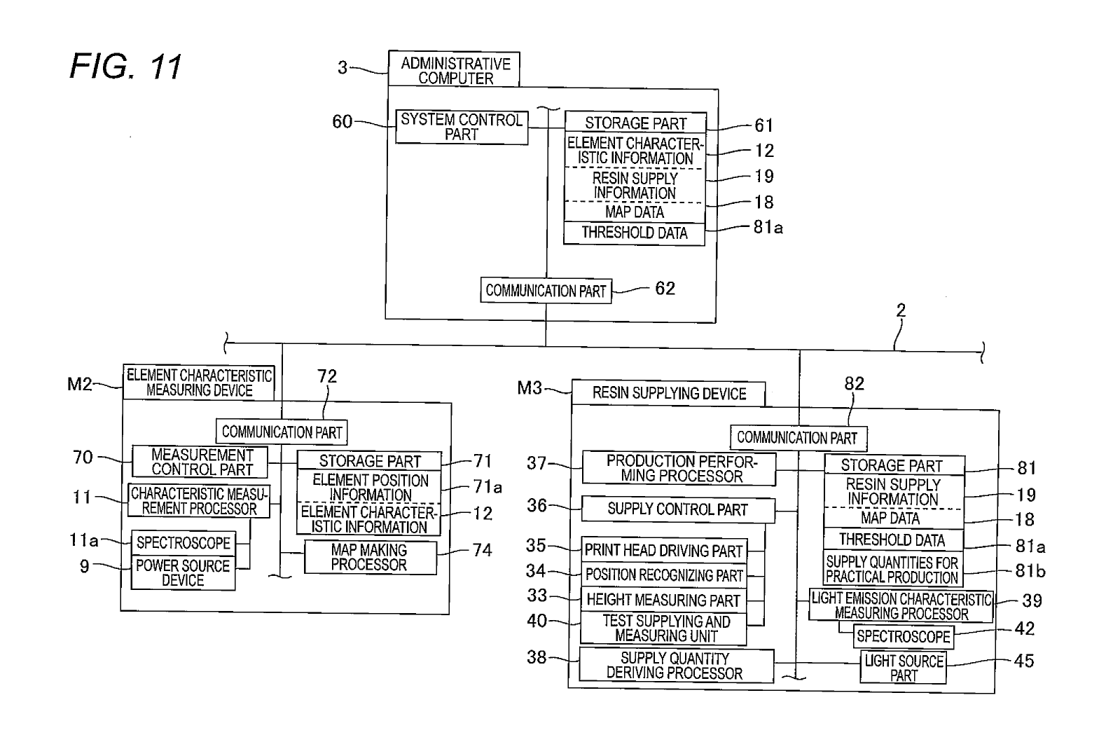

Next, the element characteristic information is described with reference to FIGS. 4(a) and 4(b). FIG. 4(a) show a standard distribution of light emission wavelength which is prepared beforehand as reference data for the LED elements 5 to be measured. By dividing a wavelength range that corresponds to the standard range in the distribution into a plurality of wavelength areas, the measured plurality of LED elements 5 are ranked by light emission wavelength. Herein, in response to each of the ranks that are set by dividing the wavelength range into five, Bin codes [1], [2], [3], [4] and [5] are given sequentially from the side of low wavelength. Based on the measurement result of the element characteristic measuring device M2, Bin codes are given to individual LED elements 5, and are stored as element characteristic information 12 in the storage part 71 (FIG. 11).

FIG. 4(b) shows map data 18 which associate the element position information indicating the position in the LED wafer 10 of a divided LED element 5 with the element characteristic information 12 on the LED element 5. Herein, an X cell coordinate 18X and a Y cell coordinate 18Y in a matrix array of the LED elements 5 in the LED wafer 10 are used as the element position information. That is, the map data 18 are constructed to make one of the Bind codes [1], [2], [3], [4] and [5] which is given to an individual LED element 5 based on the measurement result of the element characteristic measuring device M2 to correspond to the individual LED element 5 that is identified by the element position information, and by specifying a wafer ID 18a, the map data 18 of each of the individual LED wafers 10 can be read out.

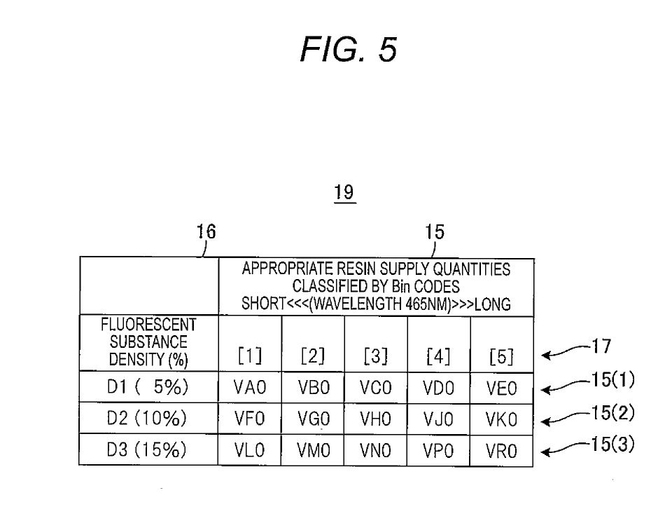

Then, the resin supply information prepared beforehand in response to the above-mentioned element characteristic information 12 is described with reference to FIG. 5. In the light emitting element of the construction to obtain white light by combining a YAG-related fluorescent substance with a blue LED, because the blue light that the LED element 5 emits is added and mixed with the yellow light that the fluorescent substance emits by being excited by the blue light, the quantity of the fluorescent substance particles in the resin film which covers the top surface of the LED element 5 becomes an important factor in ensuring the normal light emission characteristics of a finished light emitting element.

As mentioned above, because there are variations classified by the Bin codes [1], [2], [3], [4] and [5] in the light emission wavelengths of a plurality of LED elements 5 which become operation objects at the same time, the appropriate quantities of the fluorescent substance particles in the resin 8 supplied to cover the LED elements 5 differ based on the Bin codes [1], [2], [3], [4] and [5]. In this embodiment, as shown in FIG. 5, in the prepared resin supply information 19, appropriate resin supply quantities, classified based on the Bin codes, of the resin 8 which makes YAG-related fluorescent substance particles to be contained in, for example, silicone resin or epoxy resin are prescribed in nl (nanoliters) beforehand based on Bin code divisions 17. That is, when an appropriate resin supply quantity, shown in the resin supply information 19, of the resin 8 is supplied precisely to cover the LED element 5, the quantity of fluorescent substance particles in the resin covering the LED element 5 becomes an appropriate supply quantity of fluorescent substance particles, and thereby a normal light emission wavelength that is demanded is ensured in a finished product after the resin is thermally hardened.

Herein, as shown in a fluorescent substance density column 16, a plurality of fluorescent substance densities (herein, three densities, or D1 (5%), D2 (10%) and D3 (15%)) indicating the density of fluorescent substance particles of the resin 8 are set, and the appropriate resin supply quantities are set to different numerical values which are used based on the fluorescent substance density of the used resin 8. That is, when the resin 8 of the fluorescent substance density D1 is supplied, for the Bin codes [1], [2], [3], [4] and [5], the resin 8 of appropriate resin supply quantities VA0, VB0, VC0, VD0 and VE0 (appropriate resin supply quantities 15(1)) are supplied respectively. Likewise, when the resin 8 of the fluorescent substance density D2 is supplied, for the Bin codes [1], [2], [3], [4] and [5], the resin 8 of appropriate resin supply quantities VF0, VG0, VH0, VJ0 and VK0 (appropriate resin supply quantities 15(2)) are supplied respectively. Further, when the resin 8 of the fluorescent substance density D3 is supplied, for the Bin codes [1], [2], [3], [4] and [5], the resin 8 of appropriate resin supply quantities VL0, VM0, VN0, VP0 and VR0 (appropriate resin supply quantities 15(3)) are supplied respectively. In this way, the appropriate resin supply quantities are set respectively for the plurality of fluorescent substance densities which are different, and this is because supplying the resin 8 of the most suitable fluorescent substance density based on the degree of the variation of the light emission wavelength is preferable for quality insurance.

Next, with reference to FIGS. 6(a) to 7(b), a construction and functions of the resin supplying device M3 are described. The resin supplying device M3 has a function of individually supplying the resin 8 to the plurality of LED elements 5 in a wafer state which are individually divided by the dicing device M1 and whose element characteristics are measured by the element characteristic measuring device M2. As shown in a top view of FIG. 6(a), the resin supplying device M3 is constructed by disposing a resin supplying part A, which is shown in FIG. 6(b) with an A-A section, on a conveying mechanism 31 which conveys a wafer holder 4 that holds an LED wafer 10 which is an operation object.

In this embodiment, a resin discharging device which discharges the resin 8 in an inkjet manner is used as the resin supplying part A. That is, the resin supplying part A is provided with a print head 32 whose longitudinal direction is towards the X direction (conveying direction in the conveying mechanism 31). As shown in FIGS. 7(a) and 7(b), the print head 32 is provided with a built-in print nozzle unit 32a which discharges to supply a small droplet 8a of the resin 8 downwards in such a way that the discharging quantity is controllable, and when the print head 32 is driven by a print head driving part 35, the print head 32 is moved in the Y direction (arrow a) to above the LED wafer 10 which is held in the wafer holder 4, and the print nozzle unit 32a is moved in the X direction (arrow b) in the print head 32. When the print head driving part 35 is controlled by a supply control part 36, the print nozzle unit 32a is moved to an arbitrary position in the X direction and in the Y direction, and the discharging quantity of the small droplet 8a from the print nozzle unit 32a can be controlled.

A measuring head 30 including a camera 34a and a height measuring unit 33a is disposed beside the print head 32 to be movable in the X and Y directions (arrow c). When the measuring head 30 is moved to above the LED wafer 10 which is held in the wafer holder 4, and an image which is acquired by imaging the LED wafer 10 with the camera 34a is recognized by a position recognizing part 34, the position of an individual LED element 5 in the LED wafer 10 is recognized. The position recognition result is transmitted to the supply control part 36.

By aligning the height measuring unit 33a with a surface to be measured to perform a distance measuring operation with a laser beam, the height of the surface to be measured is measured. Herein, the top surface of the LED element 5 before the small droplet 8a is supplied by the print nozzle unit 32a becomes the surface to be measured, and the height measurement result by the height measuring part 33 is transmitted to the supply control part 36. When the small droplet 8a is supplied by the print nozzle unit 32a, the supply control part 36 performs a height measurement on the top surface of the LED element 5 with the height measuring part 33. When the print head 32 is controlled by the supply control part 36 in this way, as shown in FIG. 7(b), the small droplet 8a is discharged from the print nozzle unit 32a, and the resin 8 of an appropriate resin supply quantity prescribed in the resin supply information 19 is supplied to the top surface of each of the LED elements 5 of the LED wafer 10. That is, the resin supplying part A has functions of discharging a variable supply quantity of the resin 8, and supplying the resin 8 at any supply positions.

Beside the conveying mechanism 31, a test supplying and measuring unit 40 is placed in the movement range of the print head 32. The test supplying and measuring unit 40 has a function of determining whether the supply quantity of the resin 8 is appropriate before a supplying operation for practical production of supplying the resin 8 to the LED elements 5 of the LED wafer 10, by measuring the light emission characteristics of the resin 8 which is test supplied. That is, light emission characteristics when a light that a light source part 45 for measurement emits is irradiated on a light-passing member 43 where the resin 8 is test supplied by the resin supplying part A are measured by a light emission characteristic measuring part which includes a spectroscope 42 and a light emission characteristic measuring processor 39, and by comparing the measurement result with a threshold set beforehand, it is determined whether the set resin supply quantity prescribed in the resin supply information 19 shown in FIG. 5 is appropriate.

The composition and characteristic of the resin 8 containing fluorescent substance particles are not necessarily stable, and even if the appropriate resin supply quantities are set in the resin supply information 19 beforehand, it cannot be avoided that the density and the resin viscosity of the fluorescent substance fluctuate over time. Therefore, even if the resin 8 is discharged according to discharging parameters corresponding to the appropriate resin supply quantities set beforehand, it is possible that the resin supply quantity itself varies from the set appropriate value, or the resin supply quantity itself is appropriate but the supplied quantity of the fluorescent substance particles varies from what should be originally supplied due to density change.

In order to solve these problems, in the embodiment, a test supply for the purpose of detecting whether an appropriate supply quantity of fluorescent substance particles is supplied is performed by the resin supplying device M3 in a predetermined interval, and by performing the measurement of the light emission characteristic of the resin which is test supplied, the supply quantity of the fluorescent substance particles which meets the requirement of the original light emission characteristics is stabilized. Thus, the resin supplying part A included in the resin supplying device M3 shown in the present embodiment has a function of performing a supplying process for measurement in which the resin 8 is test supplied to the light-passing member 43 for the above-mentioned light emission characteristic measurement, in addition to a supplying process for production in which the resin 8 is supplied to a plurality of LED elements 5 in a wafer state of being held in the wafer holder 4 for practical production. Either of the supplying process for measurement and the supplying process for production is performed when the resin supplying part A is controlled by the supply control part 36.

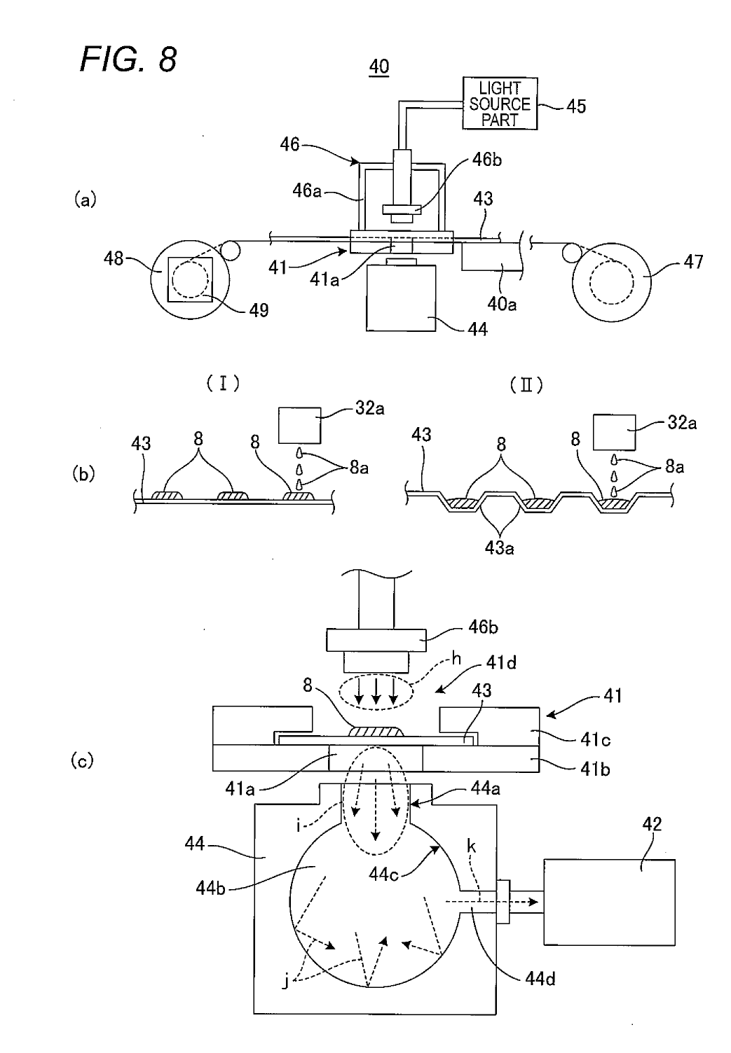

With reference to FIGS. 8(a) to 8(c), the detailed construction of the test supplying and measuring unit 40 is described. As shown in FIG. 8(a), the light-passing member 43 is supplied by being wound and accommodated in a supply reel 47, and after the light-passing member 43 is sent along the top surface of a test supplying stage 40a, the light-passing member 43 passes between a light-passing member carrying part 41 and an irradiating part 46, and is wound into a collecting reel 48 which is driven by a winding motor 49. Besides the collecting method of winding back into the collecting reel 48, various methods including a sending method in which the light-passing member 43 is sent into a collecting box by a sending mechanism can be adopted as a mechanism for collecting the light-passing member 43.

The irradiating part 46 has a function of irradiating measurement light emitted by the light source part 45 onto the light-passing member 43, and is constructed by disposing a light converging tool 46b, in which the measurement light which the light source part 45 emits is guided by fiber cables, in a shading box 46a which has the function of a simple dark box. The light source part 45 has a function of emitting excitation light to excite the fluorescent substance contained in the resin 8. In the present embodiment, the light source part 45 is placed above the light-passing member carrying part 41, and irradiates the measurement light to the light-passing member 43 from above through the light converging tool 46b.

Herein, tape material of a predetermined width formed of a planar sheet member of transparent resin, or the above tape material in which embossed parts 43a are protruded downwards from the bottom surface (emboss type), or the like are used as the light-passing member 43 (refer to FIG. 8(b)). In the process of sending the light-passing member 43 on the test supplying and measuring unit 40, the resin 8 is test supplied by the print head 32 onto the light-passing member 43. This test supply is performed as shown in FIG. 8(b), in which a prescribed supply quantity of the resin 8 in a form of the small droplet 8a is discharged (printed) by the print nozzle unit 32a to the light-passing member 43 which is supported by the test supplying stage 40a from below.

(I) of FIG. 8(b) shows that the resin 8 of the set appropriate discharging quantity prescribed in the resin supply information 19 is supplied onto the light-passing member 43 formed of the above-mentioned tape material. (II) of FIG. 8(b) shows that the resin 8 of the set appropriate discharging quantity is supplied similarly in the embossed parts 43a of the light-passing member 43 formed of the above-mentioned emboss type tape material. As described later, because the resin 8 which is supplied onto the test supplying stage 40a is test supplied to empirically determine whether the fluorescent substance supply quantity to the LED element 5 is appropriate, when the resin 8 is continuously supplied onto the light-passing member 43 at a plurality of points by the print head 32 with the same test supply movement, the supplying is performed by making the supply quantities to be different progressively based on the known data indicating the correlation of light emission characteristic measurement and the supply quantity.

After the resin 8 is test supplied in this way, white light emitted by the light source part 45 is irradiated from above through the light converging tool 46b to the light-passing member 43 which is led in the shading box 46a. The light that passes the resin 8 which is supplied onto the light-passing member 43 is received by an integrating sphere 44, which is disposed below the light-passing member carrying part 41, through a light-passing opening 41a which the light-passing member carrying part 41 is provided with. FIG. 8(c) shows structures of the light-passing member carrying part 41 and the integrating sphere 44. The light-passing member carrying part 41 is so constructed that an upper guide member 41c having a function of guiding two end surfaces of the light-passing member 43 is installed on the top surface of a lower supporting member 41b which supports the under surface of the light-passing member 43.

The light-passing member carrying part 41 has functions of guiding the light-passing member 43 at the time of conveying in the test supplying and measuring unit 40, and carrying and maintaining the position of the light-passing member 43 on which the resin 8 is test supplied in the supplying process for measurement. The integrating sphere 44 has functions of integrating the transmitted light, which is irradiated from the light converging tool 46b (arrow h) and passes through the resin 8, and leading to the spectroscope 42. That is, the integrating sphere 44 has a spherical reflecting surface 44c inside, and the transmitted light (arrows i) which enters from an opening 44a located right under the light-passing opening 41a is incident in a reflection space 44b from the opening 44a which is provided at the top of the integrating sphere 44, leaves from an output part 44d as the measurement light (arrow k) in a process of repeating total reflection (arrows j) with the spherical reflecting surface 44c, and is received by the spectroscope 42.

In the above-mentioned construction, the white light emitted by a light emitting element package used for the light source part 45 is irradiated to the resin 8 which is test supplied onto the light-passing member 43. In this process, the blue light component included in the white light excites the fluorescent substance in the resin 8 to emit yellow light. A white light in which this yellow light and the blue light are added and mixed is irradiated upwards from the resin 8, and is received by the spectroscope 42 through the above-mentioned integrating sphere 44.

The received white light is analyzed by the light emission characteristic measuring processor 39 (FIG. 6(b)) to measure the light emission characteristics. Light emission characteristics such as color tone rank or beam of the white light are detected, and, as a detection result, deviations from prescribed light emission characteristics are detected out. The integrating sphere 44, the spectroscope 42 and the light emission characteristic measuring processor 39 construct a light emission characteristic measuring part which measures light emission characteristics of the light that the resin 8 emits when the excitation light (herein, white light emitted by a white LED) emitted by the light source part 45 is irradiated from above to the resin 8 which is supplied onto the light-passing member 43 by receiving the light that the resin 8 emits from below the light-passing member 43. In the present embodiment, the light emission characteristic measuring part is constructed by placing the integrating sphere 44 below the light-passing member 43 so that the light that the resin 8 emits is received through the opening 44a of the integrating sphere 44.

The effects that are described below are obtained by constructing the light emission characteristic measuring part as above. That is, for the supply shape of the resin 8 which is test supplied onto the light-passing member 43 shown in FIG. 8(b), because the bottom side always contacts with the top surface of the light-passing member 43 or the bottom surfaces of the embossed parts 43a, the bottom surface of the resin 8 always has a standard height that is prescribed by the light-passing member 43. Therefore, the height difference between the bottom surface of the resin 8 and the opening 44a of the integrating sphere 44 is always kept constant. On the other hand, for the top surface of the resin 8, due to disturbance such as supply condition of the print nozzle unit 32a, the same liquid surface shape and height may not be necessarily realized, and the interval between the top surface of the resin 8 and the light converging tool 46b will vary.

If stability is considered when the irradiation light irradiated to the top surfaces of the resin 8 and the transmitted light from the under surfaces of the resin 8 are compared, because the irradiation light irradiated to the resin 8 is irradiated through the light converging tool 46b, the convergence degree is high, and the influence that the variation in the intervals between the top surfaces of the resin 8 and the light converging tool 46b has on the light transmission can be ignored. On the other hand, because the transmitted light which passes through the resin 8 is the excited light because the fluorescent substance is excited inside the resin 8, the divergence degree is high, and the influence that the variation in the distances between the under surfaces of the resin 8 and the opening 44a has on the degree to which light is taken in by the integrating sphere 44 cannot be ignored.

In the test supplying and measuring unit 40 shown in the present embodiment, because such a construction is adopted that the light that the resin 8 emits when the excitation light emitted by the light source part 45 as constructed above is irradiated from above to the resin 8 is received by the integrating sphere 44 from below the light-passing member 43, it is possible to determine stable light emission characteristics. By using the integrating sphere 44, it is not necessary to separately provide a darkroom structure in the light receiving part, and it is possible to compactify the device and to reduce the device cost.

As shown in FIG. 6(b), the measurement result of the light emission characteristic measuring processor 39 is sent to a supply quantity deriving processor 38, and the supply quantity deriving processor 38 revises the appropriate resin supply quantity of the resin 8 based on the measurement result of the light emission characteristic measuring processor 39 and the light emission characteristics prescribed beforehand, and derives the appropriate resin supply quantity of the resin 8 which should be supplied onto the LED element 5 as what is used for practical production. The new appropriate discharging quantity derived by the supply quantity deriving processor 38 is sent to a production performing processor 37, and the production performing processor 37 orders the supply control part 36 with the newly derived appropriate resin supply quantity. Thereby, the supply control part 36 controls the print head 32 to make the print head 32 perform a supplying process for production to supply the resin 8 of the appropriate resin supply quantity onto the LED element 5 that is mounted on the board 14.

In the supplying process for production, first, the resin 8 of the appropriate resin supply quantity prescribed in the resin supply information 19 is really supplied, and the light emission characteristics are measured when the resin 8 is in an unhardened state. Based on the obtained measurement result, a quality item range of the light emission characteristic measurement value when the light emission characteristics of the resin 8 that is supplied in the supplying process for production are measured is set, and this quality item range is used as a threshold (refer to the threshold data 81a shown in FIG. 11) with which whether a quality item is obtained in the supplying process for production is determined.

That is, in the resin supplying method in the light emitting element manufacturing system shown in the present embodiment, while a white LED is used as the light source part 45 for the light emission characteristic measurement, a light emission characteristic, which deviates from the normal light emission characteristics which are obtained from a finished product when the resin which is supplied on the LED element 5 is in a hardened state for a light emission characteristic difference because the resin 8 is in an unhardened state, is used as the light emission characteristic prescribed beforehand which is the basis of setting the threshold with which whether a quality item is obtained in the supplying process for production is determined. Thereby, the control of the resin supply quantity in the process of supplying resin onto the LED element 5 can be performed based on the normal light emission characteristics on the finished product.

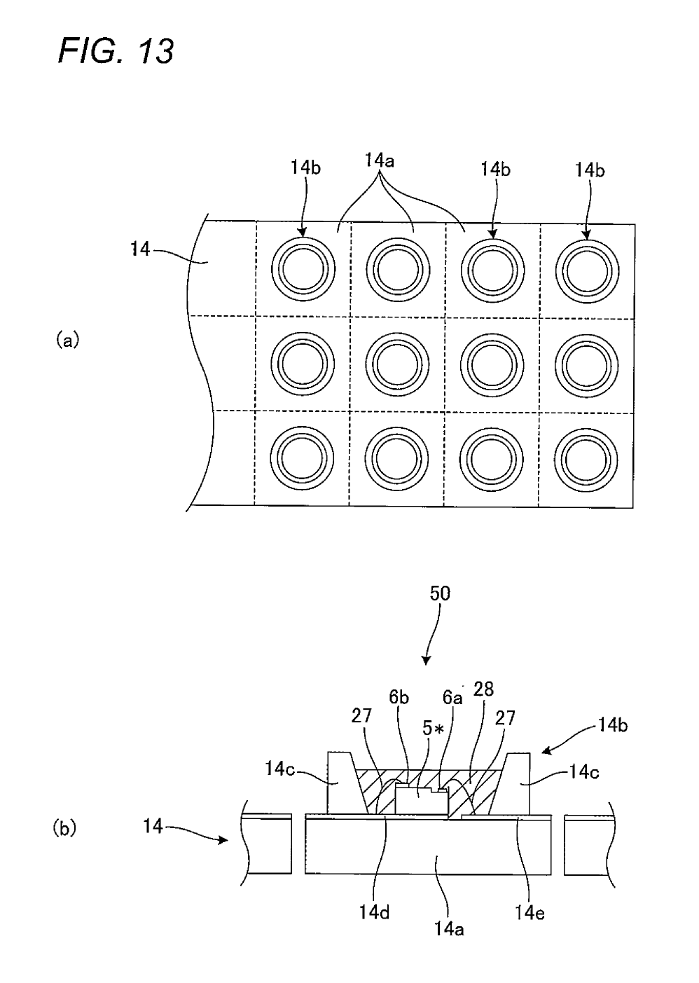

In the present embodiment, a light emitting element package 50 (refer to FIG. 13(b)) which emits white light is used as the light source part 45. Thereby, the light emission characteristic measurement of the test supplied resin 8 can be performed with a light of the same characteristic as the excitation light emitted in the light emitting element package 50 of the finished product, and a more reliable detection result can be obtained. It is not necessary to require using the same light emitting element package 50 as what is used in a finished product. In the light emission characteristic measurement, a light source device which can stably emits blue light of a constant wavelength (for example, a blue LED or a blue laser light source which emit blue light) can be used as a light source part for detection. However, by using the light emitting element package 50 which emits white light using the blue LED, there is an advantage that a light source device of stable quality can be chosen at a low cost. It is also possible to take out blue light of a predetermined wavelength by using a band pass filter.

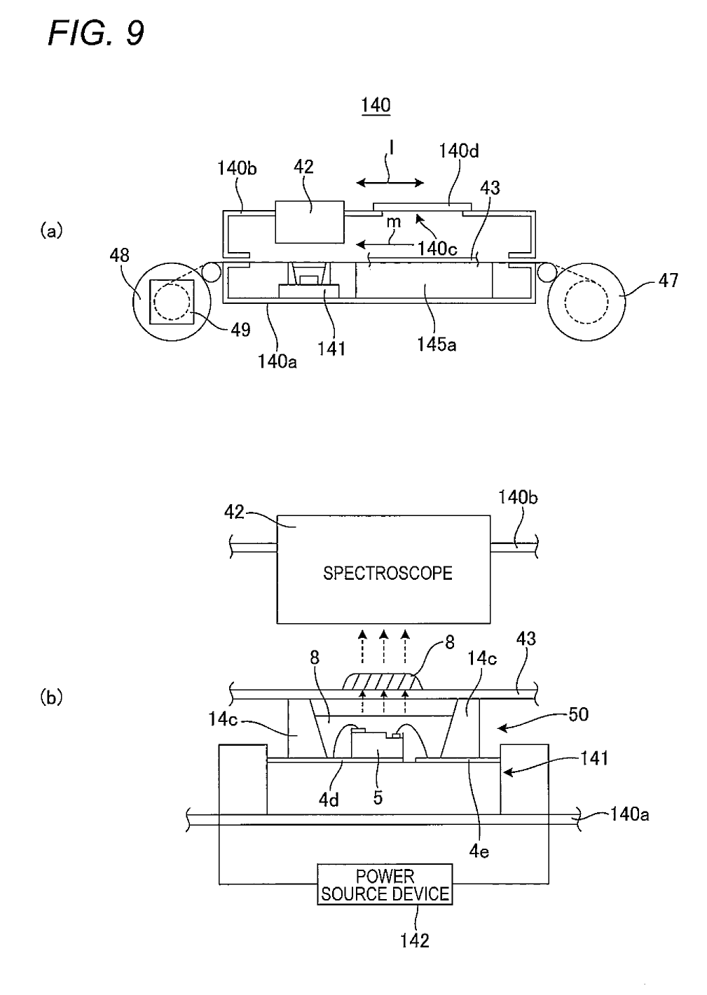

Instead of the test supplying and measuring unit 40 of the above-mentioned construction, a test supplying and measuring unit 140 of the construction shown in FIG. 9(a) may be used. That is, as shown in FIG. 9(a), the test supplying and measuring unit 140 has such an outside construction that a cover part 140b is disposed above a horizontal base 140a of a slim shape. The cover part 140b is provided with an opening 140c, and the opening 140c can be opened with a sliding window 140d which is used in supplying and is slidable (arrow 1). Inside the test supplying and measuring unit 140, a test supplying stage 145a which supports the light-passing member 43 from below, a light-passing member carrying part 141 which carries the light-passing member 43, and a spectroscope 42 which is disposed above the light-passing member carrying part 141 are provided.

The light-passing member carrying part 141 includes a light source device which emits excitation light to excite the fluorescent substance like the light source part 45 shown in FIG. 6(b). The excitation light is irradiated from below by the light source device to the light-passing member 43 on which the resin 8 is test supplied in a supplying process for measurement. Like the example shown in FIGS. 8(a) to 8(c), the light-passing member 43 is supplied by being wound and accommodated in the supply reel 47. After the light-passing member 43 is sent along the top surface of the test supplying stage 145a (arrow m), the light-passing member 43 passes between the light-passing member carrying part 141 and the spectroscope 42, and is wound into the collecting reel 48 which is driven by the winding motor 49.

When the sliding window 140d used in supplying is slid to an open state, the top surface of the test supplying stage 145a is exposed upwards, and it is possible for the print head 32 to test supply the resin 8 on the light-passing member 43 carried on the top surface. This test supplying is performed in which a prescribed supply quantity of small droplet 8a is discharged by the print nozzle unit 32a to the light-passing member 43 which is supported by the test supplying stage 145a from below.

FIG. 9(b) shows that by moving the light-passing member 43 on which the resin 8 is test supplied on the test supplying stage 145a, to make the resin 8 to be located above the light-passing member carrying part 141, and dropping the cover part 140b, a dark room for the light emission characteristic measurement is formed between the cover part 140b and the base 140a. The light emitting element package 50 emitting white light is used as a light source device in the light-passing member carrying part 141. In the light emitting element package 50, wiring layers 14e and 14d connected to the LED element 5 are connected to a power source device 142. By switching ON the power source device 142, electricity for light emission is supplied to the LED element 5 and thereby the light emitting element package 50 emits white light.

In the process that the white light is irradiated to the resin 8 test supplied on the light-passing member 43 after the white light passes through the resin 8, a white light, in which yellow light that the fluorescent substance in the resin 8, which is excited by the blue light included in the white light, emits and the blue light are added and mixed, is irradiated upwards from the resin 8. The spectroscope 42 is placed above the test supplying and measuring unit 140. The white light irradiated from the resin 8 is received by the spectroscope 42. The received white light is analyzed by the light emission characteristic measuring processor 39 to measure the light emission characteristics. Light emission characteristics such as color tone rank or beam of the white light are detected, and, as a result, deviations from prescribed light emission characteristics are detected out. That is, the light emission characteristic measuring processor 39 measures the light emission characteristic of the light that the resin 8, which is supplied onto the light-passing member 43, emits when the excitation light emitted from the LED element 5, which is the light source part, is irradiated to the resin 8. The measurement result of the light emission characteristic measuring processor 39 is sent to the supply quantity deriving processor 38, and the processes like the example shown in FIGS. 6(a) and 6(b) are performed.

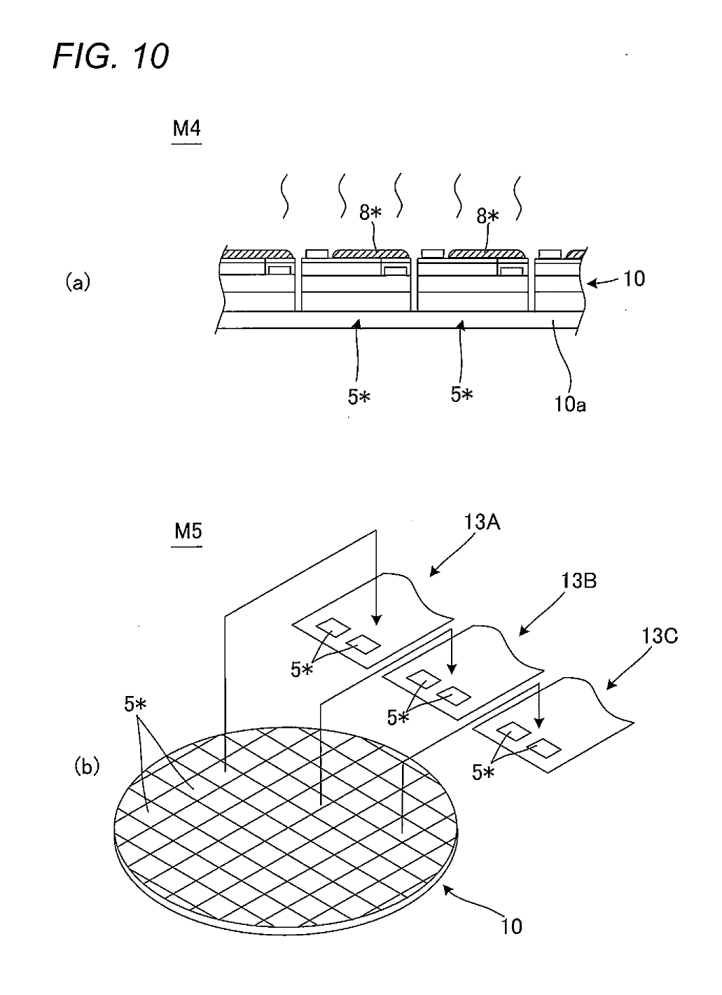

The LED elements 5 to which the resin is supplied in this way are sent to the curing device M4 in a state of the LED wafer 10. As shown in FIG. 10(a), the resin 8 is hardened by heating the LED wafer 10. Thereby, light emitting elements 5* of a construction that the LED element 5 is covered with a resin film 8* formed when the resin 8 containing the fluorescent substance is hardened are formed. After this, the LED wafer 10 is sent to the sorting device M5 in which the light emission characteristics of the plurality of light emitting elements 5* attached onto the dicing sheet 10a are measured again. Based on a result of the measurement, the plurality of light emitting elements 5* constructing the LED wafer 10 are ranked into individual predetermined characteristic ranges and respectively transferred to the plurality of element holding sheets 13A, 13B, 13C and the like. Whether the sorting device M5 in the light emitting element manufacturing system 1 is necessary is determined in consideration of the precision of the light emission characteristics demanded from a finished product and/or the precision of the resin supply quantity revision of the resin supplying device M3, and the process of the sorting device M5 is not necessarily required.

Next, with reference to FIG. 11, the construction of a control system of the light emitting element manufacturing system 1 is described. Among the component elements of the devices that construct the light emitting element manufacturing system 1, those component elements that are related to the transmission/reception and update processing of the element characteristic information 12, the resin supply information 19, the map data 18 and the threshold data 81a are shown in the administrative computer 3, the element characteristic measuring device M2 and the resin supplying device M3.

In FIG. 11, the administrative computer 3 includes a system control part 60, a storage part 61 and a communication part 62. The system control part 60 collectively controls light emitting element package manufacturing operations of the light emitting element manufacturing system 1. Besides programs and data necessary for control processes of the system control part 60, the element characteristic information 12, the resin supply information 19, and, as needed, the map data 18 and threshold data 81a, are stored in the storage part 61. The communication part 62 is connected to other devices through the LAN system 2 and delivers control signals and data. The resin supply information 19 are transmitted from outside through the LAN system 2 and the communication part 62 or through an independent storage medium such as a CD ROM, a USB memory storage, or a SD card, and are stored in the storage part 61.

The element characteristic measuring device M2 includes a measurement control part 70, a storage part 71, a communication part 72, the characteristic measurement processor 11 and a map making processor 74. The measurement control part 70 controls all parts described below based on various programs and data stored in the storage part 71 to perform element characteristic measuring operations of the element characteristic measuring device M2. Besides programs and data necessary for the control processes of the measurement control part 70, element position information 71a and the element characteristic information 12 are stored in the storage part 71. The element position information 71a is data indicating the arranged positions of the LED elements 5 in the LED wafer 10. The element characteristic information 12 is data of the result of a measurement by the characteristic measurement processor 11.

The communication part 72 is connected to other devices through the LAN system 2, and delivers control signals and data. The map making processor 74 (map data making unit) performs the process of making the map data 18 for every LED wafer 10 which associate the element position information 71a stored in the storage part 71 with the element characteristic information 12 on the LED element 5. The map data 18 such made are transmitted to the resin supplying device M3 as forward feeding data through the LAN system 2. The map data 18 may be transmitted to the resin supplying device M3 from the element characteristic measuring device M2 via the administrative computer 3. In this case, as shown in FIG. 11, the map data 18 are stored in the storage part 61 of the administrative computer 3.

The resin supplying device M3 includes the supply control part 36, a storage part 81, a communication part 82, the production performing processor 37, the supply quantity deriving processor 38, and the light emission characteristic measuring processor 39. The supply control part 36, by controlling the print head driving part 35 which forms the resin supplying part A, the position recognizing part 34, the height measuring part 33 and the test supplying and measuring unit 40, performs processes to make the supplying process for measurement in which the resin 8 is test supplied onto the light-passing member 43 used for light emission characteristic measurement, and the supplying process for production in which the resin 8 is supplied onto the LED element 5 for practical production to be performed.

Besides programs and data necessary for control processes of the supply control part 36, the resin supply information 19, the map data 18, the threshold data 81a and supply quantities for practical production 81b are stored in the storage part 81. The resin supply information 19 is transmitted from the administrative computer 3 through the LAN system 2, and the map data 18 are transmitted from the element characteristic measuring device M2 through the LAN system 2 similarly. The communication part 82 is connected to other devices through the LAN system 2 and delivers control signals and data.

The light emission characteristic measuring processor 39 performs processes to measure the light emission characteristics of the light that the resin 8 emits when the excitation light emitted from the light source part 45 is irradiated to the resin 8 which is supplied onto the light-passing member 43. The supply quantity deriving processor 38 performs calculating processes to derive the appropriate resin supply quantity of the resin 8 which should be supplied onto the LED element 5 for practical production by revising the appropriate resin supply quantity based on the measurement result of the light emission characteristic measuring processor 39 and the light emission characteristic prescribed beforehand. The production performing processor 37 makes the supplying process for production, in which the resin of the appropriate resin supply quantity is supplied on the LED element 5, to be performed by ordering the supply control part 36 with the appropriate resin supply quantity derived by the supply quantity deriving processor 38.

In the construction shown in FIG. 11, processing functions except those functions to perform the operations specific to the devices, for example, the function of the map making processor 74 which the element characteristic measuring device M2 is provided with and the function of the supply quantity deriving processor 38 which the resin supplying device M3 are provided with, are not necessarily included in the devices. For example, it is also possible that the functions of the map making processor 74 and the supply quantity deriving processor 38 may be covered by the calculation processing function that the system control part 60 of the administrative computer 3 has, and necessary signal transmission and reception may be performed through the LAN system 2.

In the construction of the above-mentioned light emitting element manufacturing system 1, each of the element characteristic measuring device M2 and the resin supplying device M3 is connected to the LAN system 2. Thus, the administrative computer 3 in which the resin supply information 19 is stored in the storage part 61 and the LAN system 2 become a resin information providing unit that provides the information, which makes the appropriate resin supply quantity of the resin 8 to correspond to the element characteristic information to obtain a light emitting element that possesses the prescribed light emission characteristics, as the resin supply information 19 to the resin supplying device M3.

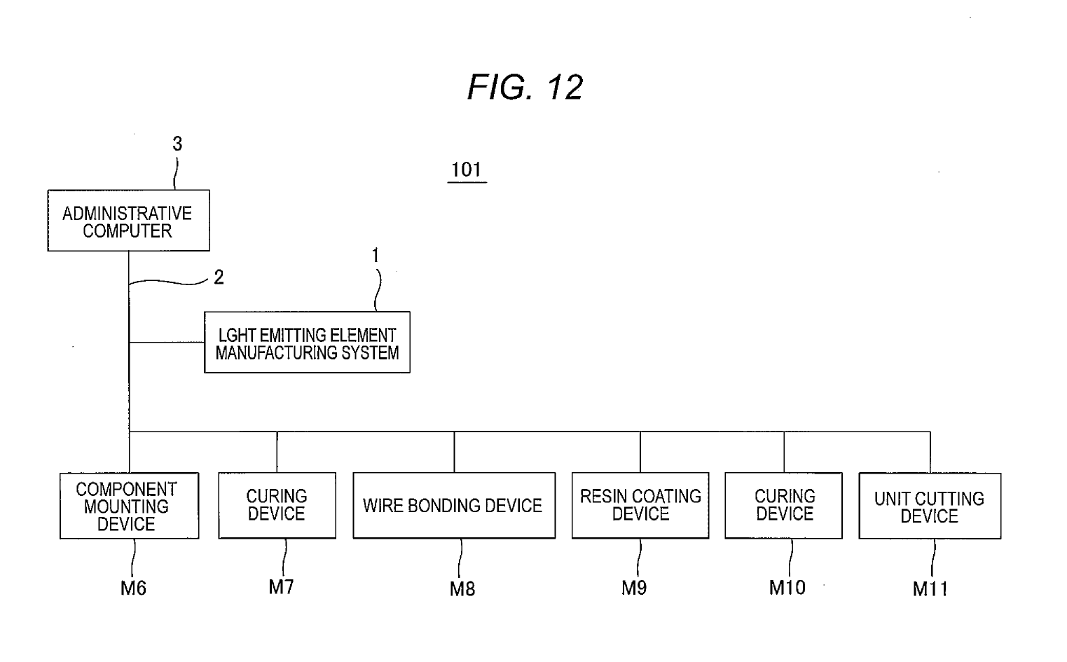

Next, with reference to FIG. 12, the construction of a light emitting element package manufacturing system 101, which manufactures light emitting element packages using the light emitting elements manufactured by the light emitting element manufacturing system 1 is described. The light emitting element package manufacturing system 101 is constructed by combining a component mounting device M6, a curing device M7, a wire bonding device M8, a resin coating device M9, a curing device M10 and a piece-cutting device M11 into the light emitting element manufacturing system 1 of the construction shown in FIG. 1.

The component mounting device M6 mounts light emitting element elements 5* manufactured by the light emitting element manufacturing system 1 by bonding the light emitting elements 5* to a board 14 (refer to FIGS. 13(a) and 13(b)), which becomes a base of LED packages, with resin adhesive. The curing device M7 hardens the resin adhesive, which is used in the bonding at the time of the mounting, by heating the board 14 after the light emitting elements 5* are mounted. The wire bonding device M8 connects electrodes of the light emitting elements 5* to electrodes of the board 14 with bonding wires. The resin coating device M9 coats transparent resin for sealing on each of the light emitting elements 5* on the board 14 after the wire bonding. The curing device M10 hardens the transparent resin, which is coated to cover the light emitting elements 5*, by heating the board 14 after the resin coating. The piece-cutting device M11 cuts the board 14 after the resin is hardened for each of the light emitting elements 5* to separate into individual light emitting element packages. Thereby, the light emitting element packages which are separated into individual pieces are completed.

In FIG. 12, an example in which the devices from the component mounting device M6 to the piece-cutting device M11 are placed in a line to construct a manufacturing line is shown. However, the light emitting element package manufacturing system 101 does not necessarily adopt such a line construction, but may be so constructed that the procedural steps are sequentially performed respectively by the devices that are dispersedly placed. It is also possible to place a plasma processing device which performs a plasma processing for the purpose of cleaning electrodes prior to the wire bonding, and a plasma processing device which performs a plasma processing for the purpose of surface reforming to improve coherency of the resin after the wire bonding and prior to the resin coating, before and after the wire bonding device M8.

With reference to FIGS. 13(a) and 13(b), the board 14, on which operations are performed, the light emitting elements 5* and a light emitting element package 50 as a finished product in the light emitting element package manufacturing system 101, are described. As shown in FIG. 13(a), the board 14 is a multiple-pieces-connected board in which a plurality of individual boards 14a, each of which becomes the base of one light emitting element package 50 in a finished product, are elaborated, and one LED mounting part 14b, where the light emitting element 5* is mounted, is formed on each of the individual boards 14a. The LED package 50 shown in FIG. 13(b) is completed by mounting the light emitting element 5* in the light emitting element mounting part 14b for each of the individual boards 14a, then coating the transparent resin 28 for sealing in the LED mounting part 14b to cover the light emitting element 5*, and, after the resin 28 is hardened, cutting the board 14, whose steps have been completed, for each of the individual boards 14a.

As shown in FIG. 13(b), the individual board 14a is provided with a reflective part 14c of a cavity shape which has, for example, a circular or an elliptic ring-like bank to form the LED mounting part 14b. An N-type part electrode 6a and a P-type part electrode 6b of the light emitting element 5* which is loaded inside the reflective part 14c are connected to wiring layers 14e and 14d which are formed on the top surface of the individual board 14a with bonding wires 27, respectively. The resin 28 is coated at a predetermined thickness inside the reflective part 14c to cover the light emitting element 5* in this state, and white light that is emitted from the light emitting element 5* is irradiated to pass through the transparent resin 28.

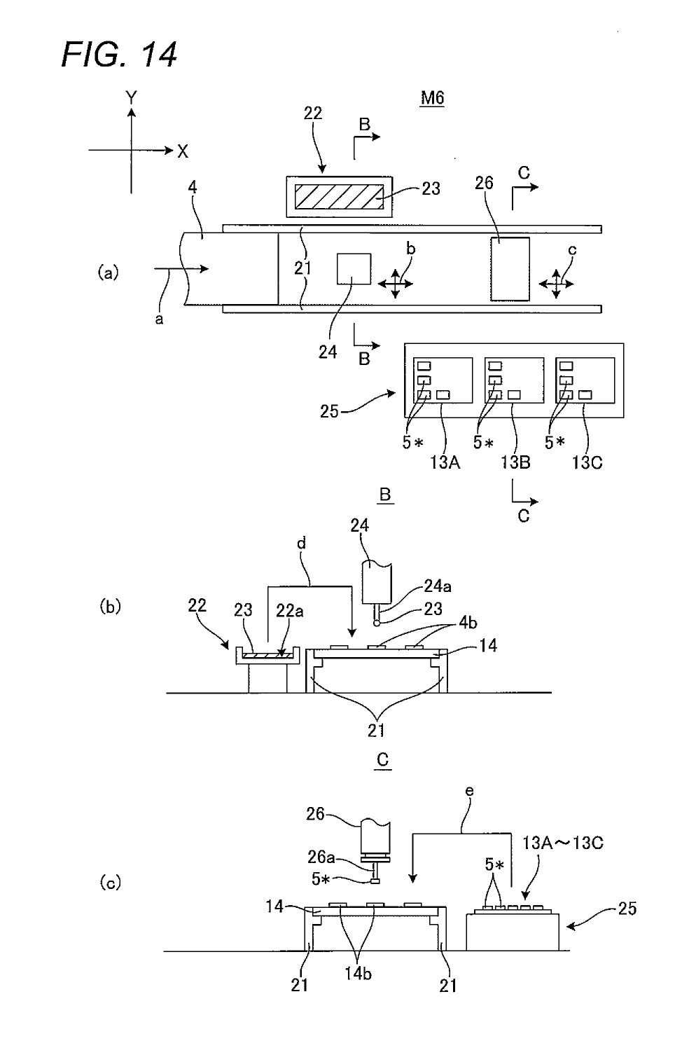

Next, with reference to FIGS. 14(a) to 14(c), a construction and functions of the component mounting device M6 are described. As shown in the top view of FIG. 14(a), the component mounting device M6 includes a board conveying mechanism 21 which conveys a board 14, which is an operation object, supplied from upstream towards the board conveying direction (arrow a). To the board conveying mechanism 21, an adhesive supplying part B shown in FIG. 14(b) with a B-B section, and a component mounting part C shown in FIG. 14(c) with a C-C section are disposed sequentially from upstream. The adhesive supplying part B includes an adhesive supplying part 22 which is placed beside the board conveying mechanism 21, and which supply resin adhesive 23 in the form of a coating of a predetermined film thickness, and an adhesive transferring mechanism 24 which is movable in the horizontal direction (arrow b) above the board conveying mechanism 21 and the adhesive supplying part 22. The component mounting part C includes a component supplying mechanism 25 which is placed beside the board conveying mechanism 21 and which holds the element holding sheets 13A, 13B, 13C and the like as shown in FIG. 10(b), and a component mounting mechanism 26 which is movable in the horizontal direction (arrow c) above the board conveying mechanism 21 and the component supplying mechanism 25.

As shown in FIG. 14(b), the board 14 imported into the board conveying mechanism 21 is positioned in the adhesive supplying part B, and the resin adhesive 23 is supplied on the LED mounting part 14b formed on each of the individual boards 14a. That is, first, by moving the adhesive transferring mechanism 24 to above the adhesive supplying part 22, a transferring pin 24a is made to touch a coating of the resin adhesive 23 formed on a transferring surface 22a, and the resin adhesive 23 is attached. Then, by moving the adhesive transferring mechanism 24 to above the board 14, and dropping the transferring pin 24a to the LED mounting part 14b (arrow d), the resin adhesive 23 which is attached to the transferring pin 24a is supplied to an element mounting position in the LED mounting part 14b with the transferring.

Then, the board 14 after the adhesive is supplied is conveyed downstream and is positioned in the component mounting part C as shown in FIG. 14(c), and a light emitting element 5* is mounted on each of the LED mounting parts 14b after the adhesive is supplied. That is, first, by moving the component mounting mechanism 26 to above the component supplying mechanism 25, and dropping a mounting nozzle 26a relative to either of the element holding sheets 13A, 13B, 13C and the like which are held on the component supplying mechanism 25, and a light emitting element 5* is held and taken out by the mounting nozzle 26a. Then, by moving the component mounting mechanism 26 to above the LED mounting part 14b of the board 14, and dropping the mounting nozzle 26a (arrow e), the light emitting element 5* held in the mounting nozzle 26a is mounted to the element mounting position where the adhesive is supplied in the LED mounting part 14b.

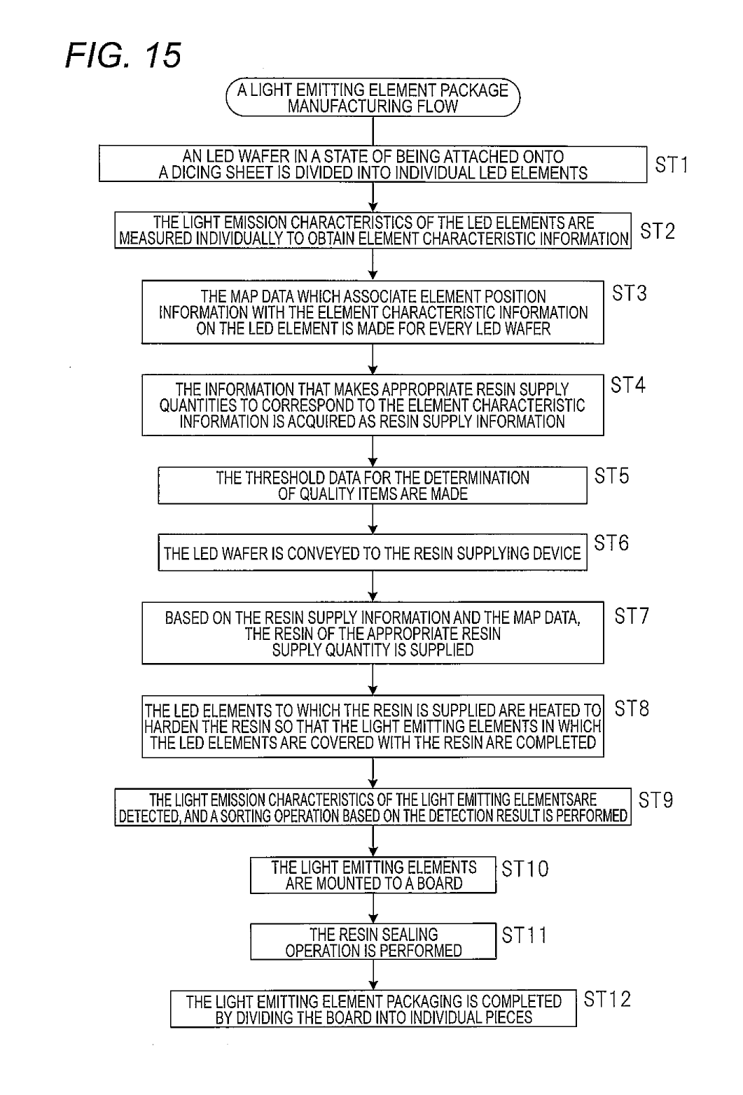

Next, light emitting element package manufacturing processes performed by the light emitting element package manufacturing system 101 are described with reference to the figures along a flow of FIG. 15. Herein, the light emitting element packages 50 which are constructed by mounting light emitting elements 5* in which the top surfaces of LED elements 5 are coated with the resin 8 containing the fluorescent substance beforehand on the board 14 are manufactured.

First, an LED wafer 10, which is an operation object, is imported into the dicing device M1, and as shown in FIG. 3(a), the LED wafer 10 in a state that a plurality of LED elements 5 are elaborated and attached onto a dicing sheet 10a is divided for each of the LED elements 5 (ST1) (dicing step). Then, the LED wafer 10 is imported into the element characteristic measuring device M2, and as shown in FIG. 3(b), an element characteristics measurement is performed. That is, the light emission characteristics of the individually divided LED elements 5 in a state of being attached and held onto the dicing sheet 10a are measured individually to obtain the element characteristic information indicating the light emission characteristics of the LED elements 5 (ST2) (element characteristic measuring step).

Then, map data 18 are made by the map making processor 74 of the element characteristic measuring device M2. That is, the map data 18 (refer to FIG. 4(b)) which associate the element position information indicating the position in the LED wafer 10 of the divided LED element 5 with the element characteristic information on the LED element 5 is made for every LED wafer 10 (ST3) (map data making step). The information that makes appropriate resin supply quantities of the resin 8 to correspond to the element characteristic information to obtain light emitting elements 5* which possess the prescribed light emission characteristics is acquired from the administrative computer 3 through the LAN system 2 as the resin supply information 19 (refer to FIG. 5) (ST4) (resin information acquiring step).

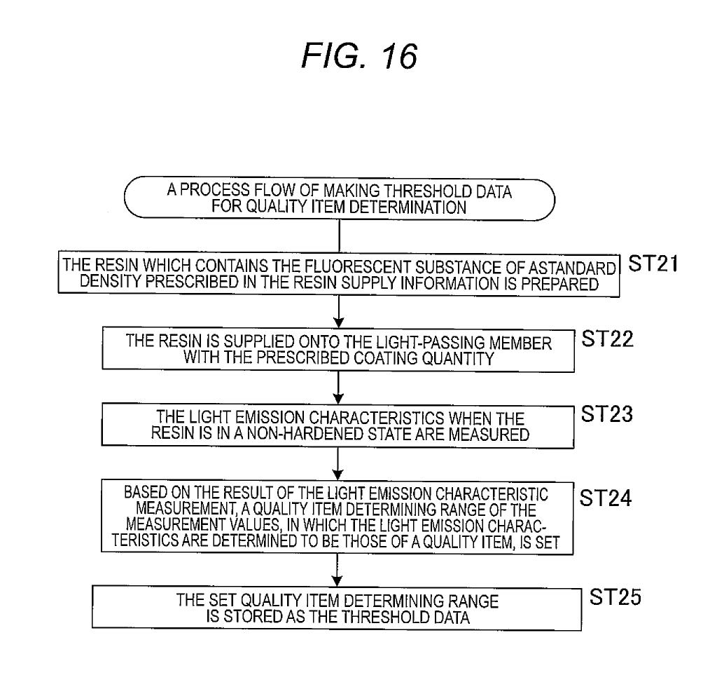

Then, the threshold data making process for the determination of quality items is performed (ST5). This process is performed to set the threshold (refer to the threshold data 81a shown in FIG. 11) to determine whether quality items are obtained in the supplying for production, and is performed repeatedly for the supplying for production corresponding to each of the Bin codes [1], [2], [3], [4] and [5]. The threshold data making process is described in detail with reference to FIGS. 16, 17(a) to 17(c) and 18. In FIG. 16, first, the resin 8 which contains the fluorescent substance of standard densities prescribed in the resin supply information 19 is prepared (ST21).

After having set the resin 8 in the print head 32, the print nozzle unit 32a is moved to the test supplying stage 40a of the test supplying and measuring unit 40, and the resin 8 is supplied onto the light-passing member 43 with the prescribed supply quantity (appropriate resin supply quantity) shown in the resin supply information 19 (ST22). Then, the resin 8 supplied onto the light-passing member 43 is moved onto the light-passing member carrying part 41, the LED element 5 is made to emit light, and the light emission characteristics when the resin 8 is in an unhardened state are measured by the light emission characteristic measuring part of the above-mentioned construction (ST23). Based on light emission characteristic measurement values 39a which are the measurement result of the light emission characteristics measured by the light emission characteristic measuring part, quality item determining ranges of the measurement values, in which the light emission characteristic is determined to be that of a quality item, are set (ST24). The set quality item determining ranges are stored as the threshold data 81a in the storage part 81, and are transferred to the administrative computer 3 and stored in the storage part 61 (ST25).

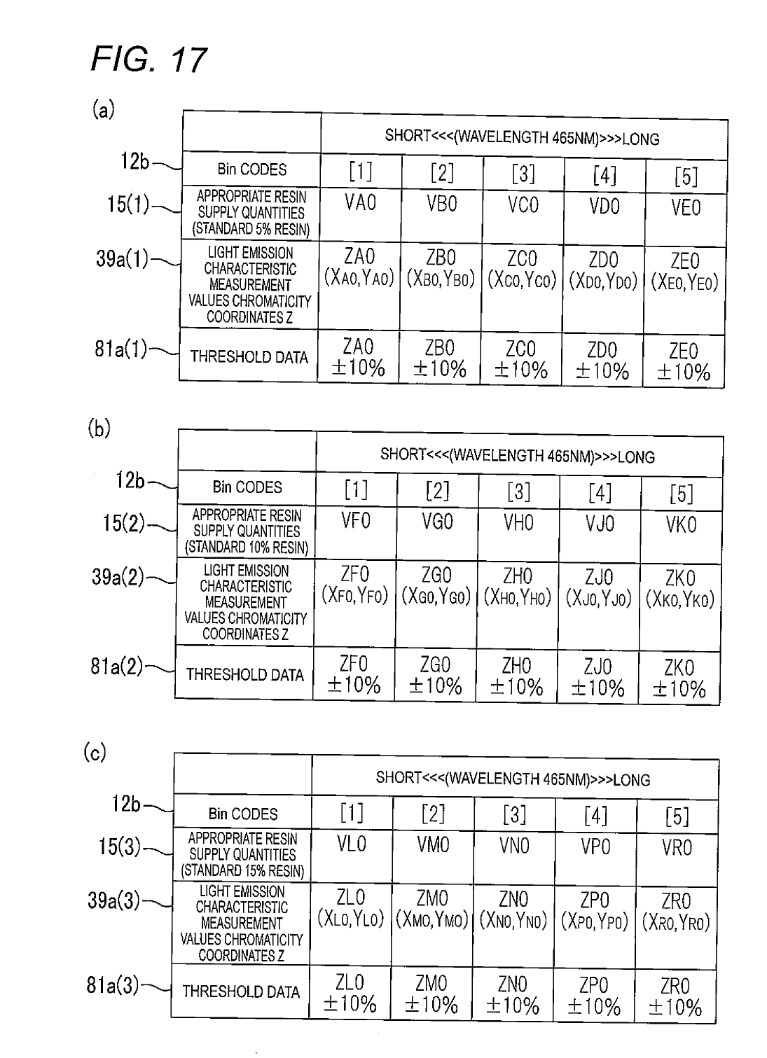

FIGS. 17(a) to 17(c) show the threshold data made in this way, namely, the light emission characteristic measurement values obtained when the resin is in an unhardened state after having supplied the resin 8 that contains fluorescent substance of standard densities, and the quality item determining ranges (the thresholds) of the measurement values to determine whether the light emission characteristic is that of a quality item. FIGS. 17(a), 17(b) and 17(c) show thresholds corresponding to the Bin codes [1], [2], [3], [4] and [5] when the fluorescent substance densities in the resin 8 are 5%, 10% and 15%, respectively.

For example, as shown in FIG. 17(a), when the fluorescent substance density of the resin 8 is 5%, the supply quantity shown in each of the appropriate resin supply quantities 15(1) corresponds to each of the Bin codes 12b, and the measurement results after the light emission characteristics of the light that the resin 8 emits by irradiating blue light of the LED element 5 to the resin 8 coated with each of the supply quantities are measured by the light emission characteristic measuring part are shown in the light emission characteristic measurement values 39a (1). Based on each of the light emission characteristic measurement values 39a (1), the threshold data 81a (1) are set.

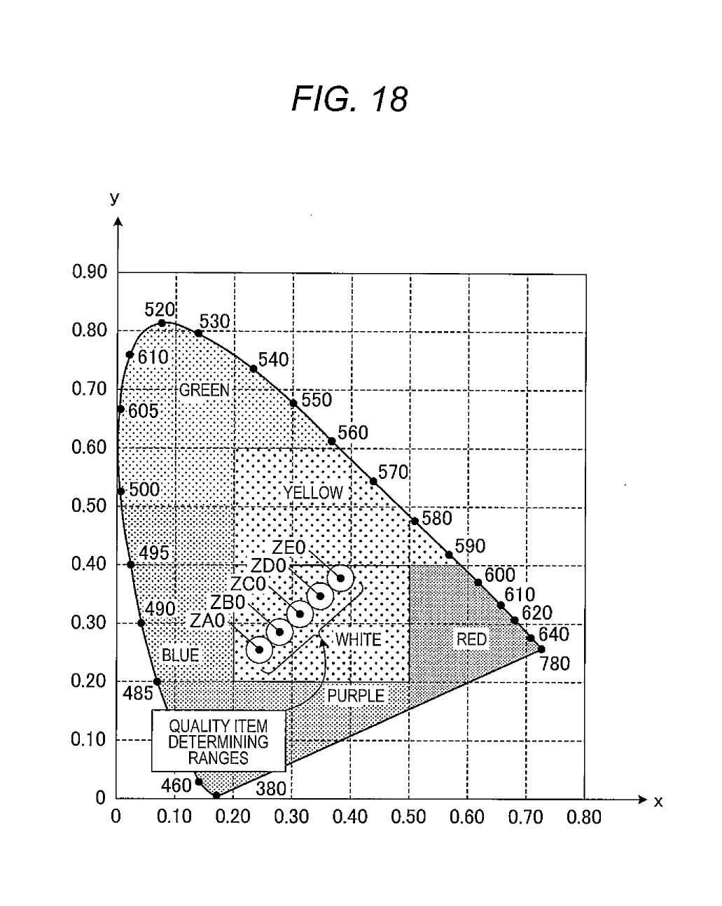

For example, the measurement result after the light emission characteristics of the resin 8 which is supplied with the appropriate resin supply quantity VA0 corresponding to the Bin code [1] are measured is represented by a chromaticity coordinate point ZA0 (XA0, YA0) in the chromaticity table shown in FIG. 18.

Around the chromaticity coordinate point ZA0, a predetermined range of the X coordinate and the Y coordinate in the chromaticity table (for example, +−10%) is set as the quality item determining range (threshold). For the appropriate resin supply quantities corresponding to other Bin codes [2] to [5], similarly, the quality item determining ranges (thresholds) are set based on the light emission characteristic measurement results (refer to the chromaticity coordinate points ZB0 to ZE0 in the chromaticity table shown in FIG. 18). Herein, the predetermined range set as the threshold is appropriately set depending on the demanded precision level of the light emission characteristics of the light emitting element package 50 as a product.

Likewise, FIGS. 17(b) and 17(c) show the light emission characteristic measurement values and the quality item determining ranges (thresholds) when the fluorescent substance densities of the resin 8 are 10% and 15%, respectively. In FIGS. 14(b) and 14(c), the appropriate resin supply quantities 15(2) and the appropriate resin supply quantities 15(3) respectively show the appropriate resin supply quantities when the fluorescent substance densities are 10% and 15%, respectively. The light emission characteristic measurement values 39a (2) and the light emission characteristic measurement values 39a (3) respectively show the light emission characteristic measurement values when the fluorescent substance densities are 10% and 15%, respectively, and the threshold data 81a (2) and the threshold data 81a (3) respectively show the quality item determining ranges (thresholds) when the fluorescent substance densities are 10% and 15%, respectively.

The threshold data made in this way can be used properly in the supplying operation for production based on the Bin code 12b which an LED element 5, on which the coating operation is performed, falls into. The threshold data making process shown in (ST5) may be performed as an off-line operation by an independent detecting device provided separately from the light emitting element package manufacturing system 101, and the threshold data 81a that are stored in the administrative computer 3 beforehand may be transmitted to the resin supplying device M3 via the LAN system 2 and used.

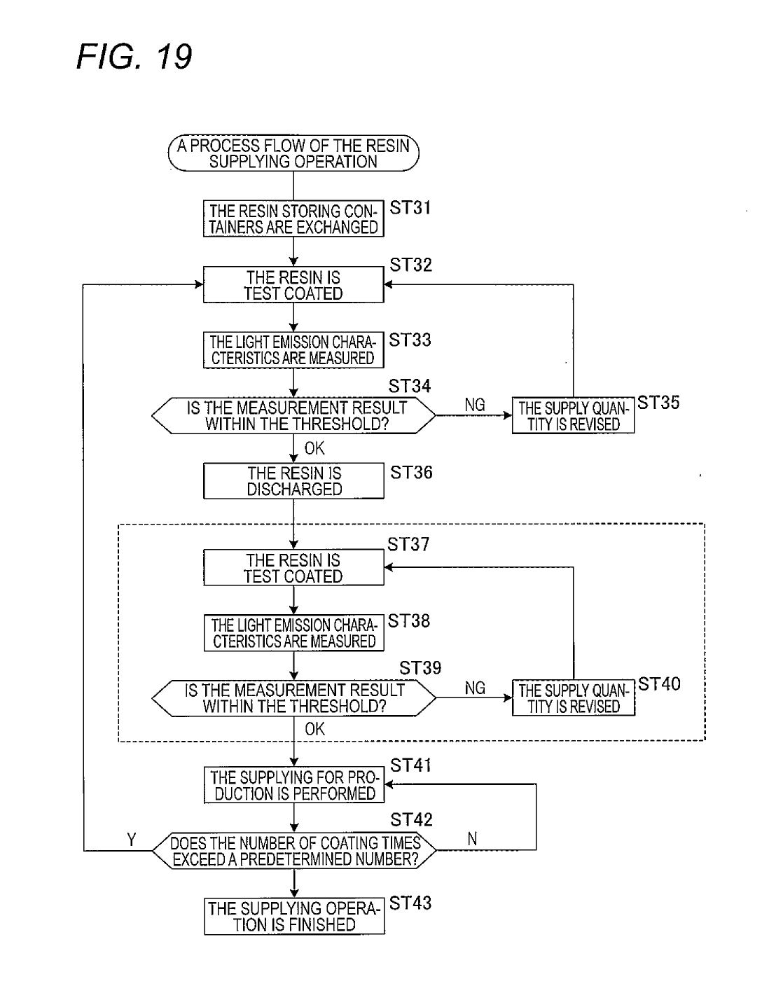

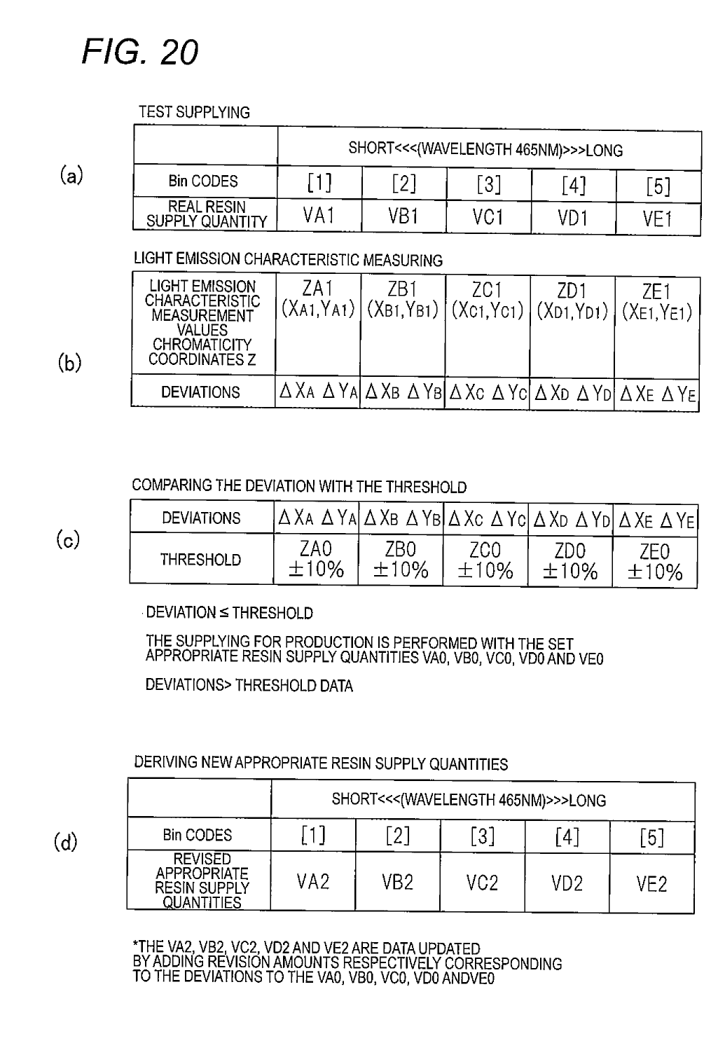

After resin supplying operations become possible in this way, the wafer holder 4 which holds the LED wafer 10 is conveyed to the resin supplying device M3 (ST6). Based on the resin supply information 19 and the map data 18, the resin 8 of the appropriate resin supply quantity to obtain the prescribed light emission characteristics is supplied to each of the LED elements 5 in a wafer state of being attached onto the dicing sheet 10a (ST7) (resin supplying step). The resin supplying operation is described in detail with reference to FIGS. 19 and 20(a) to 20(d).

First, when the resin supplying operation is started, the exchange of resin storing containers is performed as needed (ST31). That is, the resin cartridge mounted into the print head 32 is exchanged with a resin cartridge which accommodates the resin 8 of the fluorescent substance density selected in response to the characteristics of the LED element 5. Then, the resin 8 for light emission characteristic measurement is test supplied on the light-passing member 43 by the resin supplying part A which discharges a variable supply quantity of the resin 8 (supplying step for measurement) (ST32). That is, the resin 8 of the appropriate resin supply quantity (VA0 to VE0) for either of the Bin codes 12b prescribed in the resin supply information 19 shown FIG. 5 is supplied onto the light-passing member 43 which is led out to the test supplying stage 40a in the test supplying and measuring unit 40. At this time, even if the print head 32 is ordered with discharging parameters corresponding to the appropriate resin supply quantity (VA0 to VE0), the real resin supply quantity that is discharged by the print nozzle unit 32a and supplied onto the light-passing member 43 is not necessarily the above appropriate resin supply quantity because, for example, the character of the resin 8 changes over time. As shown in FIG. 20(a), the real resin supply quantity becomes VA1 to VE1 which are somewhat different from VA0 to VE0.

Then, by sending the light-passing member 43 in the test supplying and measuring unit 40, the light-passing member 43, on which the resin 8 is test supplied, is sent and carried on the light-passing member carrying part 41 (light-passing member carrying step). The excitation light to excite the fluorescent substance is emitted from the light source part 45 which is placed above the light-passing member carrying part 41. The light that the resin 8 emits, when the excitation light is irradiated to the resin 8 which is supplied on the light-passing member 43 from above, is received by the spectroscope 42 through the integrating sphere 44 from below the light-passing member 43, and the light emission characteristics of the light are measured by the light emission characteristic measuring processor 39 (light emission characteristic measuring step) (ST33).

Thereby, as shown in FIG. 20(b), the light emission characteristic measurement values represented in chromaticity coordinate points Z (refer to FIG. 18) are provided. This measurement result does not necessarily correspond to the light emission characteristic prescribed beforehand, namely, the standard chromaticity coordinate points ZA0 to ZE0 at the time of supplying the appropriate resin shown in FIG. 17(a) because of, for example, the deviation of the above-mentioned supply quantity and the density change of the fluorescent substance particles of the resin 8. Therefore, the deviations (ΔXA, ΔYA) to (ΔXE, ΔYE) indicating the differences in the X and Y coordinates between the obtained chromaticity coordinate points ZA1 to ZE1 and the standard chromaticity coordinate points ZA0 to ZE0 at the time of supplying the appropriate resin shown in FIG. 17(a) are obtained, and it is determined whether it is necessary to revise to obtain a desired light emission characteristic.

It is determined whether or not the measurement result is within the threshold (ST34). As shown in FIG. 20(c), by comparing the deviations obtained in (ST33) and the thresholds, it is determined whether the deviations (ΔXA, ΔYA) to (ΔXE, ΔYE) are within +−10% of ZA0 to ZE0. If the deviation is within the threshold, the discharging parameters corresponding to the set appropriate resin supply quantities VA0 to VE0 are just maintained. On the other hand, when the deviation exceeds the threshold, the supply quantity is revised (ST35).

That is, the deviation between the measurement result in the light emission characteristic measuring step and the light emission characteristic prescribed beforehand is obtained, and as shown in FIG. 20(d), based on the obtained deviation, a process of deriving new appropriate resin supply quantities (VA2 to VE2) for practical production with which the resin 8 should be supplied onto the LED element 5 is performed by the supply quantity deriving processor 38 (supply quantity deriving step). In other words, by revising the appropriate resin supply quantities based on the measurement result in the light emission characteristic measurement step and the light emission characteristics prescribed beforehand, new appropriate resin supply quantities for practical production are derived.

The revised appropriate resin supply quantities (VA2 to VE2) are values updated by adding revision amounts respectively corresponding to the deviations to the set appropriate resin supply quantities VA0 to VE0. The relation of the deviations and the revision amounts is recorded in the resin supply information 19 as accompanied data known beforehand. Based on the revised appropriate resin supply quantities (VA2 to VE2), the processes of (ST32), (ST33), (ST34) and (ST35) are performed repeatedly. By recognizing that the deviation between the measurement result in (ST34) and the light emission characteristics prescribed beforehand is within the threshold, the appropriate resin supply quantities for practical production are determined. That is, in the above-mentioned resin supplying method, by repeatedly performing the supplying step for measurement, the light-passing member carrying step, the excitation light emitting step, the light emission characteristic measuring step and the supply quantity deriving step, the appropriate resin supply quantities are derived with certainty. The determined appropriate resin supply quantities are stored in the storage part 81 as the supply quantities 81b for practical production.

After this, the flow shifts to the next step to perform the discharging (ST36). By making the resin 8 of the predetermined quantity to be discharged from the print nozzle unit 32a, resin flow state in the resin discharge course is improved, and the movement of the print head 32 is stabilized. The processes of (S37), (ST38), (ST39) and (ST40) shown with a broken line frame in FIG. 19 are performed similarly to the processes shown in (ST32), (ST33), (ST34) and (ST35). The processes of (ST37), (ST38), (ST39) and (ST40) are performed when it is necessary to carefully recognize that a desired light emission characteristic is completely ensured, and are not necessarily items that must be performed.

In this way, if the appropriate resin supply quantity to give the desired light emission characteristic is determined, the supplying operation for production is performed (ST41). That is, when the production performing processor 37 orders the supply control part 36, which controls the print head 32, with the appropriate resin supply quantity that is derived by the supply quantity deriving processor 38 and is stored as the supply quantity 81b for practical production, the supplying process for production, which individually supplies the resin 8 of this appropriate resin quantity on the LED element 5 in a wafer state is performed (production performing step).

In the process of repeatedly performing the supplying process for production, the number of times the print head 32 supplies is counted, and it is monitored whether the number of times of supplying exceeds a predetermined number that is set beforehand (ST42). That is, until this predetermined number is reached, the changes of the characteristic of the resin 8 and the fluorescent substance density are judged to be small, and the supplying process for production (ST41) is repeated while the same supply quantity 81b for practical production is maintained. If it is recognized that the predetermined number is surpassed in (ST42), it is judged that there is a possibility that the character of the resin 8 or the fluorescent substance density changes, and the flow returns to (ST32). Then, the same measurement of the light emission characteristics and the supply quantity revising process based on the measurement result are performed repeatedly.

Next, returning to the flow of FIG. 15, the LED wafer 10 is conveyed to the curing device M4, as shown in FIG. 10(a), the resin 8 is hardened by heating the LED elements 5 to which the resin 8 is supplied (curing step). Thereby, the light emitting elements 5* in which the LED elements 5 are covered with the resin 8 are completed (ST8). In the curing step, instead of heating to harden the resin 8, a method of promoting the hardening by irradiating UV (ultraviolet rays), or a method of just placing the resin as it is to be naturally hardened may be used. Then, the LED wafer 10 which is in a state that the light emitting elements 5* are attached onto the dicing sheet 10a is conveyed to the sorting device M5 where the light emission characteristics of the light emitting elements 5* are detected, and as shown in FIG. 10(b), a sorting operation of separating the light emitting elements 5* based on the detection result is performed (ST9).

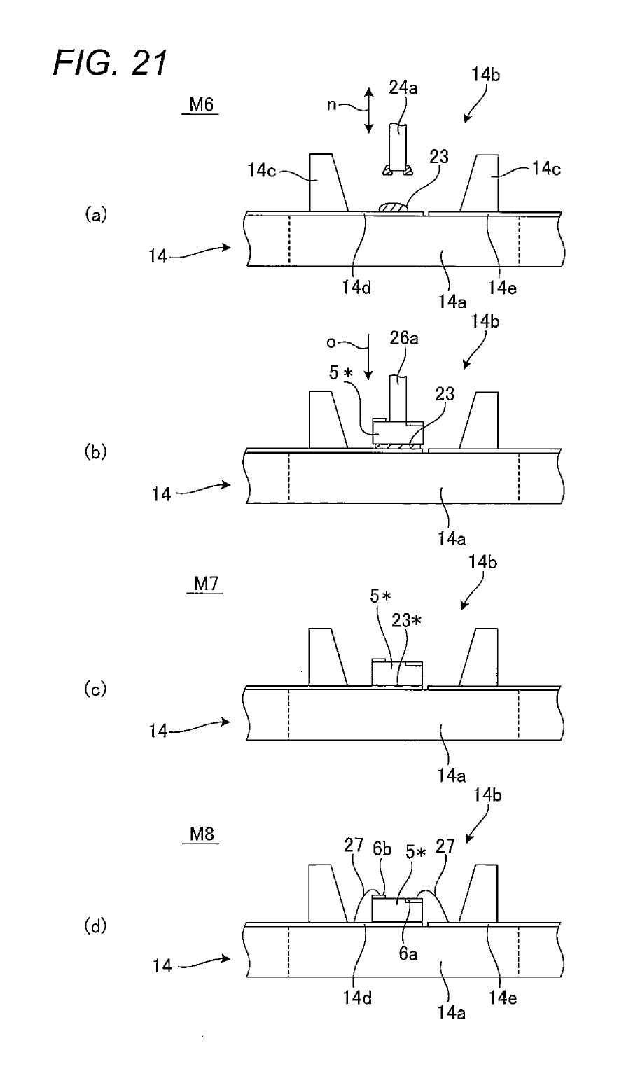

Then, the light emitting elements 5* manufactured in this way are mounted to the board 14 (ST10) (component mounting step). That is, the light emitting elements 5* separated depending on light emission characteristics are sent to the component mounting device M6 in a state of being attached onto the element holding sheets 13A, 13B and the like. After the resin adhesive 23 has been supplied to the element mounting position in the LED mounting part 14b by elevating the transferring pin 24a of the adhesive transferring mechanism 24 (arrow n), as shown in FIG. 21(a), the light emitting element 5* which is held in the mounting nozzle 26a of the component mounting mechanism 26 is dropped (arrow o) and mounted in the LED mounting part 14b of the board 14 through the resin adhesive 23, as shown in FIG. 21(b).

Then, the board 14 after the component mounting is sent to the curing device M7 where the board 14 is heated so that, as shown in FIG. 21(c), the resin adhesive 23 is thermally hardened and becomes the resin adhesive 23* and the light emitting element 5* is adhered to the individual board 14a. Then, the board 14 after the resin curing is sent to the wire bonding device M8, and the wiring layers 14e and 14d of the individual board 14a are connected to the N-type part electrode 6a and the P-type part electrode 6b of the light emitting element 5* with bonding wires 27, respectively, as shown in FIG. 21 (d).

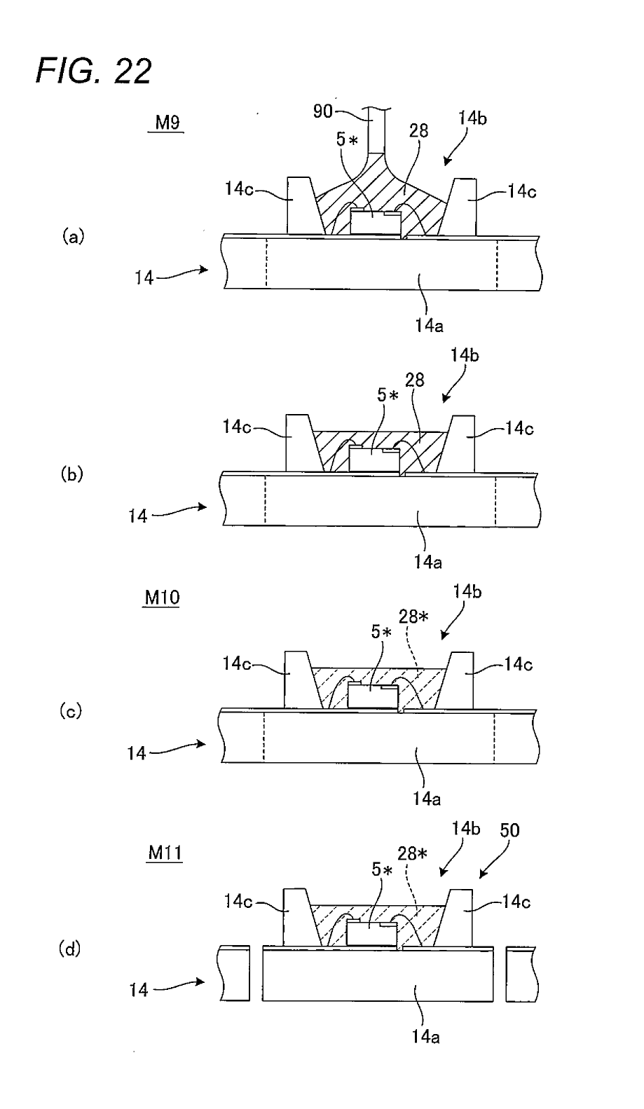

Then, the board 14 after the wire bonding is conveyed to the resin coating device M9, and the resin sealing operation is performed (ST11). That is, as shown in FIG. 22(a), inside the LED mounting part 14b surrounded by the reflective part 14c, the transparent resin 28 for sealing is discharged from a discharging nozzle 90 to cover the light emitting element 5*. When the resin supplying operation on one board 14 is finished in this way, the board 14 is sent to the curing device M10 and the resin 28 is hardened by heating the board 4 (ST9).

Thereby, as shown in FIG. 22(c), the resin 28 which is supplied to cover the light emitting element 5* is thermally hardened to become the solid resin 28*, and seals the light emitting element 5* which is in an adhered state in the LED mounting part 14b. Then, the board 14 after the resin curing is sent to the piece-cutting device M11, and by cutting the board 14 for each of the individual boards 14a, as shown in FIG. 22 (d), the board 4 and the like are divided into individual light emitting element packages 50 (ST10). Thereby, the light emitting element package 50 in which the light emitting element 5*, which is made by covering the LED element 5 with the resin 8, is mounted on the individual board 14a is completed.

As described above, with the light emitting element manufacturing system 1 and the light emitting element package manufacturing system 101 shown in the present embodiment, in manufacturing light emitting elements 5* by coating the top surfaces of LED elements 5 with the resin 8 containing the fluorescent substance, in the resin supplying operation of discharging to supply the resin 8 onto the LED elements 5 in a wafer state, the light emission characteristics of the light that the resin 8 emits when the excitation light from the light source part 45 is irradiated onto the light-passing member 43 on which the resin 8 is test supplied for light emission characteristic measurement are measured, and the appropriate resin supply quantity is revised based on the result of the measurement and the light emission characteristics prescribed beforehand, to derive an appropriate resin supply quantity of the resin 8 which should be supplied to the LED elements for practical production. Therefore, even if the light emission wavelength of the individual LED element 5 varies, by equalizing the light emission characteristics of the light emitting element 5*, production yield can be improved.

Because the resin 8 is supplied onto the LED elements 5 in a wafer state, the area of resin supply objects can be confined. Thereby, in comparison with a related method of supplying resin after having mounted to a board including a plurality of individual boards, the exclusive area of resin supplying devices can be decreased, and the area productivity of manufacturing devices can be improved.

### Embodiment 2

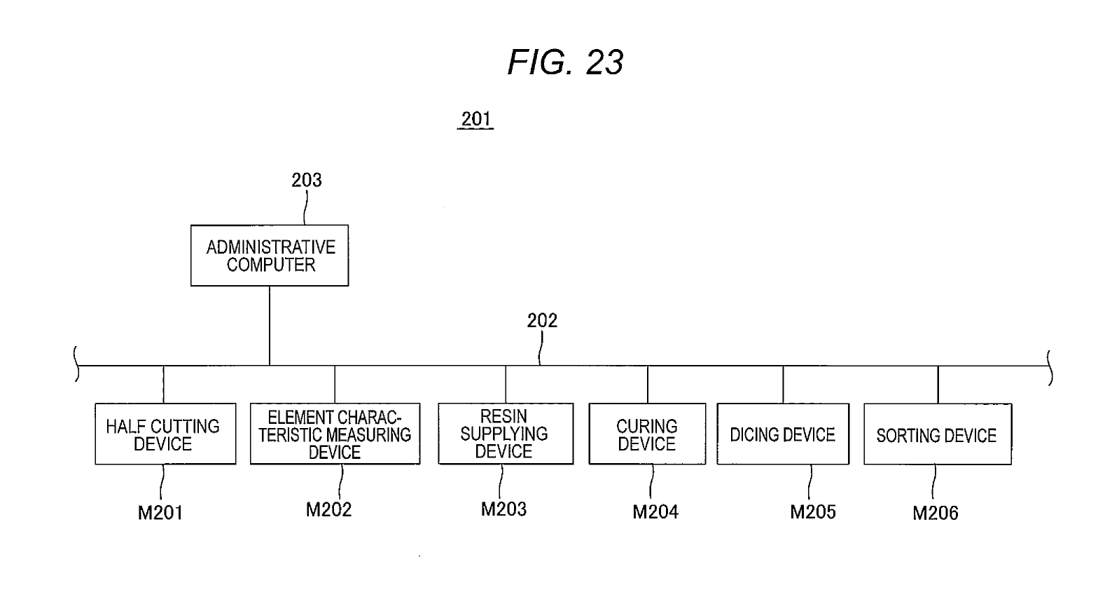

Next, an embodiment 2 of the invention is described with reference to the figures. First, with reference to FIG. 23, the construction of a light emitting element manufacturing system 201 is described. The light emitting element manufacturing system 201 has a function of manufacturing light emitting elements for white illumination which are made by coating the top surface of an LED element that emits blue light with resin including a fluorescent substance that emits yellow excited light whose color is complementary to blue. In this embodiment, as shown in FIG. 23, the LED package manufacturing system 201 is so constructed that each of a half cutting device M201, an element characteristic measuring device M202, a resin supplying device M203, a curing device M204, a dicing device M205 and a sorting device M206 is connected by a LAN system 202, and these devices are collectively controlled by an administrative computer 203.

The half cutting device M20 divides only semiconductor layers constructing LED elements in an LED wafer in which a plurality of LED elements are elaborated and attached onto a dicing sheet into individual LED element pieces. The element characteristic measuring device M202 is an element characteristic measuring part, and performs operations of measuring individually the light emission characteristics of LED elements in a half cut state that only semiconductor layers in a state of being attached and held on a dicing sheet are divided into individual pieces to obtain element characteristic information indicating the light emission characteristics of the LED elements, and making map data which associate the element position information indicating the position in the LED wafer of a divided LED element with the element characteristic information on the LED element for each LED wafer.

The resin supplying device M203, based on the above-mentioned map data, and resin supply information transmitted through the LAN system 202 from the administrative computer 203, namely, the information that makes an appropriate resin supply quantity of the resin containing the fluorescent substance to obtain the LED element that has the regulated light emission characteristics to correspond to the element characteristic information, supplies resin of appropriate resin supply quantities to have the regulated light emission characteristics to the LED elements in a wafer state of being attached onto the dicing sheet. The curing device M204 hardens the resin by heating the LED elements to which the resin is supplied. Thereby, a light emitting element of the construction that the LED element is covered with a resin film of the resin containing the fluorescent substance is formed. The curing device M204, instead of heating to harden the resin, may be constructed to promote the hardening by irradiating UV (ultraviolet rays), or may be constructed to just place the resin as it is to be naturally hardened. The dicing device M205 divides the LED wafer in which the resin is in a hardened state into individual LED elements. The sorting device M206 measures the light emission characteristics of the plurality of light emitting elements attached onto the dicing sheet again, ranks the plurality of light emitting elements into individual predetermined characteristic ranges based on the results of the measurement, and individually transfers to element holding sheets.

In FIG. 23, an example in which the devices from the half cutting device M201 to the sorting device M206 are placed in a line to construct a manufacturing line is shown. However, the light emitting element manufacturing system 201 does not necessarily adopt such a line construction, but may be so constructed that the procedural steps are sequentially performed respectively by the devices that are dispersedly placed, as far as the information communication to be described in the following discussion is suitably performed.

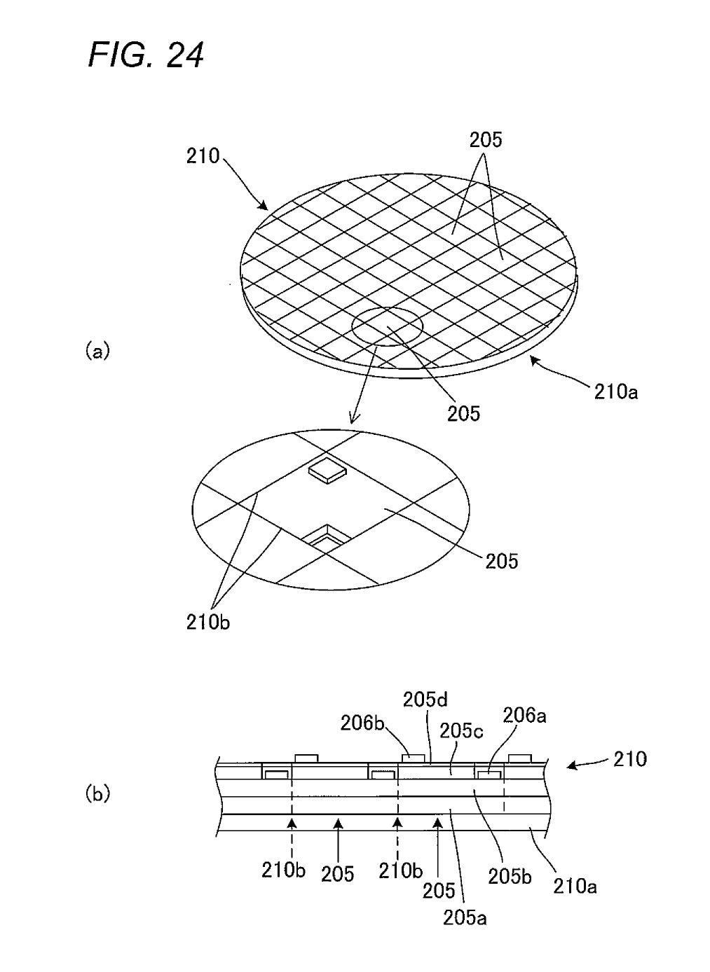

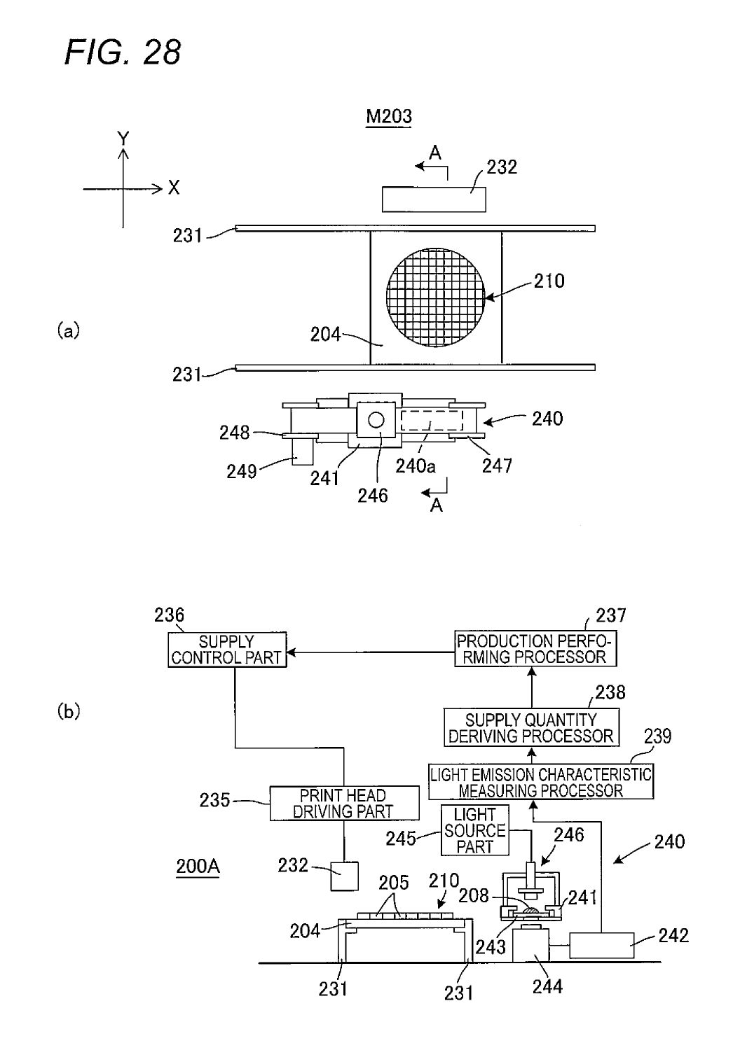

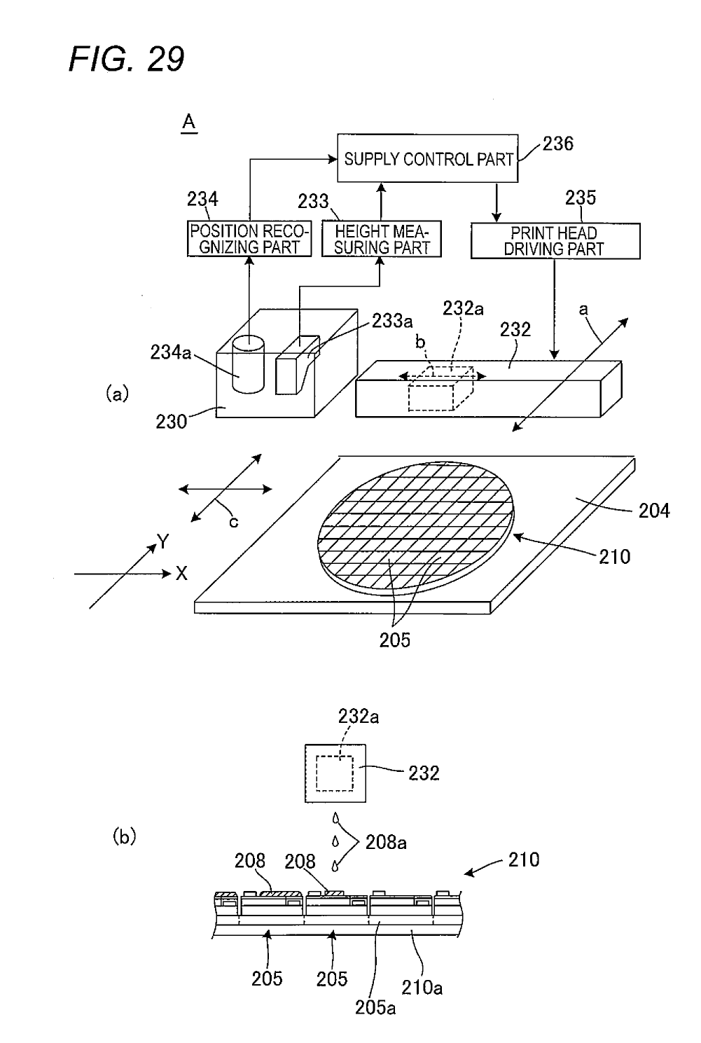

Herein, with reference to FIGS. 24(a) and 24(b), an LED wafer 210 and LED elements 205 on which operations in the light emitting element manufacturing system 201 are performed are described. As shown in FIG. 24(a), in the LED wafer 210, a plurality of LED elements 205 are elaborated in a lattice array, and a dicing sheet 210a is attached onto the under surface of the LED wafer 210. Scribe lines 210b which partition the LED elements 205 are set in the LED wafer 210, and by cutting the LED wafer 210 along the scribe lines 210b, a collection of LED elements 205 in a wafer state that the individual LED elements 205 are held by the dicing sheet 210a is formed. In the steps of the light emitting element manufacturing system 201, in a state that the LED wafer 210 is held within a wafer holder 204 (refer to FIGS. 28(a) to 29(b)), the operations and conveyance are performed.

As shown in FIG. 24(a), the LED element 205 is constructed by laminating an N-type semiconductor 205b and a P-type semiconductor 205c on a sapphire board 205a and covering the surface of the P-type semiconductor 205c with a transparent electrode 205d, and an N-type part electrode 206a and a P-type part electrode 206b for external connections are formed on the N-type semiconductor 205b and the P-type semiconductor 205c, respectively. The LED element 205 is a blue LED, and is adapted to obtain quasi-white light by being combined with resin 208 (refer to FIG. 29(b)) which contains the fluorescent substance that emits yellow fluorescence whose color is complementary to blue. In this embodiment, the resin 208 is supplied by the resin supplying device M203 to the LED elements 205 in the wafer state as described before.

Due to various kinds of deviation factors in the manufacturing process, for example, the variation of the composition at the time of film formation in the wafer, it cannot be avoided that the light emission characteristics, such as light emission wavelength, of the LED elements 205, which are obtained by separating the wafer into individual pieces, vary. When such an LED element 205 is used as a light emitting element for illumination as it is, the light emission characteristics of the final product vary. To prevent the inferior quality due to the variation of the light emission characteristics, in the present embodiment, the light emission characteristics of the plurality of LED elements 205 are measured by the element characteristic measuring device M202 in a wafer state, element characteristic information that makes each of the LED elements 205 to correspond to data indicating the light emission characteristics of the LED element 205 is prepared, and an appropriate quantity of the resin 208 that corresponds to the light emission characteristics of the LED element 205 is supplied in the supply of the resin. To supply the appropriate quantity of the resin 208, resin supply information to be described below is prepared beforehand.

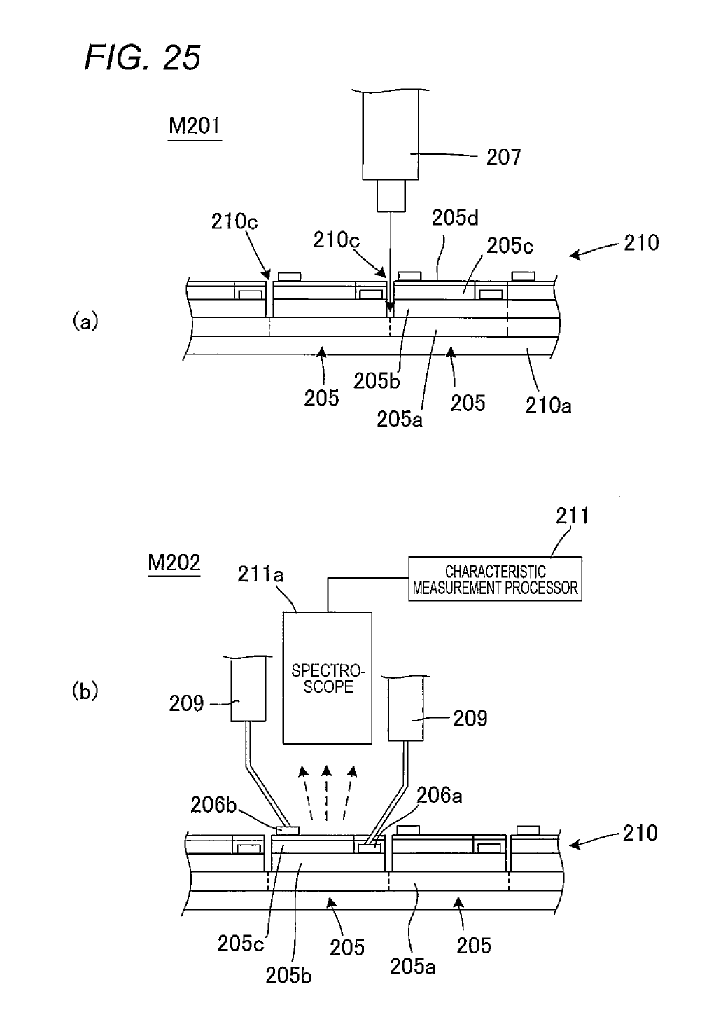

Next, the constructions and functions of the devices constructing the light emitting element manufacturing system 201 are described in the order of steps. First, the LED wafer 210 is sent to the half cutting device M201 as shown in FIG. 25(a). When dicing ditches 210c which reach the interface with the sapphire substrate 205a along the scribe lines 210b are formed in the LED wafer 210 by a laser cutting machine 207, only semiconductor layers of the LED wafer 210 including the transparent electrode 205d, the P-type semiconductor 205c and the N-type semiconductor 205b are divided for each of the LED elements 205. Thereby, circuit patterns formed in the LED wafer 210 are divided in the unit of LED element 205, and it becomes possible that each of the LED elements 205 is electrically functionalized individually. Various methods can be used as the unit of the half cutting. For example, except that the transparent electrode 205d, the P-type semiconductor 205c and the N-type semiconductor 205b are removed with a laser beam, methods such as a method of mechanically cutting only these layers with a dicing saw can be used.

Next, as shown in FIG. 25(b), the LED wafer 210 after the half cutting is sent to the element characteristic measuring device M202 where element characteristics indicating the light emission characteristics of the LED element 205 are measured. That is, while a spectroscope 211a is located right above an LED element 205 to be measured among the plurality of LED elements 205 after the half cutting in a wafer state of being attached and held onto the dicing sheet 210a, by making probes of a power supply device 209 touch the N-type part electrode 206a and the P-type part electrode 206b of the LED element 205, power is supplied to the N-type semiconductor 205b and the P-type semiconductor 205c to emit light. Then, a spectroscopic analysis of the light is performed to measure prescribed items such as light emission wavelength or light emission intensity, and the result of the measurement is processed by a characteristic measurement processor 211 so that element characteristic information indicating the light emission characteristics of the LED element 205 is obtained. This element characteristic measurement is performed sequentially for all the LED elements 205 constructing the LED wafer 210.

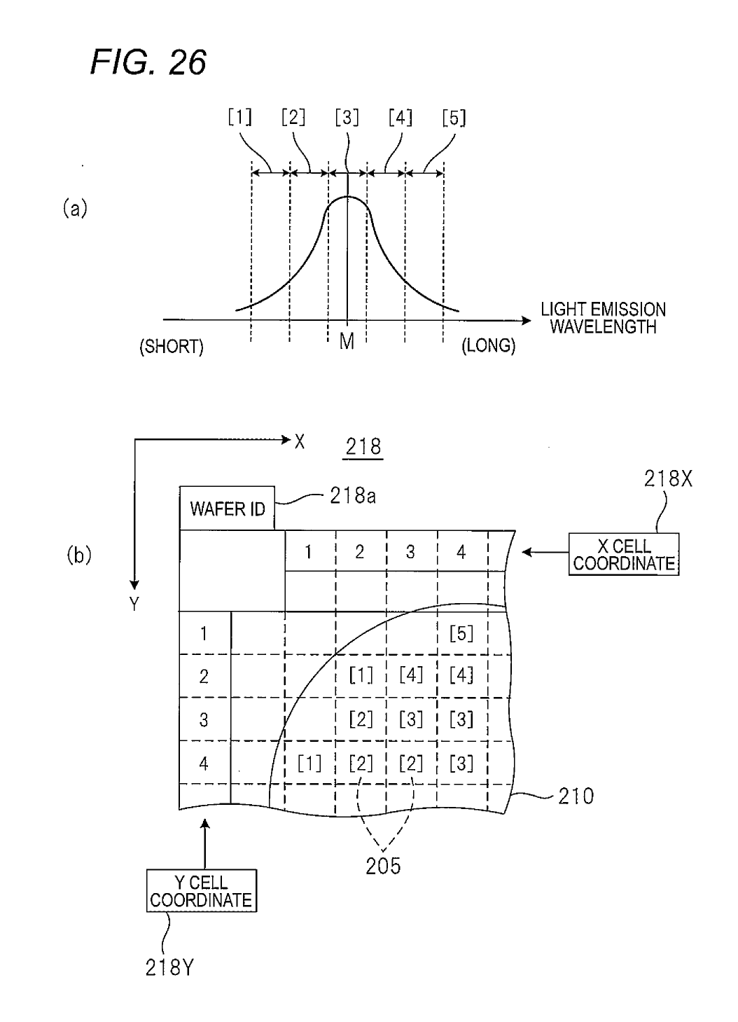

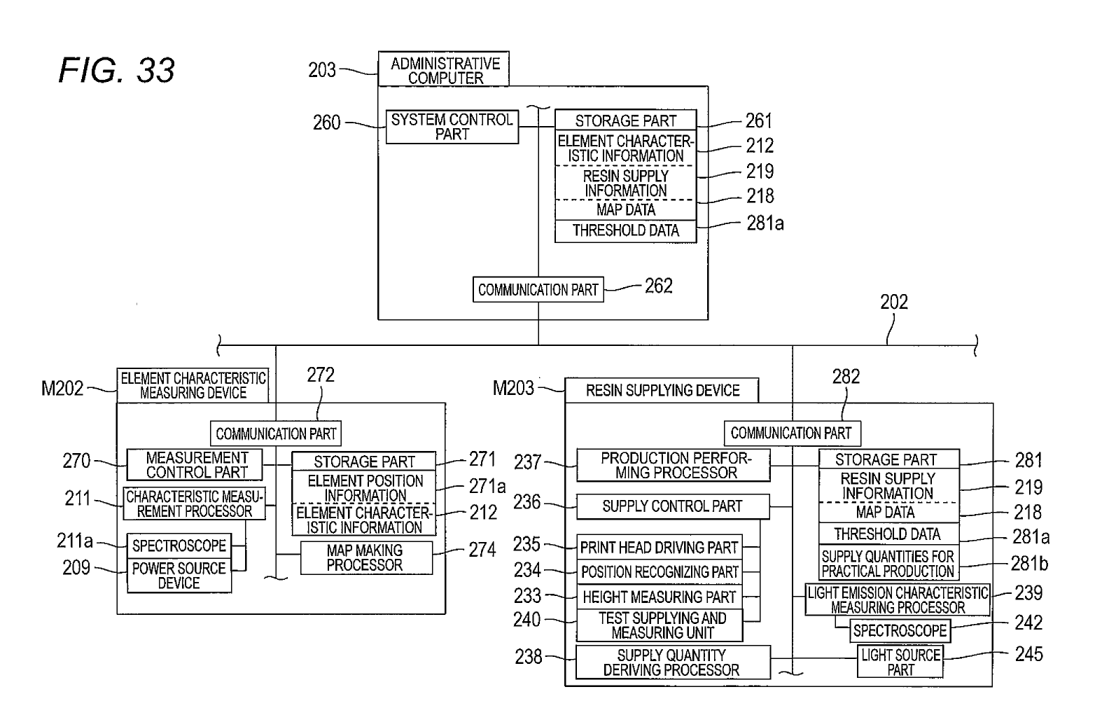

Next, the element characteristic information is described with reference to FIGS. 26(a) and 26(b). FIG. 26(a) show a standard distribution of light emission wavelength which is prepared beforehand as reference data for the LED elements 205 to be measured. By dividing a wavelength range that corresponds to the standard range in the distribution into a plurality of wavelength areas, the measured plurality of LED elements 205 are ranked by light emission wavelength. Herein, in response to each of the ranks that are set by dividing the wavelength range into five, Bin codes [1], [2], [3], [4] and [5] are given sequentially from the side of low wavelength. Based on the measurement result of the element characteristic measuring device M202, Bin codes are given to individual LED elements 205, and are stored as element characteristic information 212 in the storage part 271 (FIG. 33).

FIG. 26(b) shows map data 218 which associate the element position information indicating the position in the LED wafer 210 of a divided LED element 205 with the element characteristic information 212 on the LED element 205. Herein, an X cell coordinate 218X and a Y cell coordinate 218Y in a matrix array of the LED elements 205 in the LED wafer 210 are used as the element position information. That is, the map data 218 are constructed to make one of the Bind codes [1], [2], [3], [4] and [5] which is given to an individual LED element 205 based on the measurement result of the element characteristic measuring device M202 to correspond to the individual LED element 205 that is identified by the element position information, and by specifying a wafer ID 218a, the map data 218 of each of the individual LED wafers 210 can be read out.

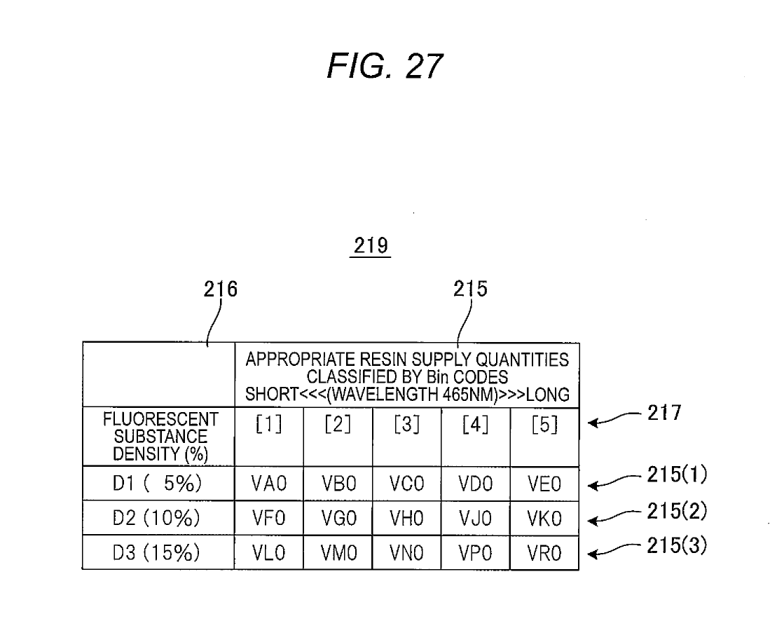

Then, the resin supply information prepared beforehand in response to the above-mentioned element characteristic information 212 is described with reference to FIG. 27. In the light emitting element of the construction to obtain white light by combining a YAG-related fluorescent substance with a blue LED, because the blue light that the LED element 205 emits is added and mixed with the yellow light that the fluorescent substance emits by being excited by the blue light, the quantity of the fluorescent substance particles in the resin film which covers the top surface of the LED element 205 becomes an important factor in ensuring the normal light emission characteristics of a finished light emitting element.

As mentioned above, because there are variations classified by the Bin codes [1], [2], [3], [4] and [5] in the light emission wavelengths of a plurality of LED elements 205 which become operation objects at the same time, the appropriate quantities of the fluorescent substance particles in the resin 208 supplied to cover the LED elements 205 differ based on the Bin codes [1], [2], [3], [4] and [5]. In this embodiment, as shown in FIG. 27, in the prepared resin supply information 219, appropriate resin supply quantities, classified based on the Bin codes, of the resin 208 which makes YAG-related fluorescent substance particles to be contained in, for example, silicone resin or epoxy resin are prescribed in nl (nanoliters) beforehand based on Bin code divisions 217. That is, when an appropriate resin supply quantity, shown in the resin supply information 219, of the resin 208 is supplied precisely to cover the LED element 205, the quantity of fluorescent substance particles in the resin covering the LED element 205 becomes an appropriate supply quantity of fluorescent substance particles, and thereby a normal light emission wavelength that is demanded is ensured in a finished product after the resin is thermally hardened.

Herein, as shown in a fluorescent substance density column 216, a plurality of fluorescent substance densities (herein, three densities, or D1 (5%), D2 (10%) and D3 (15%)) indicating the density of fluorescent substance particles of the resin 208 are set, and the appropriate resin supply quantities are set to different numerical values which are used based on the fluorescent substance density of the used resin 208. That is, when the resin 208 of the fluorescent substance density D1 is supplied, for the Bin codes [1], [2], [3], [4] and [5], the resin 208 of appropriate resin supply quantities VA0, VB0, VC0, VD0 and VE0 (appropriate resin supply quantities 215(1)) are supplied respectively. Likewise, when the resin 208 of the fluorescent substance density D2 is supplied, for the Bin codes [1], [2], [3], [4] and [5], the resin 208 of appropriate resin supply quantities VF0, VG0, VH0, VJ0 and VK0 (appropriate resin supply quantities 215(2)) are supplied respectively. Further, when the resin 208 of the fluorescent substance density D3 is supplied, for the Bin codes [1], [2], [3], [4] and [5], the resin 208 of appropriate resin supply quantities VL0, VM0, VN0, VP0 and VR0 (appropriate resin supply quantities 215(3)) are supplied respectively. In this way, the appropriate resin supply quantities are set respectively for the plurality of fluorescent substance densities which are different, and this is because supplying the resin 208 of the most suitable fluorescent substance density based on the degree of the variation of the light emission wavelength is preferable for quality insurance.

Next, with reference to FIGS. 28(a) to 29(b), a construction and functions of the resin supplying device M203 are described. The resin supplying device M203 has a function of individually supplying the resin 208 to the plurality of LED elements 205 in a half cut state which are half cut by the half cutting device M201 and whose element characteristics are measured by the element characteristic measuring device M202. As shown in a top view of FIG. 28(a), the resin supplying device M203 is constructed by disposing a resin supplying part 200A, which is shown in FIG. 28(b) with an A-A section, on a conveying mechanism 231 which conveys a wafer holder 204 that holds an LED wafer 210 which is an operation object.

In this embodiment, a resin discharging device which discharges the resin 208 in an inkjet manner is used as the resin supplying part 200A. That is, the resin supplying part 200A is provided with a print head 232 whose longitudinal direction is towards the X direction (conveying direction in the conveying mechanism 231). As shown in FIGS. 29(a) and 29(b), the print head 232 is provided with a built-in print nozzle unit 232a which discharges to supply a small droplet 208a of the resin 208 downwards in such a way that the discharging quantity is controllable, and when the print head 232 is driven by a print head driving part 235, the print head 232 is moved in the Y direction (arrow a) to above the LED wafer 210 which is held in the wafer holder 204, and the print nozzle unit 232a is moved in the X direction (arrow b) in the print head 232. When the print head driving part 235 is controlled by a supply control part 236, the print nozzle unit 232a is moved to an arbitrary position in the X direction and in the Y direction, and the discharging quantity of the small droplet 208a from the print nozzle unit 232a can be controlled.

A measuring head 230 including a camera 234a and a height measuring unit 233a is disposed beside the print head 232 to be movable in the X and Y directions (arrow c). When the measuring head 230 is moved to above the LED wafer 210 which is held in the wafer holder 204, and an image which is acquired by imaging the LED wafer 210 with the camera 234a is recognized by a position recognizing part 234, the position of an individual LED element 205 in the LED wafer 210 is recognized. The position recognition result is transmitted to the supply control part 236.

By aligning the height measuring unit 233a with a surface to be measured to perform a distance measuring operation with a laser beam, the height of the surface to be measured is measured. Herein, the top surface of the LED element 205 before the small droplet 208a is supplied by the print nozzle unit 232a becomes the surface to be measured, and the height measurement result by the height measuring part 233 is transmitted to the supply control part 236. When the small droplet 208a is supplied by the print nozzle unit 232a, the supply control part 236 performs a height measurement on the top surface of the LED element 205 with the height measuring part 233. When the print head 232 is controlled by the supply control part 236 in this way, as shown in FIG. 29(b), the small droplet 208a is discharged from the print nozzle unit 232a, and the resin 208 of an appropriate resin supply quantity prescribed in the resin supply information 219 is supplied to the top surface of each of the LED elements 205 of the LED wafer 210 in a half cut state. That is, the resin supplying part 200A has functions of discharging a variable supply quantity of the resin 208, and supplying the resin 8 at any supply positions.

Beside the conveying mechanism 231, a test supplying and measuring unit 240 is placed in the movement range of the print head 232. The test supplying and measuring unit 240 has a function of determining whether the supply quantity of the resin 208 is appropriate before a supplying operation for practical production of supplying the resin 208 to the LED elements 205 of the LED wafer 210, by measuring the light emission characteristics of the resin 208 which is test supplied. That is, light emission characteristics when a light that a light source part 245 for measurement emits is irradiated on a light-passing member 243 where the resin 208 is test supplied by the resin supplying part 200A are measured by a light emission characteristic measuring part which includes a spectroscope 242 and a light emission characteristic measuring processor 239, and by comparing the measurement result with a threshold set beforehand, it is determined whether the set resin supply quantity prescribed in the resin supply information 219 shown in FIG. 27 is appropriate.

The composition and characteristic of the resin 208 containing fluorescent substance particles are not necessarily stable, and even if the appropriate resin supply quantities are set in the resin supply information 219 beforehand, it cannot be avoided that the density and the resin viscosity of the fluorescent substance fluctuate over time. Therefore, even if the resin 208 is discharged according to discharging parameters corresponding to the appropriate resin supply quantities set beforehand, it is possible that the resin supply quantity itself varies from the set appropriate value, or the resin supply quantity itself is appropriate but the supplied quantity of the fluorescent substance particles varies from what should be originally supplied due to density change.

In order to solve these problems, in the embodiment, a test supply for the purpose of detecting whether an appropriate supply quantity of fluorescent substance particles is supplied is performed by the resin supplying device M203 in a predetermined interval, and by performing the measurement of the light emission characteristic of the resin which is test supplied, the supply quantity of the fluorescent substance particles which meets the requirement of the original light emission characteristics is stabilized. Thus, the resin supplying part 200A included in the resin supplying device M203 shown in the present embodiment has a function of performing a supplying process for measurement in which the resin 208 is test supplied to the light-passing member 243 for the above-mentioned light emission characteristic measurement, in addition to a supplying process for production in which the resin 208 is supplied to a plurality of LED elements 205 in a wafer state of being held in the wafer holder 204 for practical production. Either of the supplying process for measurement and the supplying process for production is performed when the resin supplying part 200A is controlled by the supply control part 236.

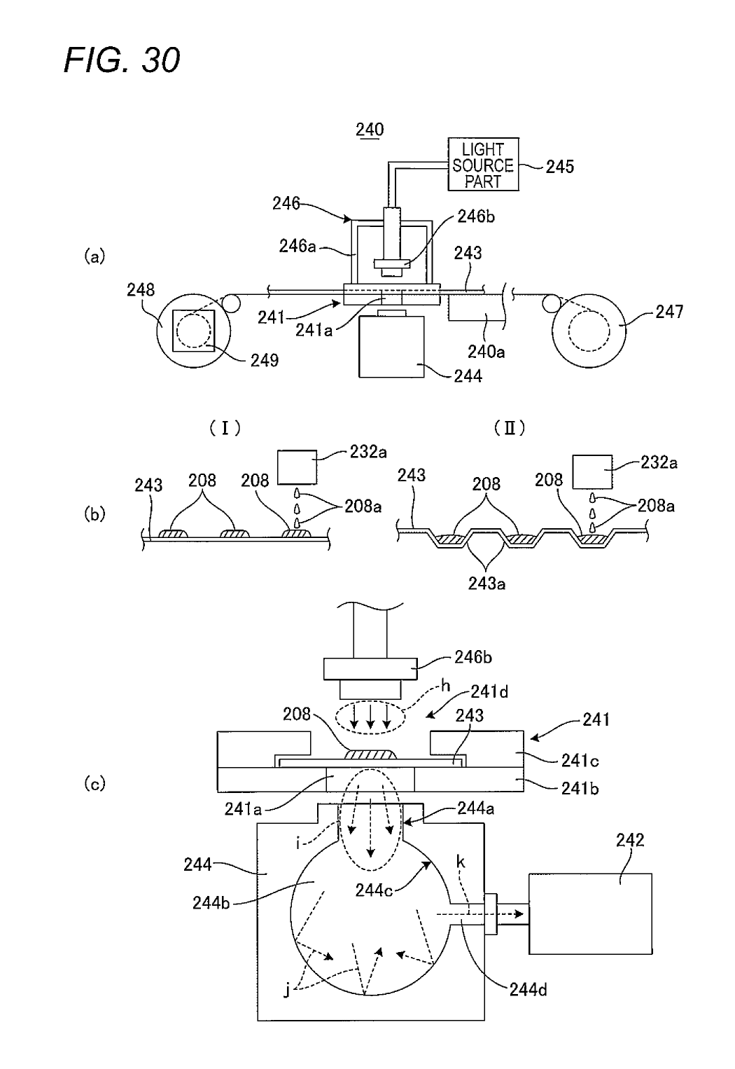

With reference to FIGS. 30(a) to 8(c), the detailed construction of the test supplying and measuring unit 240 is described. As shown in FIG. 30(a), the light-passing member 243 is supplied by being wound and accommodated in a supply reel 247, and after the light-passing member 43 is sent along the top surface of a test supplying stage 240a, the light-passing member 43 passes between a light-passing member carrying part 241 and an irradiating part 246, and is wound into a collecting reel 248 which is driven by a winding motor 249. Besides the collecting method of winding back into the collecting reel 248, various methods including a sending method in which the light-passing member 243 is sent into a collecting box by a sending mechanism can be adopted as a mechanism for collecting the light-passing member 243.

The irradiating part 246 has a function of irradiating measurement light emitted by the light source part 245 onto the light-passing member 243, and is constructed by disposing a light converging tool 246b, in which the measurement light which the light source part 45 emits is guided by fiber cables, in a shading box 246a which has the function of a simple dark box. The light source part 245 has a function of emitting excitation light to excite the fluorescent substance contained in the resin 208. In the present embodiment, the light source part 45 is placed above the light-passing member carrying part 241, and irradiates the measurement light to the light-passing member 243 from above through the light converging tool 246b.

Herein, tape material of a predetermined width formed of a planar sheet member of transparent resin, or the above tape material in which embossed parts 243a are protruded downwards from the bottom surface (emboss type), or the like are used as the light-passing member 243 (refer to FIG. 30(b)). In the process of sending the light-passing member 243 on the test supplying and measuring unit 240, the resin 208 is test supplied by the print head 232 onto the light-passing member 243. This test supply is performed as shown in FIG. 30(b), in which a prescribed supply quantity of the resin 208 in a form of the small droplet 208a is discharged (printed) by the print nozzle unit 232a to the light-passing member 243 which is supported by the test supplying stage 240a from below.

(I) of FIG. 30(b) shows that the resin 208 of the set appropriate discharging quantity prescribed in the resin supply information 219 is supplied onto the light-passing member 243 formed of the above-mentioned tape material. (II) of FIG. 30(b) shows that the resin 208 of the set appropriate discharging quantity is supplied similarly in the embossed parts 243a of the light-passing member 243 formed of the above-mentioned emboss type tape material. As described later, because the resin 208 which is supplied onto the test supplying stage 240a is test supplied to empirically determine whether the fluorescent substance supply quantity to the LED element 205 is appropriate, when the resin 208 is continuously supplied onto the light-passing member 243 at a plurality of points by the print head 232 with the same test supply movement, the supplying is performed by making the supply quantities to be different progressively based on the known data indicating the correlation of light emission characteristic measurement and the supply quantity.

After the resin 208 is test supplied in this way, white light emitted by the light source part 245 is irradiated from above through the light converging tool 246b to the light-passing member 243 which is led in the shading box 246a. The light that passes the resin 208 which is supplied onto the light-passing member 243 is received by an integrating sphere 244, which is disposed below the light-passing member carrying part 241, through a light-passing opening 241a which the light-passing member carrying part 241 is provided with. FIG. 30(c) shows structures of the light-passing member carrying part 241 and the integrating sphere 244. The light-passing member carrying part 241 is so constructed that an upper guide member 241c having a function of guiding two end surfaces of the light-passing member 243 is installed on the top surface of a lower support member 241b which supports the under surface of the light-passing member 243.

The light-passing member carrying part 241 has functions of guiding the light-passing member 243 at the time of conveying in the test supplying and measuring unit 240, and carrying and maintaining the position of the light-passing member 243 on which the resin 208 is test supplied in the supplying process for measurement. The integrating sphere 244 has functions of integrating the transmitted light which is irradiated from the light converging tool 246b (arrow h), and passes through the resin 208, and leading to the spectroscope 242. That is, the integrating sphere 244 has a spherical reflecting surface 244c inside, and the transmitted light (arrows i) which enters from an opening 244a located right under the light-passing opening 241a is incident in a reflection space 244b from the opening 244a which is provided at the top of the integrating sphere 244, leaves from an output part 244d as the measurement light (arrow k) in a process of repeating total reflection (arrows j) with the spherical reflecting surface 244c, and is received by the spectroscope 242.

In the above-mentioned construction, the white light emitted by a light emitting element package used for the light source part 245 is irradiated to the resin 208 which is test supplied onto the light-passing member 243. In this process, the blue light components included in the white light excites the fluorescent substance in the resin 208 to emit yellow light. The white light in which this yellow light and the blue light are added and mixed is irradiated upwards from the resin 208, and is received by the spectroscope 242 through the above-mentioned integrating sphere 244.

The received white light is analyzed by the light emission characteristic measuring processor 239 (FIG. 28(b)) to measure the light emission characteristics. Light emission characteristics such as color tone rank or beam of the white light are detected, and, as a detection result, deviations from prescribed light emission characteristics are detected out. The integrating sphere 244, the spectroscope 242 and the light emission characteristic measuring processor 239 construct a light emission characteristic measuring part which measures light emission characteristics of the light that the resin 208 emits when the excitation light (herein, white light emitted by a white LED) emitted by the light source part 245 is irradiated from above to the resin 208 which is supplied onto the light-passing member 243 by receiving the light that the resin 208 emits from below the light-passing member 243. In the present embodiment, the light emission characteristic measuring part is constructed by placing the integrating sphere 244 below the light-passing member 243 so that the light that the resin 208 emits is received through the opening 244a of the integrating sphere 244.

The effects that are described below are obtained by constructing the light emission characteristic measuring part as above. That is, for the supply shape of the resin 30 which is test supplied onto the light-passing member 243 shown in FIG. 208(b), because the bottom side always contacts with the top surface of the light-passing member 243 or the bottom surfaces of the embossed parts 243a, the bottom surface of the resin 208 always has a standard height that is prescribed by the light-passing member 243. Therefore, the height difference between the bottom surface of the resin 208 and the opening 244a of the integrating sphere 244 is always kept constant. On the other hand, for the top surface of the resin 208, due to disturbance such as supply condition of the print nozzle unit 232a, the same liquid surface shape and height may not be necessarily realized, and the interval between the top surface of the resin 208 and the light converging tool 246b will vary.

If stability is considered when the irradiation light irradiated to the top surfaces of the resin 208 and the transmitted light from the under surfaces of the resin 208 are compared, because the irradiation light irradiated to the resin 208 is irradiated through the light converging tool 246b, the convergence degree is high, and the influence that the variation in the intervals between the top surfaces of the resin 208 and the light converging tool 246b has on the light transmission can be ignored. On the other hand, because the transmitted light which passes through the resin 208 is the excited light because the fluorescent substance is excited inside the resin 208, the divergence degree is high, and the influence that the variation in the distances between the under surfaces of the resin 208 and the opening 244a has on the degree to which light is taken in by the integrating sphere 244 cannot be ignored.

In the test supplying and measuring unit 240 shown in the present embodiment, because such a construction is adopted that the light that the resin 208 emits when the excitation light emitted by the light source part 245 as constructed above is irradiated from above to the resin 208 is received by the integrating sphere 244 from below the light-passing member 243, it is possible to determine stable light emission characteristics. By using the integrating sphere 244, it is not necessary to separately provide a darkroom structure in the light receiving part, and it is possible to compactify the device and to reduce the device cost.

As shown in FIG. 28(b), the measurement result of the light emission characteristic measuring processor 239 is sent to a supply quantity deriving processor 238, and the supply quantity deriving processor 238 revises the appropriate resin supply quantity of the resin 208 based on the measurement result of the light emission characteristic measuring processor 239 and the light emission characteristics prescribed beforehand, and derives the appropriate resin supply quantity of the resin 208 which should be supplied onto the LED element 205 as what is used for practical production. The new appropriate discharging quantity derived by the supply quantity deriving processor 238 is sent to a production performing processor 237, and the production performing processor 237 orders the supply control part 236 with the newly derived appropriate resin supply quantity. Thereby, the supply control part 236 controls the print head 232 to make the print head 232 perform a supplying process for production to supply the resin 208 of the appropriate resin supply quantity onto the LED element 205 that is mounted on the board 214.

In the supplying process for production, first, the resin 208 of the appropriate resin supply quantity prescribed in the resin supply information 219 is really supplied, and the light emission characteristics are measured when the resin 208 is in an unhardened state. Based on the obtained measurement result, a quality item range of the light emission characteristic measurement value when the light emission characteristics of the resin 208 that is supplied in the supplying process for production are measured is set, and this quality item range is used as a threshold (refer to the threshold data 281a shown in FIG. 33) with which whether a quality item is obtained in the supplying process for production is determined.

That is, in the resin supplying method in the light emitting element manufacturing system shown in the present embodiment, while a white LED is used as the light source part 245 for the light emission characteristic measurement, a light emission characteristic, which deviates from the normal light emission characteristics which are obtained from a finished product when the resin which is supplied on the LED element 205 is in a hardened state for a light emission characteristic difference because the resin 208 is in an unhardened state, is used as the light emission characteristic prescribed beforehand which is the basis of setting the threshold with which whether a quality item is obtained in the supplying process for production is determined. Thereby, the control of the resin supply quantity in the process of supplying resin onto the LED element 205 can be performed based on the normal light emission characteristics on the finished product.

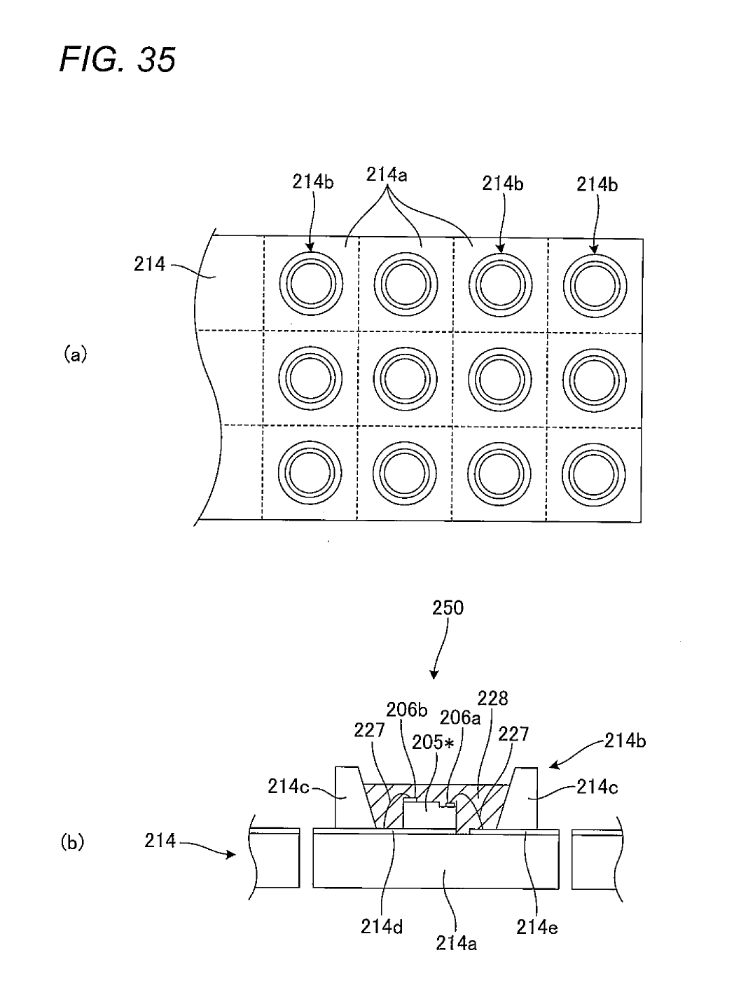

In the present embodiment, a light emitting element package 250 (refer to FIG. 35(b)) which emits white light is used as the light source part 245. Thereby, the light emission characteristic measurement of the test supplied resin 208 can be performed with a light of the same characteristic as the excitation light emitted in the light emitting element package 250 of the finished product, and a more reliable detection result can be obtained. It is not necessary to require using the same light emitting element package 250 as what is used in a finished product. In the light emission characteristic measurement, a light source device which can stably emits blue light of a constant wavelength (for example, a blue LED or a blue laser light source which emit blue light) can be used as a light source part for detection. However, by using the light emitting element package 250 which emits white light using the blue LED, there is an advantage that a light source device of stable quality can be chosen at a low cost. It is also possible to take out blue light of a predetermined wavelength by using a band pass filter.

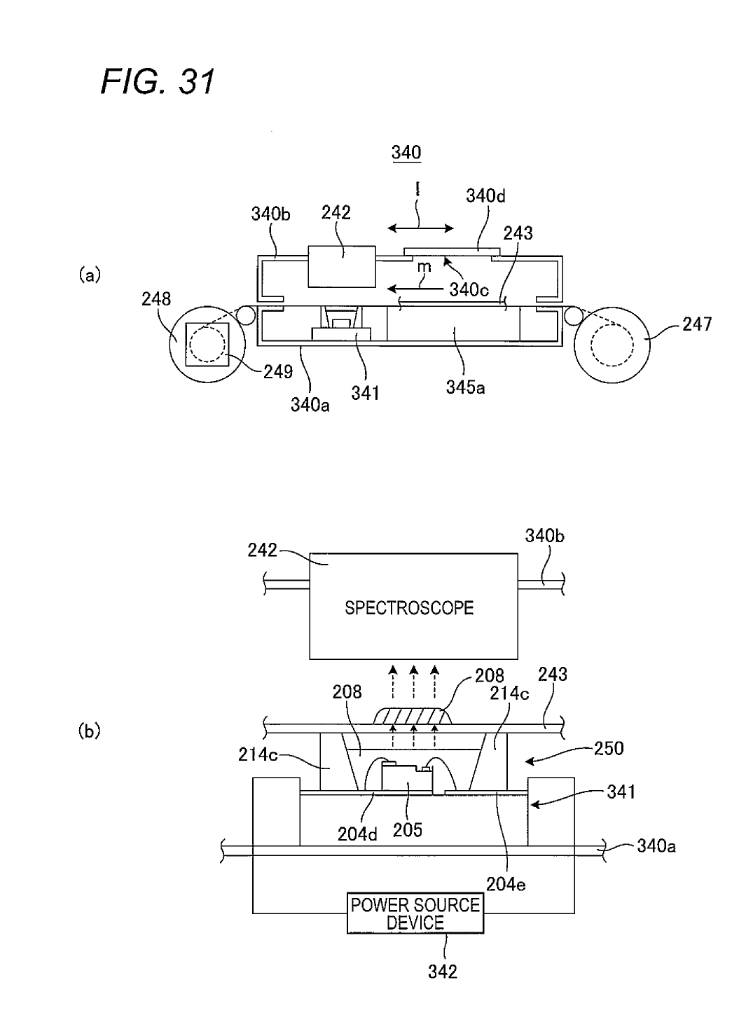

Instead of the test supplying and measuring unit 240 of the above-mentioned construction, a test supplying and measuring unit 340 of the construction shown in FIG. 31(a) may be used. That is, as shown in FIG. 31(a), the test supplying and measuring unit 340 has such an outside construction that a cover part 340b is disposed above a horizontal base 340a of a slim shape. The cover part 340b is provided with an opening 340c, and the opening 340c can be opened with a sliding window 340d which is used in supplying and is slidable (arrow 1). Inside the test supplying and measuring unit 340, a test supplying stage 345a which supports the light-passing member 243 from below, a light-passing member carrying part 341 which carries the light-passing member 243, and a spectroscope 242 which is disposed above the light-passing member carrying part 341 are provided.

The light-passing member carrying part 341 includes a light source device which emits excitation light to excite the fluorescent substance like the light source part 245 shown in FIG. 28(b). The excitation light is irradiated from below by the light source device to the light-passing member 243 on which the resin 208 is test supplied in a supplying process for measurement. Like the example shown in FIGS. 30(a) to 8(c), the light-passing member 243 is supplied by being wound and accommodated in the supply reel 247. After the light-passing member 243 is sent along the top surface of the test supplying stage 345a (arrow m), the light-passing member 243 passes between the light-passing member carrying part 341 and the spectroscope 242, and is wound into the collecting reel 248 which is driven by the winding motor 249.

When the sliding window 340d used in supplying is slid to an open state, the top surface of the test supplying stage 345a is exposed upwards, and it is possible for the print head 232 to test supply the resin 208 on the light-passing member 243 carried on the top surface. This test supplying is performed in which a prescribed supply quantity of small droplet 208a is discharged by the print nozzle unit 232a to the light-passing member 243 which is supported by the test supplying stage 345a from below.

FIG. 31(b) shows that by moving the light-passing member 243 on which the resin 208 is test supplied on the test supplying stage 345a, to make the resin 208 to be located above the light-passing member carrying part 341, and dropping the cover part 340b, a dark room for the light emission characteristic measurement is formed between the cover part 340b and the base 340a. The light emitting element package 250 emitting white light is used as a light source device in the light-passing member carrying part 341. In the light emitting element package 250, wiring layers 214e and 214d connected to the LED element 205 are connected to a power source device 342. By switching ON the power source device 342, electricity for light emission is supplied to the LED element 205 and thereby the light emitting element package 250 emits white light.

In the process that the white light is irradiated to the resin 208 test supplied on the light-passing member 243 after the white light passes through the resin 208, a white light, in which yellow light that the fluorescent substance in the resin 208, which is excited by the blue light included in the white light, emits and the blue light are added and mixed, is irradiated upwards from the resin 208. The spectroscope 242 is placed above the test supplying and measuring unit 340. The white light irradiated from the resin 208 is received by the spectroscope 242. The received white light is analyzed by the light emission characteristic measuring processor 239 to measure the light emission characteristic. Light emission characteristics such as color tone rank or beam of the white light are detected, and, as a detection result, deviations from prescribed light emission characteristics are detected out. That is, the light emission characteristic measuring processor 239 measures the light emission characteristic of the light that the resin 208, which is supplied onto the light-passing member 243, emits when the excitation light emitted from the LED element 205, which is the light source part, is irradiated to the resin 208. The measurement result of the light emission characteristic measuring processor 239 is sent to the supply quantity deriving processor 238, and the processes like the example shown in FIGS. 28(a) and 28(b) are performed.

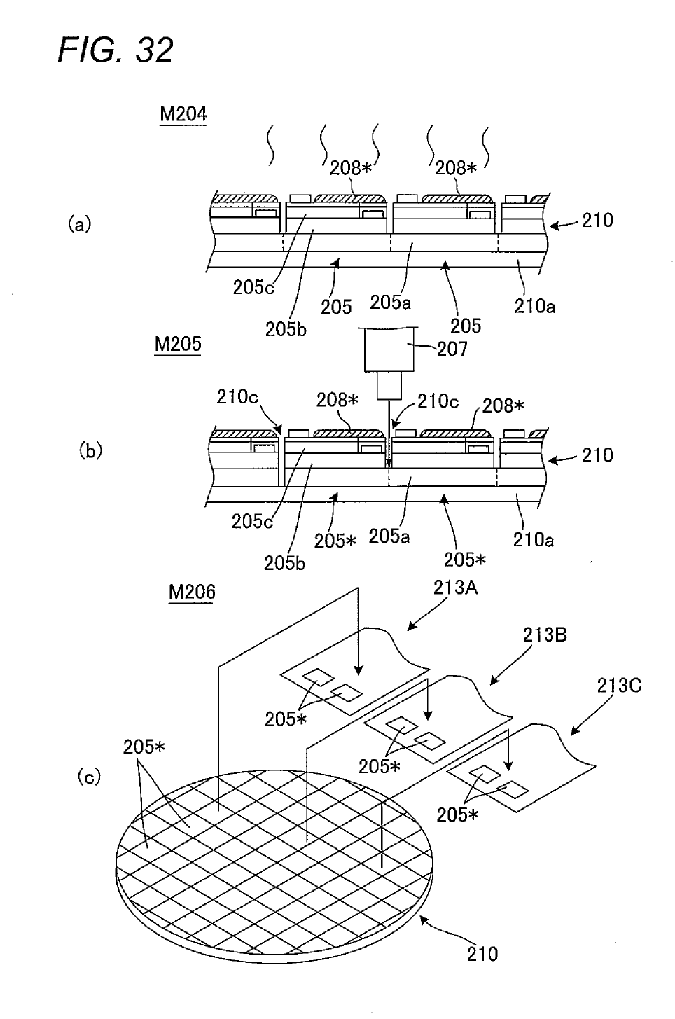

The LED elements 205 to which the resin is supplied in this way are sent to the curing device M204 in a state of the LED wafer 210. As shown in FIG. 32(a), the resin 208 is hardened by heating the LED wafer 210. Thereby, the top surfaces of the LED elements 205 are covered with a resin film 208* formed when the resin 208 containing the fluorescent substance is hardened. Then, the LED wafer 210 is conveyed to the dicing device M205, and as shown in FIG. 32(b), the sapphire board 205a which remains uncut in the half cutting of the half cutting device M201 is cut by the laser cutting machine 207. Thereby, the light emitting elements 205* in which the top surfaces of the individual LED elements 205 are covered with the resin film 208* are formed. Besides the method of removing the sapphire substrate 205a with laser, a method of mechanically cutting the sapphire substrate 205a with a dicing saw or a method of forming embrittled areas with a laser beam in the sapphire substrate 5a in half cutting and dividing the sapphire substrate 5a by flaking to break those embrittled areas mechanically may be used as the dicing method.

After this, the LED wafer 210 is sent to the sorting device M206 in which the light emission characteristics of the plurality of light emitting elements 205* attached onto the dicing sheet 210a are measured again. Based on a result of the measurement, the plurality of light emitting elements 205* constructing the LED wafer 210 are ranked into individual predetermined characteristic ranges and respectively transferred to the plurality of element holding sheets 213A, 213B, 213C and the like. Whether the sorting device M206 in the light emitting element manufacturing system 201 is necessary is determined in consideration of the precision of the light emission characteristics demanded from a finished product and/or the precision of the resin supply quantity revision of the resin supplying device M203, and the process of the sorting device M206 is not necessarily required.

Next, with reference to FIG. 33, the construction of a control system of the light emitting element manufacturing system 201 is described. Among the component elements of the devices that construct the light emitting element manufacturing system 201, those component elements that are related to the transmission/reception and update processing of the element characteristic information 212, the resin supply information 219, the map data 218 and the threshold data 281a are shown in the administrative computer 203, the element characteristic measuring device M202 and the resin supplying device M203.

In FIG. 33, the administrative computer 203 includes a system control part 260, a storage part 261 and a communication part 262. The system control part 260 collectively controls light emitting element package manufacturing operations of the light emitting element manufacturing system 201. Besides programs and data necessary for control processes of the system control part 260, the element characteristic information 212, the resin supply information 219, and, as needed, the map data 218 and threshold data 281a, are stored in the storage part 261. The communication part 262 is connected to other devices through the LAN system 202 and delivers control signals and data. The resin supply information 219 are transmitted from outside through the LAN system 202 and the communication part 262 or through an independent storage medium such as a CD ROM, a USB memory storage, or a SD card, and are stored in the storage part 261.

The element characteristic measuring device M202 includes a measurement control part 270, a storage part 271, a communication part 272, the characteristic measurement processor 211 and a map making processor 274. The measurement control part 270 controls all parts described below based on various programs and data stored in the storage part 271 to perform element characteristic measuring operations of the element characteristic measuring device M202. Besides programs and data necessary for the control processes of the measurement control part 270, element position information 271a and the element characteristic information 212 are stored in the storage part 271. The element position information 271a is data indicating the arranged positions of the LED elements 205 in the LED wafer 210. The element characteristic information 212 is data of the result of a measurement by the characteristic measurement processor 211.

The communication part 272 is connected to other devices through the LAN system 202, and delivers control signals and data. The map making processor 274 (map data making part) performs the process of making the map data 218 for every LED wafer 210 which associate the element position information 271a stored in the storage part 271 with the element characteristic information 212 on the LED element 205. The map data 218 such made are transmitted to the resin supplying device M203 as forward feeding data through the LAN system 202. The map data 218 may be transmitted to the resin supplying device M203 from the element characteristic measuring device M202 via the administrative computer 203. In this case, as shown in FIG. 33, the map data 218 are stored in the storage part 261 of the administrative computer 203.

The resin supplying device M203 includes the supply control part 236, a storage part 281, a communication part 282, the production performing processor 237, the supply quantity deriving processor 238, and the light emission characteristic measuring processor 239. The supply control part 236, by controlling the print head driving part 235 which forms the resin supplying part 200A, the position recognizing part 234, the height measuring part 233 and the test supplying and measuring unit 240, performs processes to make the supplying process for measurement in which the resin 208 is test supplied onto the light-passing member 243 used for light emission characteristic measurement, and the supplying process for production in which the resin 208 is supplied onto the LED element 205 for practical production to be performed.

Besides programs and data necessary for control processes of the supply control part 236, the resin supply information 219, the map data 218, the threshold data 281a and supply quantities for practical production 281b are stored in the storage part 281. The resin supply information 219 is transmitted from the administrative computer 203 through the LAN system 202, and the map data 218 are transmitted from the element characteristic measuring device M202 through the LAN system 202 similarly. The communication part 282 is connected to other devices through the LAN system 202 and delivers control signals and data.

The light emission characteristic measuring processor 239 performs processes to measure the light emission characteristics of the light that the resin 208 emits when the excitation light emitted from the light source part 245 is irradiated to the resin 8 which is supplied onto the light-passing member 243. The supply quantity deriving processor 238 performs calculating processes to derive the appropriate resin supply quantity of the resin 208 which should be supplied onto the LED element 205 for practical production by revising the appropriate resin supply quantity based on the measurement result of the light emission characteristic measuring processor 239 and the light emission characteristic prescribed beforehand. The production performing processor 237 makes the supplying process for production, in which the resin of the appropriate resin supply quantity is supplied on the LED element 205, to be performed by ordering the supply control part 236 with the appropriate resin supply quantity derived by the supply quantity deriving processor 238.

In the construction shown in FIG. 33, processing functions except those functions to perform the operations specific to the devices, for example, the function of the map making processor 274 which the element characteristic measuring device M202 is provided with and the function of the supply quantity deriving processor 238 which the resin supplying device M203 are provided with, are not necessarily included in the devices. For example, it is also possible that the functions of the map making processor 274 and the supply quantity deriving processor 238 may be covered by the calculation processing function that the system control part 260 of the administrative computer 203 has, and necessary signal transmission and reception may be performed through the LAN system 202.

In the construction of the above-mentioned light emitting element manufacturing system 201, each of the element characteristic measuring device M202 and the resin supplying device M203 is connected to the LAN system 202. Thus, the administrative computer 203 in which the resin supply information 219 is stored in the storage part 261 and the LAN system 202 become a resin information providing unit that provides the information, which makes the appropriate resin supply quantity of the resin 208 to correspond to the element characteristic information to obtain a light emitting element that possesses the prescribed light emission characteristics, as the resin supply information 219 to the resin supplying device M203.

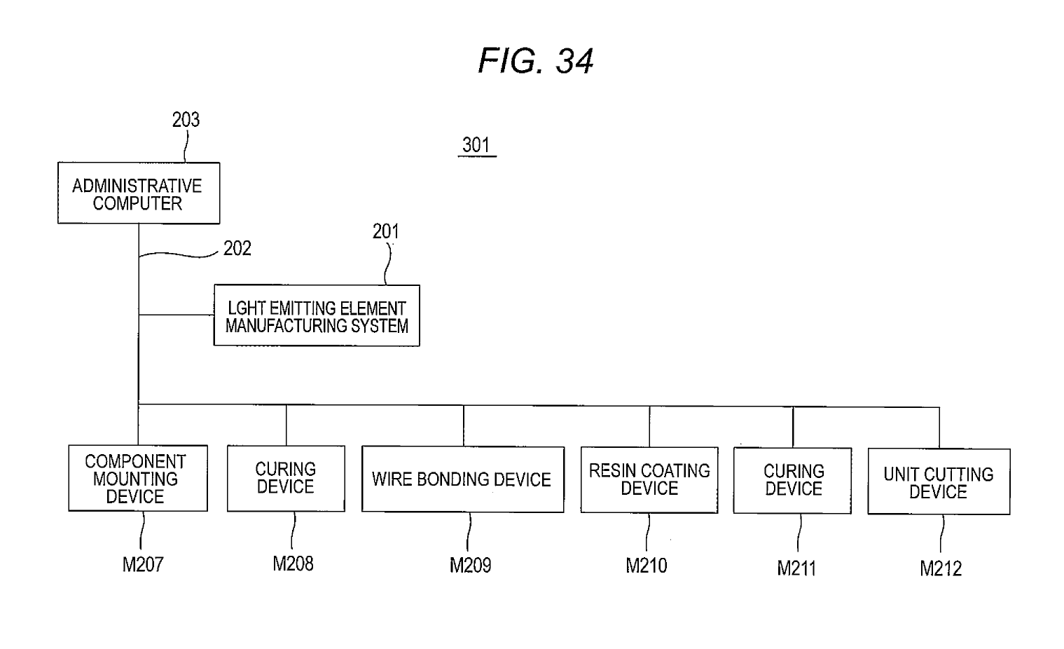

Next, with reference to FIG. 34, the construction of a light emitting element package manufacturing system 301, which manufactures light emitting element packages using the light emitting elements manufactured by the light emitting element manufacturing system 201 is described. The light emitting element package manufacturing system 301 is constructed by combining a component mounting device M207, a curing device M208, a wire bonding device M209, a resin coating device M210, a curing device M211 and a piece-cutting device M212 into the light emitting element manufacturing system 201 of the construction shown in FIG. 23.

The component mounting device M207 mounts light emitting element elements 205* manufactured by the light emitting element manufacturing system 201 by bonding the light emitting elements 5* to a board 214 (refer to FIGS. 35(a) and 35(b)), which becomes a base of LED packages, with resin adhesive. The curing device M208 hardens the resin adhesive, which is used in the bonding at the time of the mounting, by heating the board 214 after the light emitting elements 205* are mounted. The wire bonding device M209 connects electrodes of the light emitting elements 205* to electrodes of the board 214 with bonding wires. The resin coating device M210 coats transparent resin for sealing on each of the light emitting elements 205* on the board 214 after the wire bonding. The curing device M211 hardens the transparent resin, which is coated to cover the light emitting elements 205*, by heating the board 214 after the resin coating. The piece-cutting device M212 cuts the board 214 after the resin is hardened for each of the light emitting elements 205* to separate into individual light emitting element packages. Thereby, the light emitting element packages which are separated into individual pieces are completed.

In FIG. 34, an example in which the devices from the component mounting device M207 to the piece-cutting device M212 are placed in a line to construct a manufacturing line is shown. However, the light emitting element package manufacturing system 301 does not necessarily adopt such a line construction, but may be so constructed that the procedural steps are sequentially performed respectively by the devices that are dispersedly placed. It is also possible to place a plasma processing device which performs a plasma processing for the purpose of cleaning electrodes prior to the wire bonding, and a plasma processing device which performs a plasma processing for the purpose of surface reforming to improve coherency of the resin after the wire bonding and prior to the resin coating, before and after the wire bonding device M209.

With reference to FIGS. 35(a) and 35(b), the board 214, on which operations are performed, the light emitting elements 205* and a light emitting element package 250 as a finished product in the light emitting element package manufacturing system 301, are described. As shown in FIG. 35(a), the board 214 is a multiple-pieces-connected board in which a plurality of individual boards 214a, each of which becomes the base of one light emitting element package 250 in a finished product, are elaborated, and one LED mounting part 214b, where the light emitting element 205* is mounted, is formed on each of the individual boards 214a. The LED package 250 shown in FIG. 35(b) is completed by mounting the light emitting element 205* in the light emitting element mounting part 214b for each of the individual boards 214a, then coating the transparent resin 228 for sealing in the LED mounting part 214b to cover the light emitting element 205*, and, after the resin 228 is hardened, cutting the board 214, whose steps have been completed, for each of the individual boards 214a.

As shown in FIG. 35(b), the individual board 214a is provided with a reflective part 214c of a cavity shape which has, for example, a circular or an elliptic ring-like bank to form the LED mounting part 214b. An N-type part electrode 206a and a P-type part electrode 206b of the light emitting element 205* which is loaded inside the reflective part 214c are connected to wiring layers 214e and 214d which are formed on the top surface of the individual board 214a with bonding wires 227, respectively. The resin 228 is coated at a predetermined thickness inside the reflective part 214c to cover the light emitting element 205* in this state, and white light that is emitted from the light emitting element 205* is irradiated to pass through the transparent resin 228.

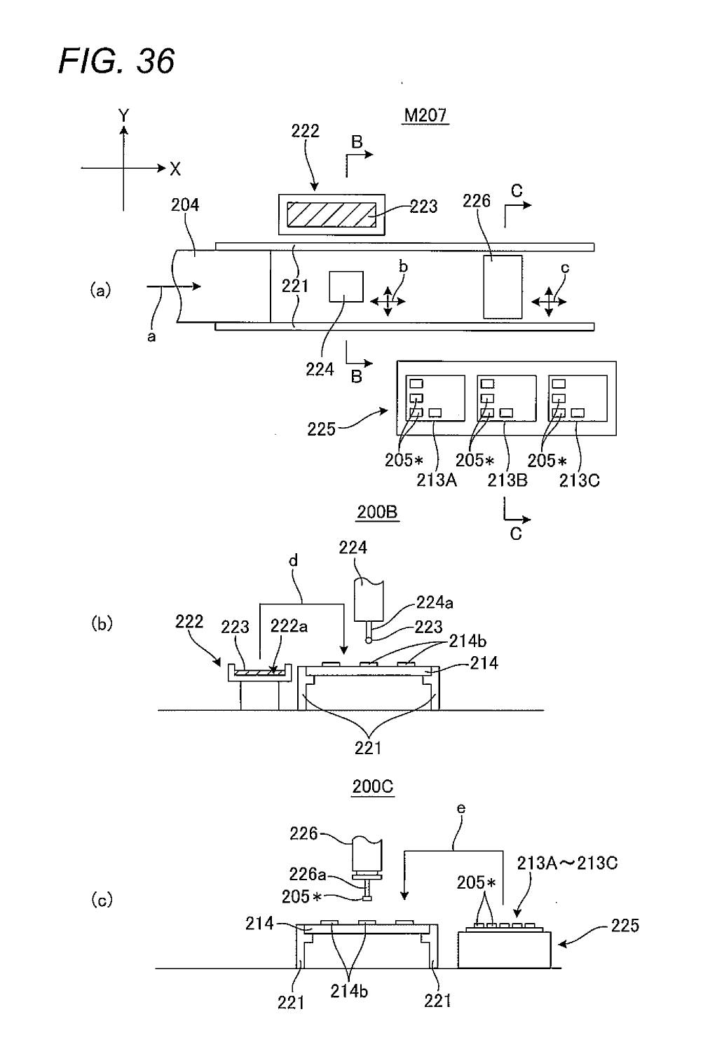

Next, with reference to FIGS. 36(a) to 14(c), a construction and functions of the component mounting device M207 are described. As shown in the top view of FIG. 36(a), the component mounting device M207 includes a board conveying mechanism 221 which conveys a board 214, which is an operation object, supplied from upstream towards the board conveying direction (arrow a). To the board conveying mechanism 221, an adhesive supplying part 200B shown in FIG. 36(b) with a B-B section, and a component mounting part 200C shown in FIG. 36(c) with a C-C section are disposed sequentially from upstream. The adhesive supplying part 200B includes an adhesive supplying part 222 which is placed beside the board conveying mechanism 221, and which supply resin adhesive 223 in the form of a coating of a predetermined film thickness, and an adhesive transferring mechanism 224 which is movable in the horizontal direction (arrow b) above the board conveying mechanism 221 and the adhesive supplying part 222. The component mounting part 200C includes a component supplying mechanism 225 which is placed beside the board conveying mechanism 221 and which holds the element holding sheets 213A, 213B, 213C and the like as shown in FIG. 32(b), and a component mounting mechanism 226 which is movable in the horizontal direction (arrow c) above the board conveying mechanism 221 and the component supplying mechanism 225.

As shown in FIG. 36(b), the board 214 imported into the board conveying mechanism 221 is positioned in the adhesive supplying part 200B, and the resin adhesive 223 is supplied on the LED mounting part 214b formed on each of the individual boards 214a. That is, first, by moving the adhesive transferring mechanism 224 to above the adhesive supplying part 222, a transferring pin 224a is made to touch a coating of the resin adhesive 223 formed on a transferring surface 222a, and the resin adhesive 223 is attached. Then, by moving the adhesive transferring mechanism 224 to above the board 214, and dropping the transferring pin 224a to the LED mounting part 214b (arrow d), the resin adhesive 223 which is attached to the transferring pin 224a is supplied to an element mounting position in the LED mounting part 214b with the transferring.

Then, the board 214 after the adhesive is supplied is conveyed downstream and is positioned in the component mounting part 200C as shown in FIG. 36(C), and a light emitting element 205* is mounted on each of the LED mounting parts 214b after the adhesive is supplied. That is, first, by moving the component mounting mechanism 226 to above the component supplying mechanism 225, and dropping a mounting nozzle 226a relative to either of the element holding sheets 213A, 213B, 213C and the like which are held on the component supplying mechanism 225, and a light emitting element 205* is held and taken out by the mounting nozzle 226a. Then, by moving the component mounting mechanism 226 to above the LED mounting part 214b of the board 214, and dropping the mounting nozzle 226a (arrow e), the light emitting element 205* held in the mounting nozzle 226a is mounted to the element mounting position where the adhesive is supplied in the LED mounting part 214b.

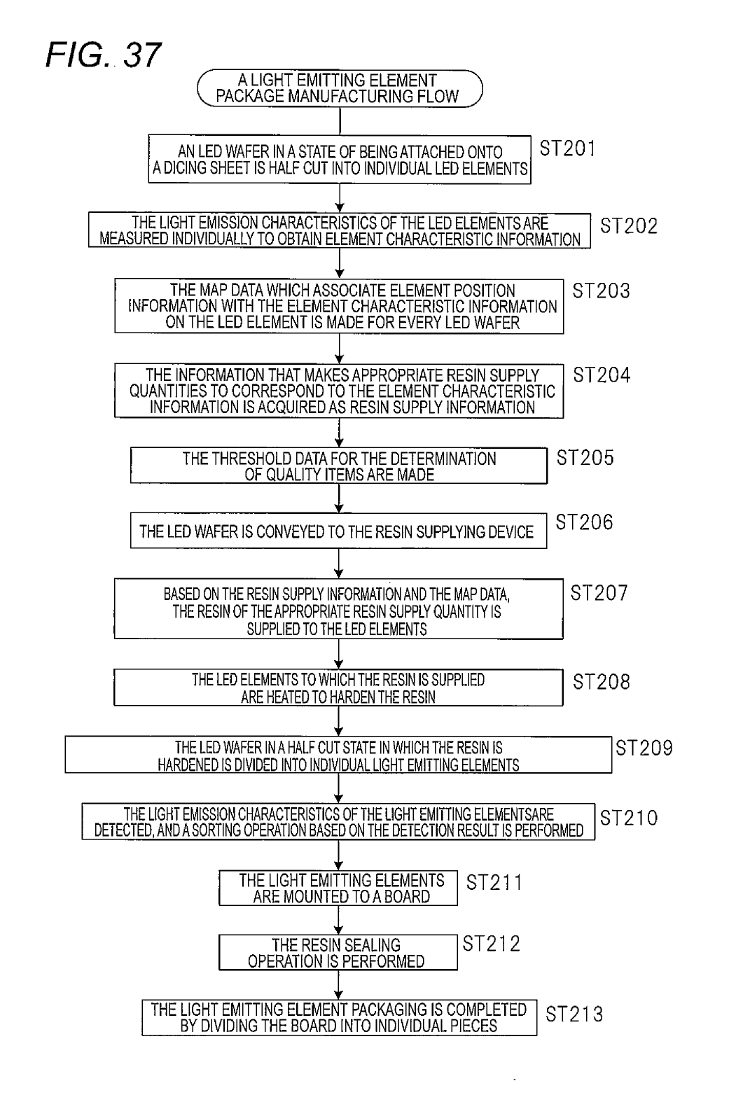

Next, light emitting element package manufacturing processes performed by the light emitting element package manufacturing system 301 are described with reference to the figures along a flow of FIG. 37. Herein, the light emitting element packages 250 which are constructed by mounting light emitting elements 205* in which the top surfaces of LED elements 205 are coated with the resin 208 containing the fluorescent substance beforehand on the board 214 are manufactured.

First, an LED wafer 210, which is an operation object, is imported into the half cutting device M201, and as shown in FIG. 25(a), the LED wafer 210 in a state that a plurality of LED elements 205 are elaborated and attached onto a dicing sheet 210a is half cut for each of the LED elements 205 (ST201) (half cutting step). That is, only the semiconductor layers constructing the LED elements 205 are divided for each of the individual pieces. Then, the LED wafer 210 in a half cut state is imported into the element characteristic measuring device M202, and as shown in FIG. 25(b), an element characteristics measurement is performed. That is, the light emission characteristics of the LED elements 205 in a half cut state that only the semiconductor layers are divided into individual pieces in a state of being attached and held onto the dicing sheet 210a are measured individually to obtain the element characteristic information indicating the light emission characteristics of the LED elements 205 (ST202) (element characteristic measuring step).

Then, map data 218 are made by the map making processor 274 of the element characteristic measuring device M202. That is, the map data 218 (refer to FIG. 26) which associate the element position information indicating the position in the LED wafer 210 of the half cut LED element 205 with the element characteristic information on the LED element 205 is made for every LED wafer 210 (ST203) (map data making step). The information that makes appropriate resin supply quantities of the resin 208 to correspond to the element characteristic information to obtain light emitting elements 205* which possess the prescribed light emission characteristics is acquired from the administrative computer 203 through the LAN system 202 as the resin supply information 219 (refer to FIG. 27) (ST204) (resin information acquiring step).

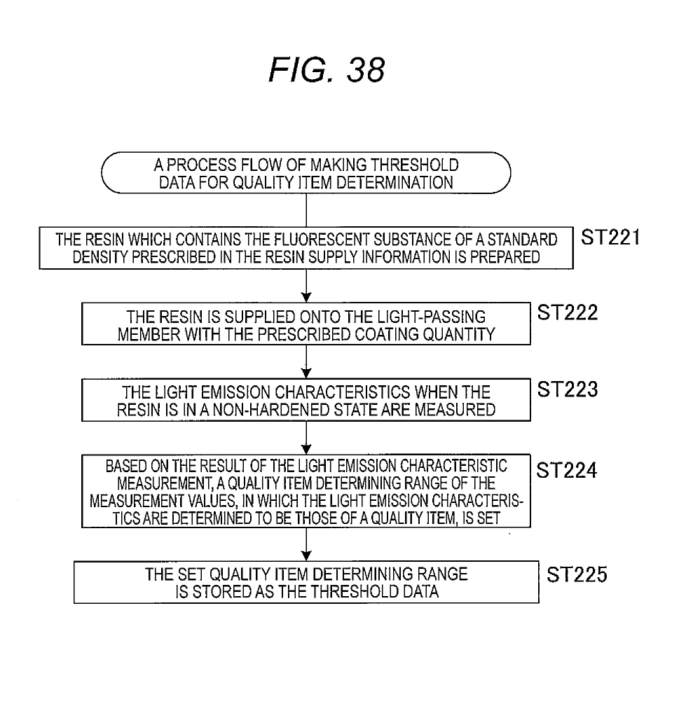

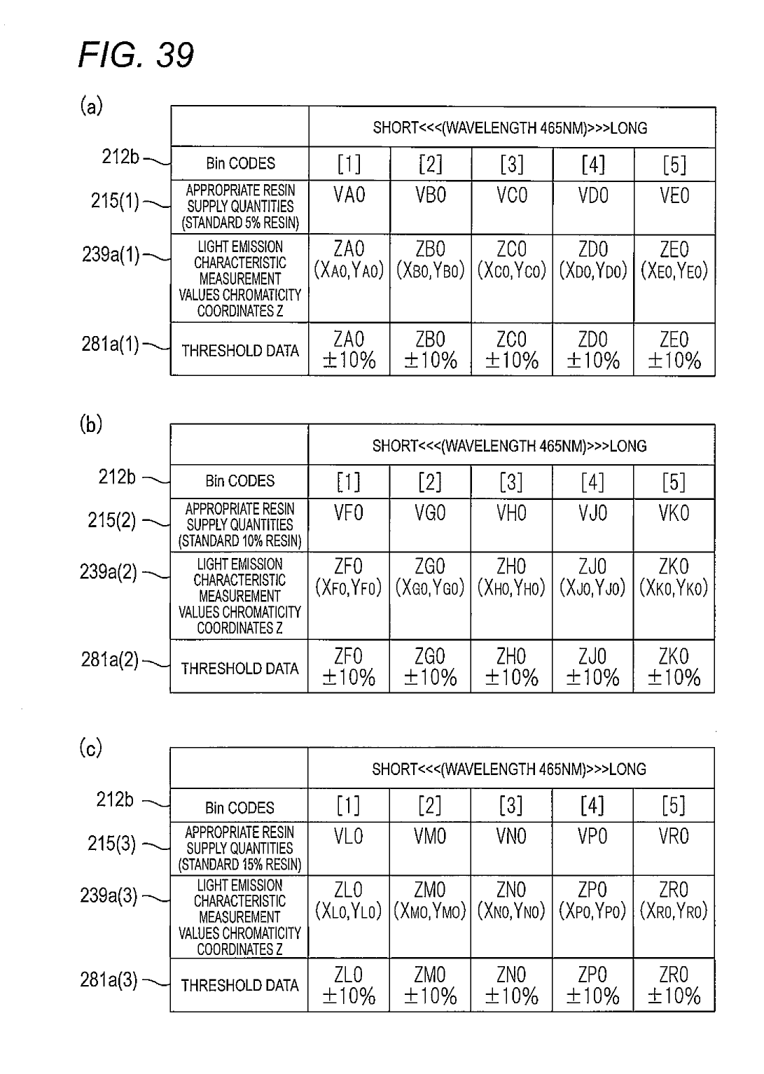

Then, the threshold data making process for the determination of quality items is performed (ST205). This process is performed to set the threshold (refer to the threshold data 281a shown in FIG. 33) to determine whether quality items are obtained in the supplying for production, and is performed repeatedly for the supplying for production corresponding to each of the Bin codes [1], [2], [3], [4] and [5]. The threshold data making process is described in detail with reference to FIGS. 38 and 39(a) to 39(c) and the above FIG. 18. In FIG. 38, first, the resin 208 which contains the fluorescent substance of standard densities prescribed in the resin supply information 219 is prepared (ST221).

After having set the resin 208 in the print head 232, the print nozzle unit 232a is moved to the test supplying stage 240a of the test supplying and measuring unit 240, and the resin 208 is supplied onto the light-passing member 243 with the prescribed supply quantity (appropriate resin supply quantity) shown in the resin supply information 219 (ST222). Then, the resin 208 supplied onto the light-passing member 243 is moved onto the light-passing member carrying part 241, the LED element 205 is made to emit light, and the light emission characteristics when the resin 208 is in an unhardened state are measured by the light emission characteristic measuring part of the above-mentioned construction (ST223). Based on light emission characteristic measurement values 239a which are the measurement result of the light emission characteristics measured by the light emission characteristic measuring part, quality item determining ranges of the measurement values, in which the light emission characteristic is determined to be that of a quality item, are set (ST224). The set quality item determining ranges are stored as the threshold data 281a in the storage part 281, and are transferred to the administrative computer 203 and stored in the storage part 261 (ST225).

FIGS. 39(a) to 39(c) show the threshold data made in this way, namely, the light emission characteristic measurement values obtained when the resin is in an unhardened state after having supplied the resin 208 that contains fluorescent substance of standard densities, and the quality item determining ranges (the thresholds) of the measurement values to determine whether the light emission characteristic is that of a quality item. FIGS. 39(a), 39(b) and 39(c) show thresholds corresponding to the Bin codes [1], [2], [3], [4] and [5] when the fluorescent substance densities in the resin 208 are 5%, 10% and 15%, respectively.

For example, as shown in FIG. 39(a), when the fluorescent substance density of the resin 208 is 5%, the supply quantity shown in each of the appropriate resin supply quantities 215(1) corresponds to each of the Bin codes 212b, and the measurement results after the light emission characteristics of the light that the resin 208 emits by irradiating blue light of the LED element 205 to the resin 208 coated with each of the supply quantities are measured by the light emission characteristic measuring part are shown in the light emission characteristic measurement values 239a (1). Based on each of the light emission characteristic measurement values 239a (1), the threshold data 281a (1) are set.

For example, the measurement result after the light emission characteristics of the resin 208 which is supplied with the appropriate resin supply quantity VA0 corresponding to the Bin code [1] are measured is represented by a chromaticity coordinate point ZA0 (XA0, YA0) in the chromaticity table shown in the above FIG. 18. Around the chromaticity coordinate point ZA0, a predetermined range of the X coordinate and the Y coordinate in the chromaticity table (for example, +−10%) is set as the quality item determining range (threshold). For the appropriate resin supply quantities corresponding to other Bin codes [2] to [5], similarly, the quality item determining ranges (thresholds) are set based on the light emission characteristic measurement results (refer to the chromaticity coordinate points ZB0 to ZE0 in the chromaticity table shown in FIG. 18). Herein, the predetermined range set as the threshold is appropriately set depending on the demanded precision level of the light emission characteristics of the light emitting element package 250 as a product.

Likewise, FIGS. 39(b) and 39(c) show the light emission characteristic measurement values and the quality item determining ranges (thresholds) when the fluorescent substance densities of the resin 208 are 10% and 15%, respectively. In FIGS. 36(b) and 36(c), the appropriate resin supply quantities 215(2) and the appropriate resin supply quantities 215(3) respectively show the appropriate resin supply quantities when the fluorescent substance densities are 10% and 15%, respectively. The light emission characteristic measurement values 239a (2) and the light emission characteristic measurement values 239a (3) respectively show the light emission characteristic measurement values when the fluorescent substance densities are 10% and 15%, respectively, and the threshold data 281a (2) and the threshold data 281a (3) respectively show the quality item determining ranges (thresholds) when the fluorescent substance densities are 10% and 15%, respectively.

The threshold data made in this way can be used properly in the supplying operation for production based on the Bin code 212b which an LED element 205, on which the coating operation is performed, falls into. The threshold data making process shown in (ST205) may be performed as an off-line operation by an independent detecting device provided separately from the light emitting element package manufacturing system 301, and the threshold data 281a that are stored in the administrative computer 203 beforehand may be transmitted to the resin supplying device M203 via the LAN system 202 and used.

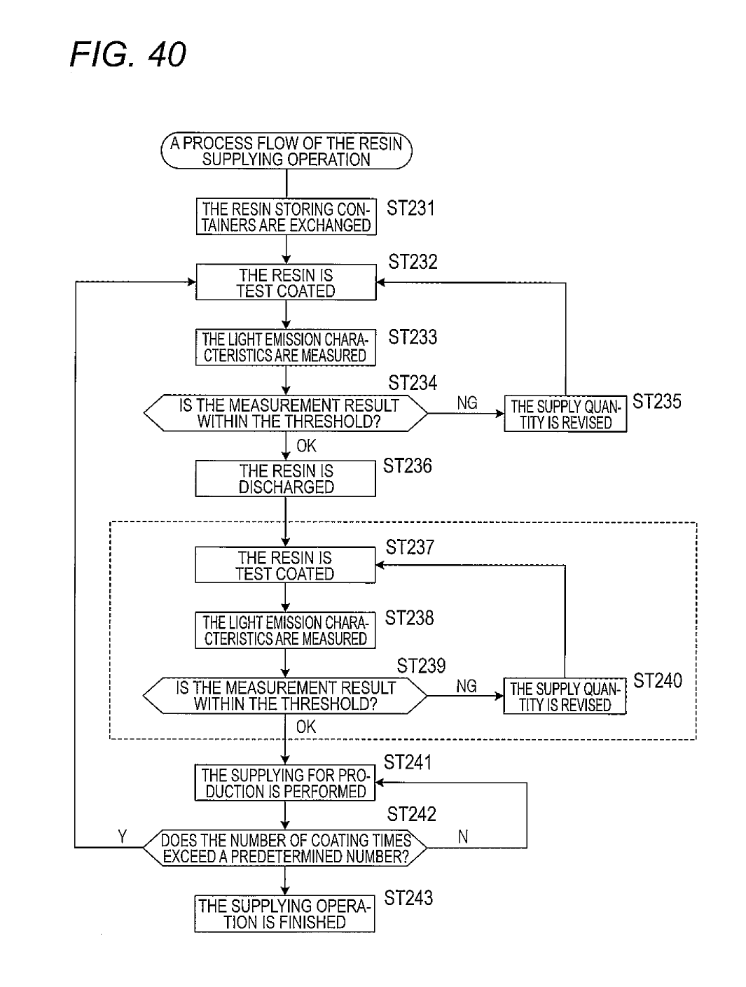

After resin supplying operations become possible in this way, the wafer holder 204 which holds the LED wafer 210 is conveyed to the resin supplying device M203 (ST206). Based on the resin supply information 219 and the map data 218, the resin 208 of the appropriate resin supply quantity to obtain the prescribed light emission characteristics is supplied to each of the LED elements 205 in a wafer state of being attached onto the dicing sheet 210a (ST207) (resin supplying step). The resin supplying operation is described in detail with reference to FIG. 40 and the above FIGS. 20(a) to 20(d).

First, when the resin supplying operation is started, the exchange of resin storing containers is performed as needed (ST231). That is, the resin cartridge mounted into the print head 232 is exchanged with a resin cartridge which accommodates the resin 208 of the fluorescent substance density selected in response to the characteristics of the LED element 205. Then, the resin 208 for light emission characteristic measurement is test supplied on the light-passing member 243 by the resin supplying part 200A which discharges a variable supply quantity of the resin 208 (supplying step for measurement) (ST232). That is, the resin 208 of the appropriate resin supply quantity (VA0 to VE0) for either of the Bin codes 212b prescribed in the resin supply information 219 shown FIG. 27 is supplied onto the light-passing member 243 which is led out to the test supplying stage 240a in the test supplying and measuring unit 240. At this time, even if the print head 232 is ordered with discharging parameters corresponding to the appropriate resin supply quantity (VA0 to VE0), the real resin supply quantity that is discharged by the print nozzle unit 232a and supplied onto the light-passing member 243 is not necessarily the above appropriate resin supply quantity because, for example, the character of the resin 208 changes over time. As shown in the above FIG. 20(a), the real resin supply quantity becomes VA1 to VE1 which are somewhat different from VA0 to VE0.

Then, by sending the light-passing member 243 in the test supplying and measuring unit 240, the light-passing member 243, on which the resin 208 is test supplied, is sent and carried on the light-passing member carrying part 241 (light-passing member carrying step). The excitation light to excite the fluorescent substance is emitted from the light source part 245 which is placed above the light-passing member carrying part 241. The light that the resin 208 emits, when the excitation light is irradiated to the resin 208 which is supplied on the light-passing member 243 from above, is received by the spectroscope 242 through the integrating sphere 244 from below the light-passing member 243, and the light emission characteristics of the light are measured by the light emission characteristic measuring processor 239 (light emission characteristic measuring step) (ST233).

Thereby, as shown in the above FIG. 20(b), the light emission characteristic measurement values represented in chromaticity coordinate points Z (refer to FIG. 18) are provided. This measurement result does not necessarily correspond to the light emission characteristic prescribed beforehand, namely, the standard chromaticity coordinate points ZA0 to ZE0 at the time of supplying the appropriate resin shown in FIG. 39(a) because of, for example, the deviation of the above-mentioned supply quantity and the density change of the fluorescent substance particles of the resin 208. Therefore, the deviations (ΔXA, ΔYA) to (ΔXE, ΔYE) indicating the differences in the X and Y coordinates between the obtained chromaticity coordinate points ZA1 to ZE1 and the standard chromaticity coordinate points ZA0 to ZE0 at the time of supplying the appropriate resin shown in FIG. 39(a) are obtained, and it is determined whether it is necessary to revise to obtain a desired light emission characteristic.

It is determined whether or not the measurement result is within the threshold (ST234). As shown in the above FIG. 20(c), by comparing the deviations obtained in (ST233) and the thresholds, it is determined whether the deviations (ΔXA, ΔYA) to (ΔXE, ΔYE) are within +−10% of ZA0 to ZE0. If the deviation is within the threshold, the discharging parameters corresponding to the set appropriate resin supply quantities VA0 to VE0 are just maintained. On the other hand, when the deviation exceeds the threshold, the supply quantity is revised (ST235).

That is, the deviation between the measurement result in the light emission characteristic measuring step and the light emission characteristic prescribed beforehand is obtained, and as shown in the above FIG. 20(d), based on the obtained deviation, a process of deriving new appropriate resin supply quantities (VA2 to VE2) for practical production with which the resin 8 should be supplied onto the LED element 205 is performed by the supply quantity deriving processor 238 (supply quantity deriving step). In other words, by revising the appropriate resin supply quantities based on the measurement result in the light emission characteristic measurement step and the light emission characteristics prescribed beforehand, new appropriate resin supply quantities for practical production are derived.

The revised appropriate resin supply quantities (VA2 to VE2) are values updated by adding revision amounts respectively corresponding to the deviations to the set appropriate resin supply quantities VA0 to VE0. The relation of the deviations and the revision amounts is recorded in the resin supply information 219 as accompanied data known beforehand. Based on the revised appropriate resin supply quantities (VA2 to VE2), the processes of (ST232), (ST233), (ST234) and (ST235) are performed repeatedly. By recognizing that the deviation between the measurement result in (ST234) and the light emission characteristics prescribed beforehand is within the threshold, the appropriate resin supply quantities for practical production are determined. That is, in the above-mentioned resin supplying method, by repeatedly performing the supplying step for measurement, the light-passing member carrying step, the excitation light emitting step, the light emission characteristic measuring step and the supply quantity deriving step, the appropriate resin supply quantities are derived with certainty. The determined appropriate resin supply quantities are stored in the storage part 281 as the supply quantities 281b for practical production.

After this, the flow shifts to the next step to perform the discharging (ST236). By making the resin 208 of the predetermined quantity to be discharged from the print nozzle unit 232a, resin flow state in the resin discharge course is improved, and the movement of the print head 232 is stabilized. The processes of (ST237), (ST238), (ST239) and (ST240) shown with a broken line frame in FIG. 40 are performed similarly to the processes shown in (ST232), (ST233), (ST234) and (ST235). The processes of (ST237), (ST238), (ST239) and (ST240) are performed when it is necessary to carefully recognize that a desired light emission characteristic is completely ensured, and are not necessarily items that must be performed.

In this way, if the appropriate resin supply quantity to give the desired light emission characteristic is determined, the supplying operation for production is performed (ST241). That is, when the production performing processor 237 orders the supply control part 236, which controls the print head 232, with the appropriate resin supply quantity that is derived by the supply quantity deriving processor 238 and is stored as the supply quantity 281b for practical production, the supplying process for production, which individually supplies the resin 208 of this appropriate resin quantity on the LED element 205 in a wafer state is performed (production performing step).

In the process of repeatedly performing the supplying process for production, the number of times the print head 232 supplies is counted, and it is monitored whether the number of times of supplying exceeds a predetermined number that is set beforehand (ST242). That is, until this predetermined number is reached, the changes of the characteristic of the resin 208 and the fluorescent substance density are judged to be small, and the supplying process for production (ST241) is repeated while the same supply quantity 281b for practical production is maintained. If it is recognized that the predetermined number is surpassed in (ST242), it is judged that there is a possibility that the character of the resin 208 or the fluorescent substance density changes, and the flow returns to (ST232). Then, the same measurement of the light emission characteristics and the supply quantity revising process based on the measurement result are performed repeatedly.

Next, returning to the flow of FIG. 37, the LED wafer 210 is conveyed to the curing device M204, as shown in FIG. 32(a), the resin 208 is hardened by heating the LED elements 205 to which the resin 208 is supplied (ST208) (curing step). Thereby, the top surfaces of the LED elements 205 are covered with a resin film 208* formed when the resin 208 is hardened. In the curing step, instead of heating to harden the resin 208, a method of promoting the hardening by irradiating UV (ultraviolet rays), or a method of just placing the resin as it is to be naturally hardened may be used. Then, the LED wafer 210 is conveyed to the dicing device M205 where the LED wafer 210 in a half cut state in which the resin 208 is hardened is divided into individual light emitting elements 205*, as shown in FIG. 32(b) (ST209), (dicing step). Then, the LED wafer 210 which is in a state that the light emitting elements 205* are attached onto the dicing sheet 210a is conveyed to the sorting device M206 where the light emission characteristics of the light emitting elements 205* are detected, and as shown in FIG. 32(c), a sorting operation of separating the light emitting elements 205* based on the detection result is performed (ST210).

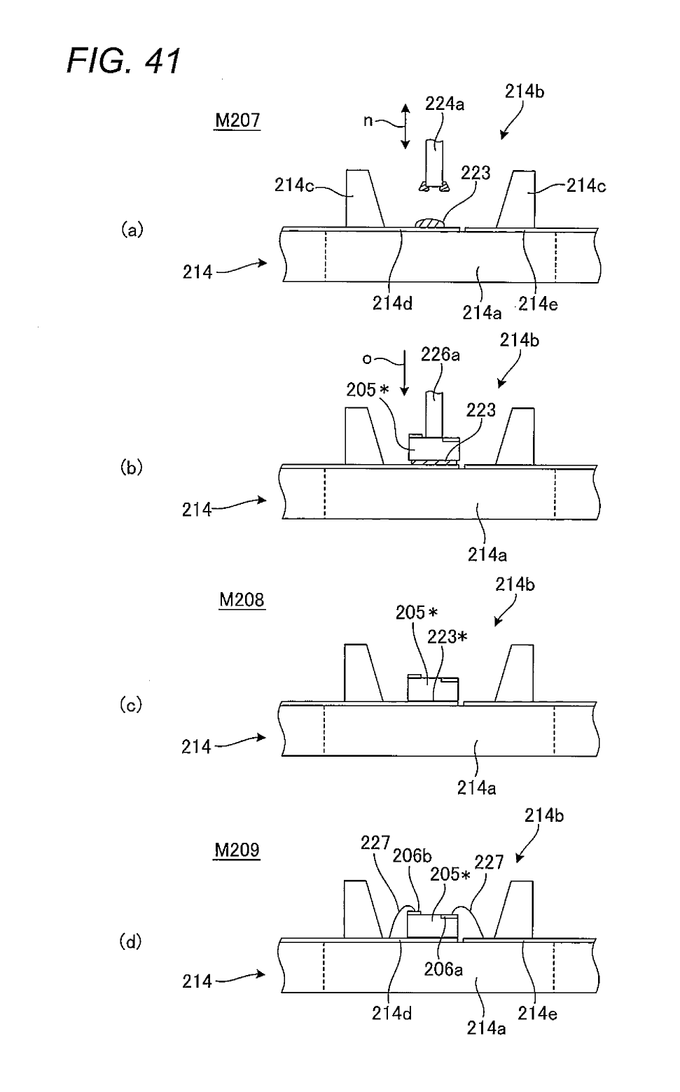

Then, the light emitting elements 205* manufactured in this way are mounted to the board 214 (ST211) (component mounting step). That is, the light emitting elements 205* separated depending on light emission characteristics are sent to the component mounting device M207 in a state of being attached onto the element holding sheets 213A, 213B and the like. After the resin adhesive 223 has been supplied to the element mounting position in the LED mounting part 214b by elevating the transferring pin 224a of the adhesive transferring mechanism 224 (arrow n), as shown in FIG. 41(a), the light emitting element 205* which is held in the mounting nozzle 226a of the component mounting mechanism 226 is dropped (arrow o) and mounted in the LED mounting part 214b of the board 214 through the resin adhesive 223, as shown in FIG. 41(b).

Then, the board 214 after the component mounting is sent to the curing device M208 where the board 14 is heated so that, as shown in FIG. 41(c), the resin adhesive 223 is thermally hardened and becomes the resin adhesive 223* and the light emitting element 205* is adhered to the individual board 214a. Then, the board 214 after the resin curing is sent to the wire bonding device M209, and the wiring layers 214e and 214d of the individual board 214a are connected to the N-type part electrode 206a and the P-type part electrode 206b of the light emitting element 205* with bonding wires 227, respectively, as shown in FIG. 41(d).

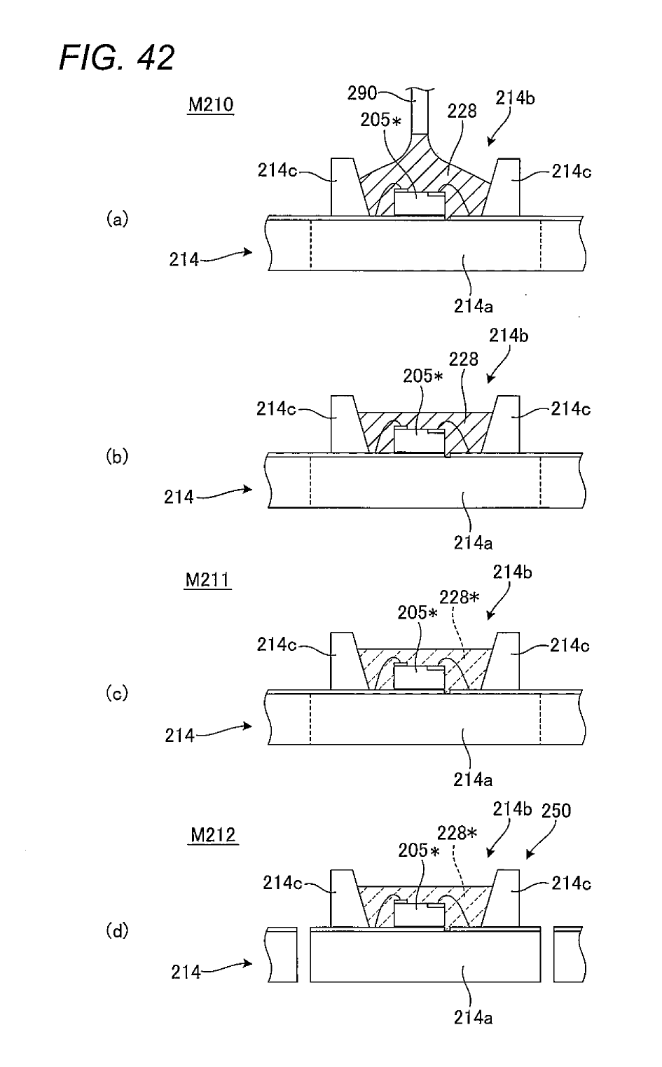

Then, the board 214 after the wire bonding is conveyed to the resin coating device M210, and the resin sealing operation is performed (ST211). That is, as shown in FIG. 42(a), inside the LED mounting part 214b surrounded by the reflective part 214c, the transparent resin 228 for sealing is discharged from a discharging nozzle 290 to cover the light emitting element 205*. When the resin supplying operation on one board 214 is finished in this way, the board 214 is sent to the curing device M211 and the resin 228 is hardened by heating the board 214 (ST209).

Thereby, as shown in FIG. 42(c), the resin 228 which is supplied to cover the light emitting element 205* is thermally hardened to become the solid resin 228*, and seals the light emitting element 205* which is in an adhered state in the LED mounting part 214b. Then, the board 214 after the resin curing is sent to the piece-cutting device M212, and by cutting the board 214 for each of the individual boards 214a, as shown in FIG. 42 (d), the board 4 and the like are divided into individual light emitting element packages 250 (ST210). Thereby, the light emitting element package 250 in which the light emitting element 205*, which is made by covering the LED element 205 with the resin 208, is mounted on the individual board 214a is completed.

As described above, with the light emitting element manufacturing system 201 and the light emitting element package manufacturing system 301 shown in the present embodiment, in manufacturing light emitting elements 205* by coating the top surfaces of LED elements 205 with the resin 208 containing the fluorescent substance, in the resin supplying operation of discharging to supply the resin 208 onto the LED elements 205 in a half cut wafer state, the light emission characteristics of the light that the resin 208 emits when the excitation light from the light source part 245 is irradiated onto the light-passing member 243 on which the resin 208 is test supplied for light emission characteristic measurement are measured, and the appropriate resin supply quantity is revised based on the result of the measurement and the light emission characteristics prescribed beforehand, to derive an appropriate resin supply quantity of the resin 208 which should be supplied to the LED elements for practical production. Therefore, even if the light emission wavelength of the individual LED element 205 varies, by equalizing the light emission characteristics of the light emitting element 205*, production yield can be improved.

Because the resin 208 is supplied onto the LED elements 205 in a half cut wafer state, the area of resin supply objects can be confined. Thereby, in comparison with a related method of supplying resin after having mounted to a board including a plurality of individual boards, the exclusive area of resin supplying devices can be decreased, and the area productivity of manufacturing devices can be improved.

### Embodiment 3

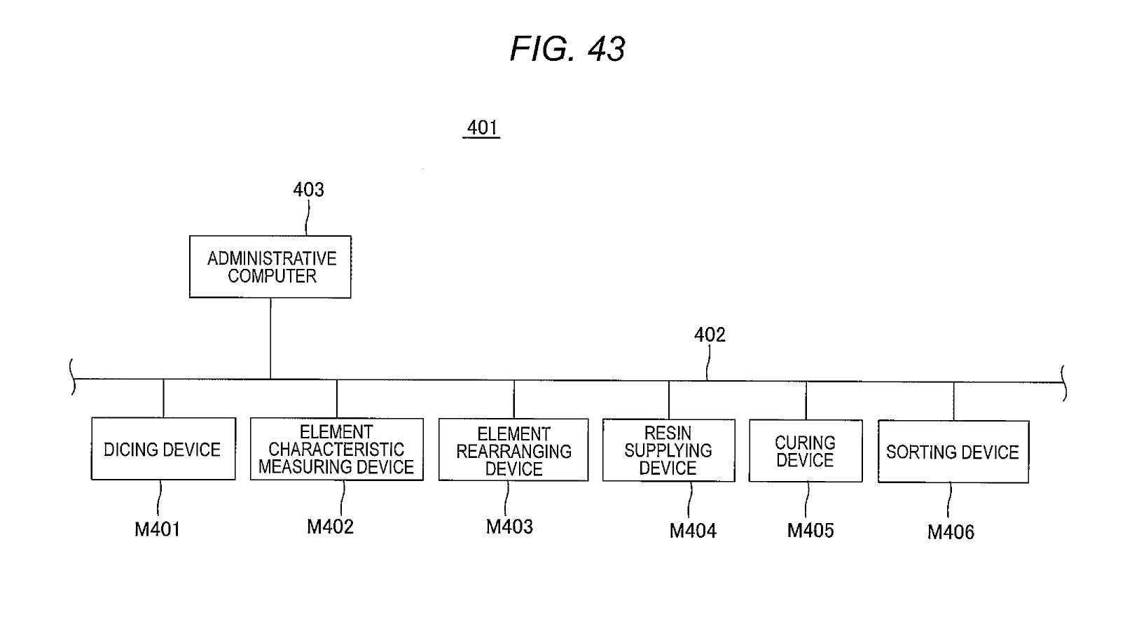

Next, an embodiment 3 of the invention is described with reference to the figures. First, with reference to FIG. 43, the construction of a light emitting element manufacturing system 401 is described. The light emitting element manufacturing system 401 has a function of manufacturing light emitting elements for white illumination which are made by coating the top surface of an LED element that emits blue light with resin including a fluorescent substance that emits yellow excited light whose color is complementary to blue. In this embodiment, as shown in FIG. 43, the light emitting element manufacturing system 401 is so constructed that each of a dicing device M401, an element characteristic measuring device M402, an element rearranging device M403, a resin supplying device M404, a curing device M405 and a sorting device M406 is connected by an LAN system 402, and these devices are collectively controlled by an administrative computer 403.

The dicing device M401 divides an LED wafer in which a plurality of LED elements are elaborated and attached onto a dicing sheet into individual LED elements. The element characteristic measuring device M402 is an element characteristic measuring part, and performs operations of measuring individually the light emission characteristics of LED elements in a half cut state that only semiconductor layers in a state of being attached and held on a dicing sheet are divided into individual pieces to obtain element characteristic information indicating the light emission characteristics of the LED elements, and making map data which associate the element position information indicating the position in the LED wafer of a divided LED element with the element characteristic information on the LED element for each LED wafer.

The element rearranging device M403 is an element rearranging part, and performs an element rearranging process by taking out the LED elements from the LED wafer and rearranging the LED elements on an element holding surface with a predetermined array based on map data. The resin supplying device M404, based on element array information indicating the array of the LED elements which are rearranged by the element rearranging device M403, and resin supply information transmitted through the LAN system 402 from the administrative computer 403, namely, the information that makes an appropriate resin supply quantity of the resin containing the fluorescent substance to obtain the LED element that has the regulated light emission characteristics to correspond to the element characteristic information, supplies resin of appropriate resin supply quantities to have the regulated light emission characteristics to the LED elements in a state of being held onto the element holding surface.

The curing device M405 hardens the resin by heating the LED elements to which the resin is supplied. Thereby, a light emitting element of the construction that the LED element is covered with a resin film of the resin containing the fluorescent substance is formed. The curing device M405, instead of heating to harden the resin, may be constructed to promote the hardening by irradiating UV (ultraviolet rays), or may be constructed to just place the resin as it is to be naturally hardened. The sorting device M406 measures the light emission characteristics of the plurality of light emitting elements held onto the element holding surface again, ranks the plurality of light emitting elements into individual predetermined characteristic ranges based on the results of the measurement, and individually transfers to element holding sheets.

In FIG. 43, an example in which the devices from the dicing device M401 to the sorting device M406 are placed in a line to construct a manufacturing line is shown. However, the light emitting element manufacturing system 401 does not necessarily adopt such a line construction, but may be so constructed that the procedural steps are sequentially performed respectively by the devices that are dispersedly placed, as far as the information communication to be described in the following discussion is suitably performed.

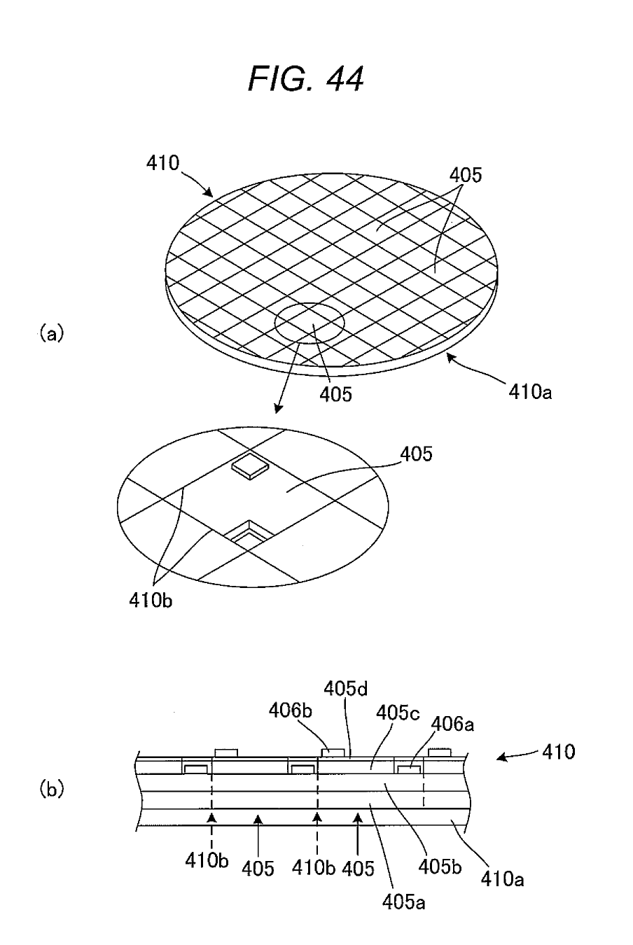

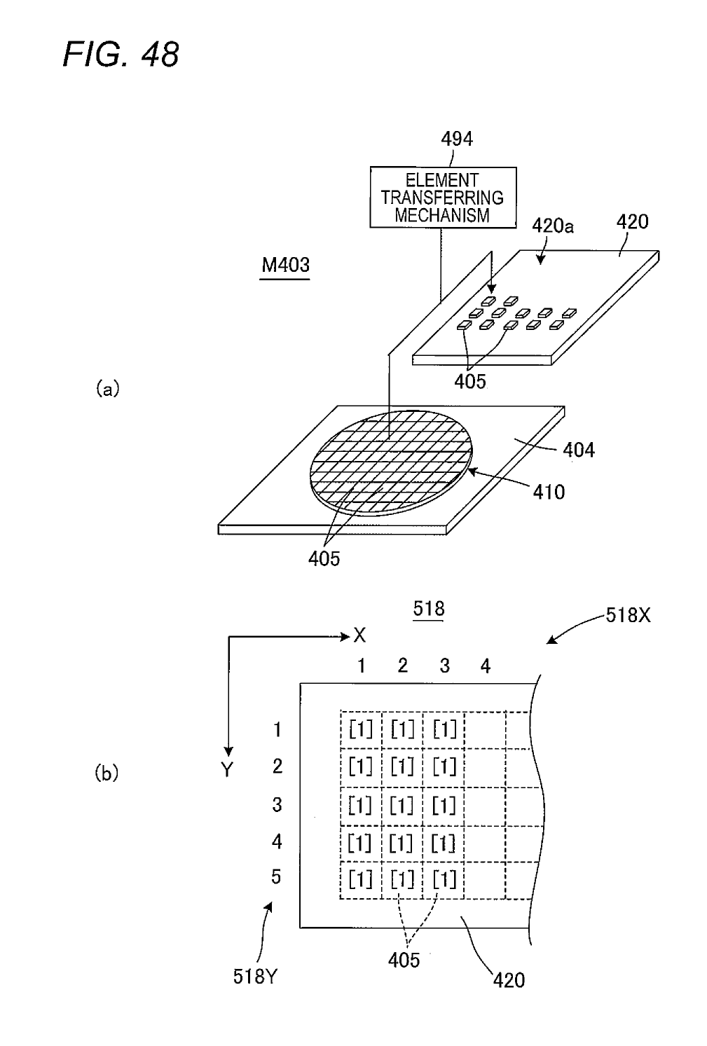

Herein, with reference to FIGS. 44(a) and 44(b), an LED wafer 410 and LED elements 405 on which operations in the light emitting element manufacturing system 401 are performed are described. As shown in FIG. 44(a), in the LED wafer 410, a plurality of LED elements 405 are elaborated in a lattice array, and a dicing sheet 410a is attached onto the under surface of the LED wafer 410. Scribe lines 410b which partition the LED elements 405 are set in the LED wafer 410, and by cutting the LED wafer 410 along the scribe lines 410b, a collection of LED elements 405 in a wafer state that the individual LED elements 405 are held by the dicing sheet 410a is formed. From the dicing step to the element rearranging step of the light emitting element manufacturing system 401, in a state that the LED wafer 410 is held within a wafer holder 404 (refer to FIG. 48(a)), the operations and conveyance are performed.

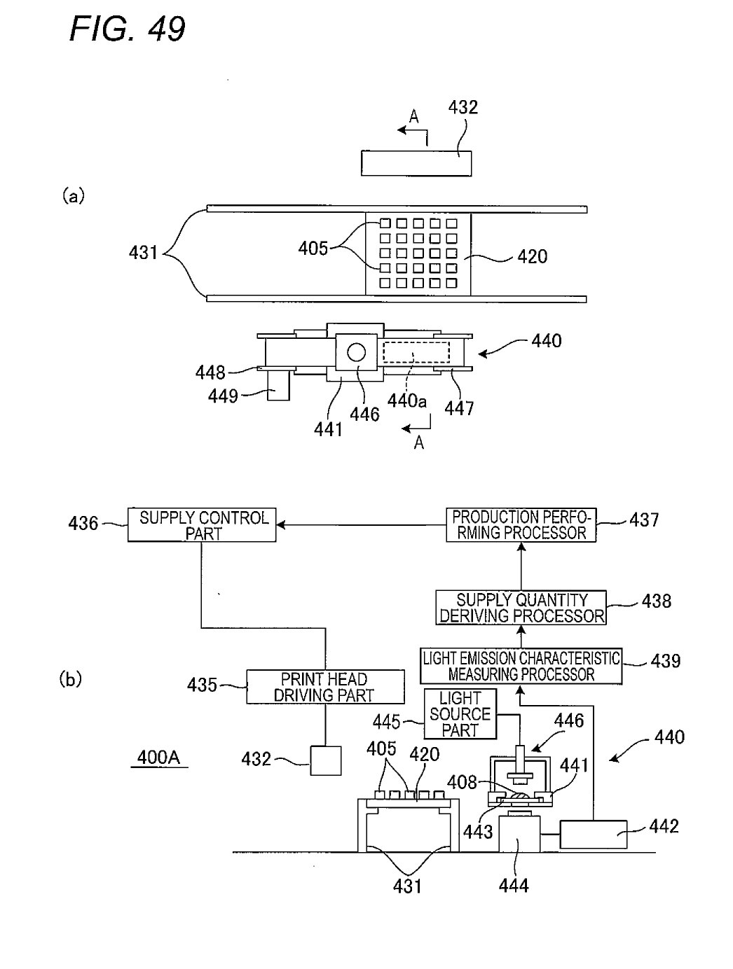

As shown in FIG. 44(a), the LED element 405 is constructed by laminating an N-type semiconductor 405b and a P-type semiconductor 405c on a sapphire board 405a and covering the surface of the P-type semiconductor 405c with a transparent electrode 405d, and an N-type part electrode 406a and a P-type part electrode 406b for external connections are formed on the N-type semiconductor 405b and the P-type semiconductor 405c, respectively. The LED element 405 is a blue LED, and is adapted to obtain quasi-white light by being combined with resin 408 (refer to FIG. 49(b)) which contains the fluorescent substance that emits yellow fluorescence whose color is complementary to blue. In this embodiment, the resin 408 is supplied by the resin supplying device M404 to the LED elements 405 in the wafer state as described before.

Due to various kinds of deviation factors in the manufacturing process, for example, the variation of the composition at the time of film formation in the wafer, it cannot be avoided that the light emission characteristics, such as light emission wavelength, of the LED elements 405, which are obtained by separating the wafer into individual pieces, vary. When such an LED element 405 is used as a light emitting element for illumination as it is, the light emission characteristics of the final product vary. To prevent the inferior quality due to the variation of the light emission characteristics, in the present embodiment, the light emission characteristics of the plurality of LED elements 405 are measured by the element characteristic measuring device M402 in a wafer state, element characteristic information that makes each of the LED elements 405 to correspond to data indicating the light emission characteristics of the LED element 405 is prepared, and an appropriate quantity of the resin 408 that corresponds to the light emission characteristics of the LED element 405 is supplied in the supply of the resin. To supply the appropriate quantity of the resin 408, resin supply information to be described below is prepared beforehand.

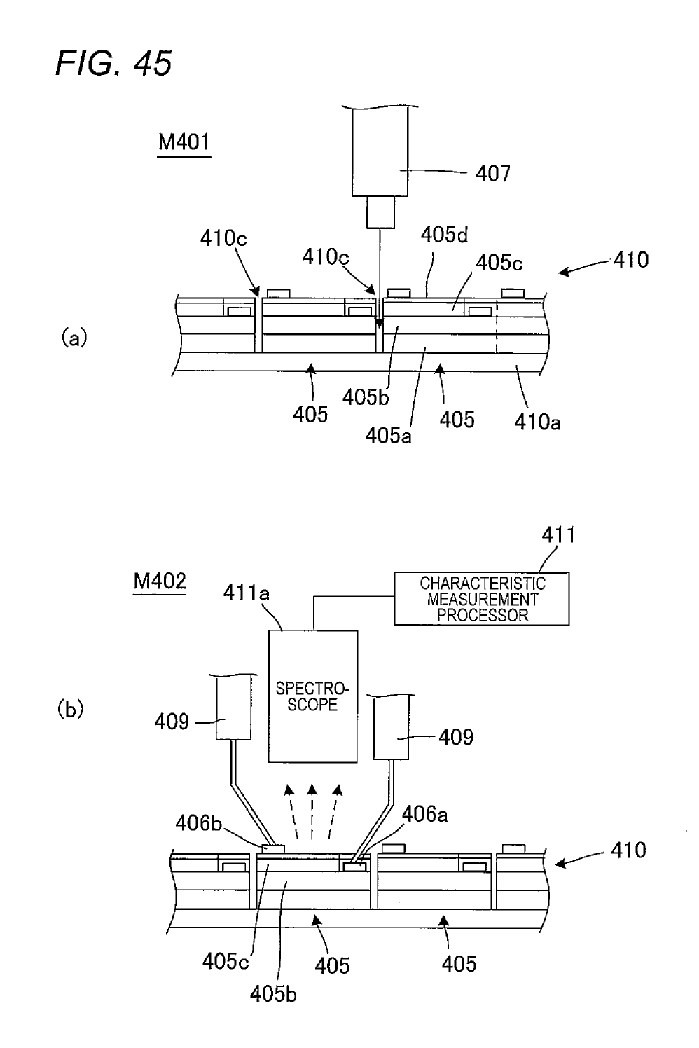

Next, the constructions and functions of the devices constructing the light emitting element manufacturing system 401 are described in the order of steps. First, the LED wafer 410 is sent to the dicing device M401 as shown in FIG. 45(a). When dicing ditches 410c which reach the dicing sheet 410a along the scribe lines 410b are formed in the LED wafer 410 by a laser cutting machine 407, the LED wafer 410 is divided into individual LED elements 405 in each of which the transparent electrode 405d, the P-type semiconductor 405c, the N-type semiconductor 405b, and the sapphire substrate 405a are laminated. Various methods can be used as the unit of the dicing. For example, individual LED elements 405 may be obtained with a method of mechanically cutting with a dicing saw, or by removing only the transparent electrode 405d, the P-type semiconductor 405c and the N-type semiconductor 405b in the thickness direction with a laser beam, and divides the sapphire substrate 405a by flaking to break those embrittled areas formed by the laser beam.

Next, as shown in FIG. 45(b), the LED wafer 410 after the dicing is sent to the element characteristic measuring device M402 where element characteristics indicating the light emission characteristics of the LED element 405 are measured. That is, while a spectroscope 411a is located right above an LED element 405 to be measured among the plurality of LED elements 405 in a wafer state of being attached and held onto the dicing sheet 410a, by making probes of a power supply device 409 touch the N-type part electrode 406a and the P-type part electrode 406b of the LED element 405, power is supplied to the N-type semiconductor 405b and the P-type semiconductor 405c to emit light. Then, a spectroscopic analysis of the light is performed to measure prescribed items such as light emission wavelength or light emission intensity, and the result of the measurement is processed by a characteristic measurement processor 411 so that element characteristic information indicating the light emission characteristics of the LED element 405 is obtained. This element characteristic measurement is performed sequentially for all the LED elements 405 constructing the LED wafer 410.

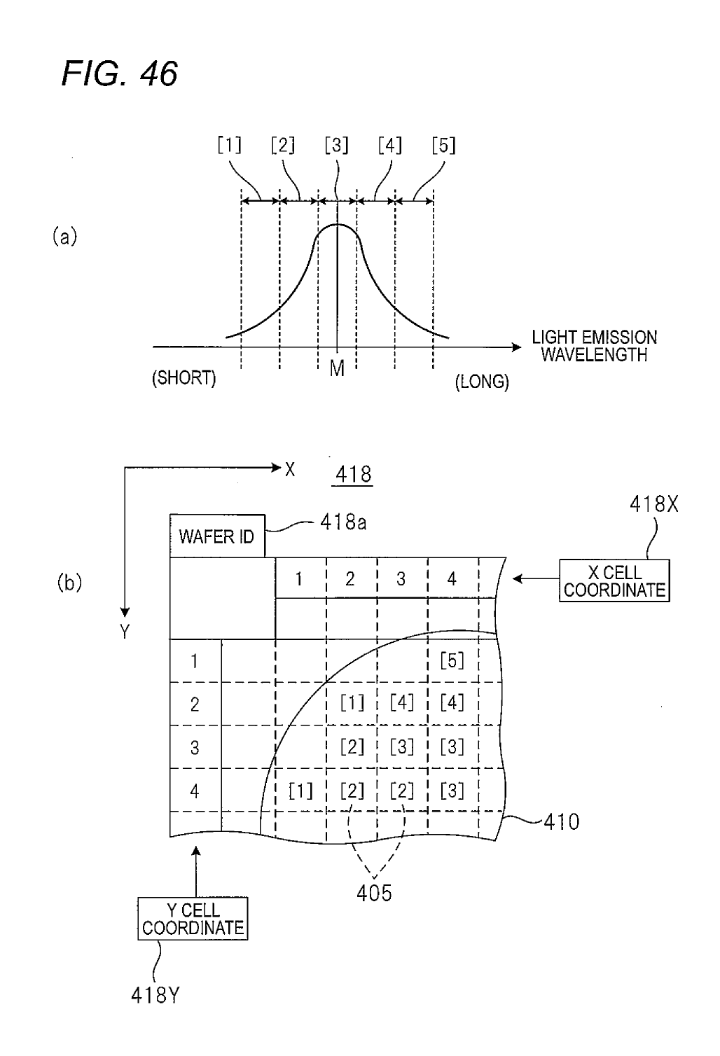

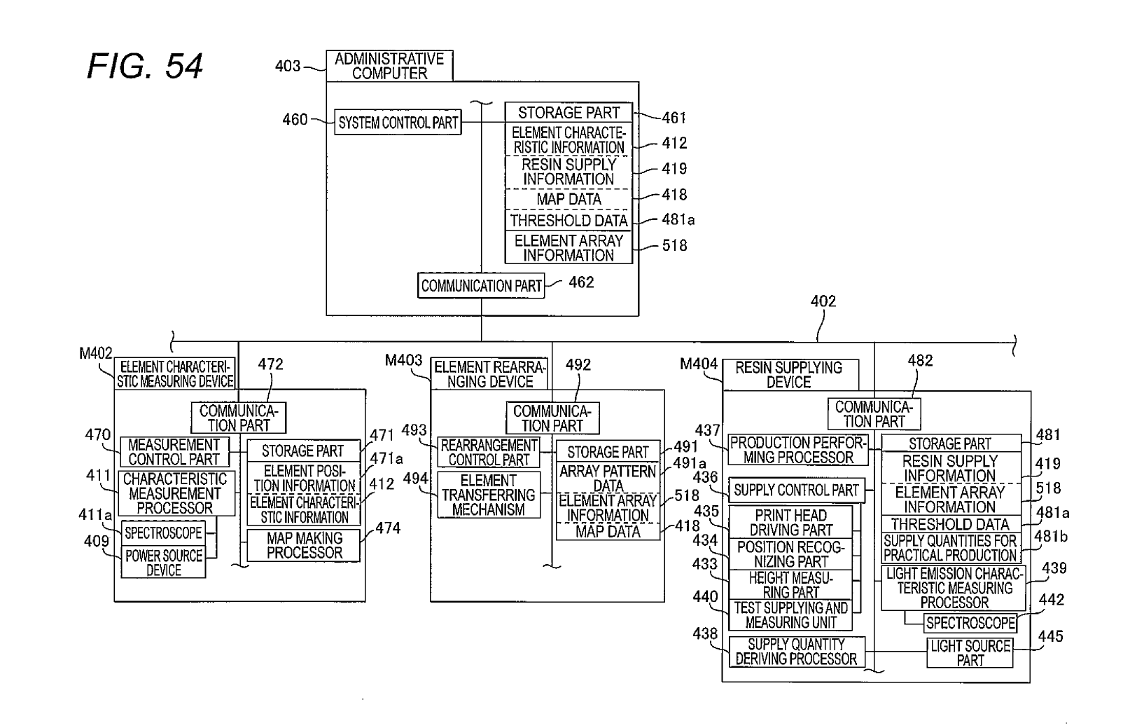

Next, the element characteristic information is described with reference to FIGS. 46(a) and 46(b). FIG. 46(a) show a standard distribution of light emission wavelength which is prepared beforehand as reference data for the LED elements 405 to be measured. By dividing a wavelength range that corresponds to the standard range in the distribution into a plurality of wavelength areas, the measured plurality of LED elements 405 are ranked by light emission wavelength. Herein, in response to each of the ranks that are set by dividing the wavelength range into five, Bin codes [1], [2], [3], [4] and [5] are given sequentially from the side of low wavelength. Based on the measurement result of the element characteristic measuring device M402, Bin codes are given to individual LED elements 405, and are stored as element characteristic information 412 in the storage part 471 (FIG. 54).

FIG. 46(b) shows map data 418 which associate the element position information indicating the position in the LED wafer 410 of a divided LED element 405 with the element characteristic information 412 on the LED element 405. Herein, an X cell coordinate 418X and a Y cell coordinate 418Y in a matrix array of the LED elements 405 in the LED wafer 410 are used as the element position information. That is, the map data 418 are constructed to make one of the Bind codes [1], [2], [3], [4] and [5] which is given to an individual LED element 405 based on the measurement result of the element characteristic measuring device M402 to correspond to the individual LED element 405 that is identified by the element position information, and by specifying a wafer ID 418a, the map data 418 of each of the individual LED wafers 410 can be read out.

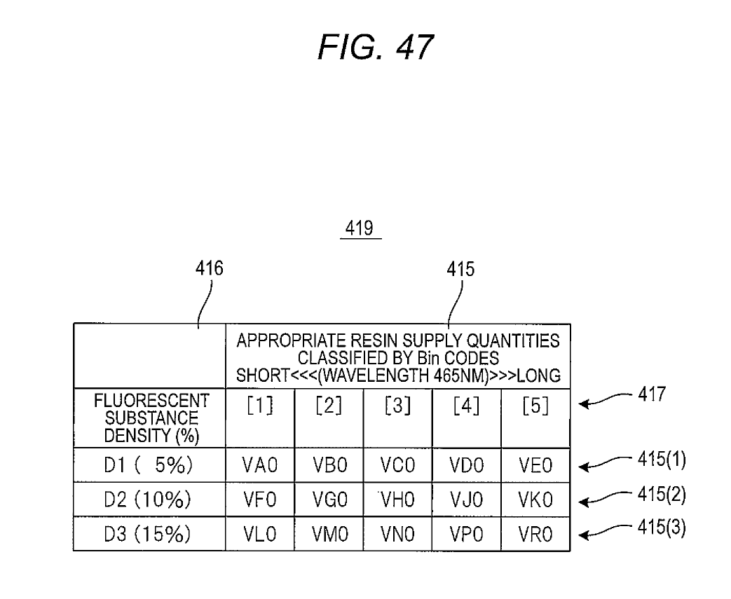

Then, the resin supply information prepared beforehand in response to the above-mentioned element characteristic information 412 is described with reference to FIG. 47. In the light emitting element of the construction to obtain white light by combining a YAG-related fluorescent substance with a blue LED, because the blue light that the LED element 405 emits is added and mixed with the yellow light that the fluorescent substance emits by being excited by the blue light, the quantity of the fluorescent substance particles in the resin film which covers the top surface of the LED element 405 becomes an important factor in ensuring the normal light emission characteristics of a finished light emitting element.

As mentioned above, because there are variations classified by the Bin codes [1], [2], [3], [4] and [5] in the light emission wavelengths of a plurality of LED elements 405 which become operation objects at the same time, the appropriate quantities of the fluorescent substance particles in the resin 408 supplied to cover the LED elements 405 differ based on the Bin codes [1], [2], [3], [4] and [5]. In this embodiment, as shown in FIG. 47, in the prepared resin supply information 419, appropriate resin supply quantities, classified based on the Bin codes, of the resin 408 which makes YAG-related fluorescent substance particles to be contained in, for example, silicone resin or epoxy resin are prescribed in nl (nanoliters) beforehand based on Bin code divisions 417. That is, when an appropriate resin supply quantity, shown in the resin supply information 419, of the resin 408 is supplied precisely to cover the LED element 405, the quantity of fluorescent substance particles in the resin covering the LED element 405 becomes an appropriate supply quantity of fluorescent substance particles, and thereby a normal light emission wavelength that is demanded is ensured in a finished product after the resin 408 is thermally hardened.

Herein, as shown in a fluorescent substance density column 416, a plurality of fluorescent substance densities (herein, three densities, or D1 (5%), D2 (10%) and D3 (15%)) indicating the density of fluorescent substance particles of the resin 408 are set, and the appropriate resin supply quantities are set to different numerical values which are used based on the fluorescent substance density of the used resin 408. That is, when the resin 408 of the fluorescent substance density D1 is supplied, for the Bin codes [1], [2], [3], [4] and [5], the resin 408 of appropriate resin supply quantities VA0, VB0, VC0, VD0 and VE0 (appropriate resin supply quantities 415(1)) are supplied respectively. Likewise, when the resin 408 of the fluorescent substance density D2 is supplied, for the Bin codes [1], [2], [3], [4] and [5], the resin 408 of appropriate resin supply quantities VF0, VG0, VH0, VJ0 and VK0 (appropriate resin supply quantities 415(2)) are supplied respectively. Further, when the resin 408 of the fluorescent substance density D3 is supplied, for the Bin codes [1], [2], [3], [4] and [5], the resin 408 of appropriate resin supply quantities VL0, VM0, VN0, VP0 and VR0 (appropriate resin supply quantities 415(3)) are supplied respectively. In this way, the appropriate resin supply quantities are set respectively for the plurality of fluorescent substance densities which are different, and this is because supplying the resin 408 of the most suitable fluorescent substance density based on the degree of the variation of the light emission wavelength is preferable for quality insurance.

Next, with reference to FIGS. 48(a) and 48(b), the functions of the element rearranging device M403 and the element array information generated by the element rearranging device M403 are described. As shown in FIG. 48(a), the element rearranging device M403 has functions of taking out the LED elements 405 after the light emission characteristic measurement with an element transferring mechanism 494 (refer to FIG. 54) from the LED wafer 410 which is held in the wafer holder 404, and rearranging the LED elements with a predetermined array on an element holding surface 420a formed on the top surface of an element holding member 420, based on the map data 418 and array pattern data 491a (refer to FIG. 54) set beforehand.

In this embodiment, the resin 408 may be supplied to the LED element 405 in a state that the LED element 405 is take out from the LED wafer 410 and held on the element holding surface 420a of the element holding member 420. Thereby, the LED elements 405 whose positions are fixed in the wafer state can be held on the element holding member 420 by being rearranged into a desirable array so that the resin supplying device M404 can perform the resin supplying operations more efficiently. In FIG. 48(a), an example is shown in which only one element holding member 420 corresponds to one LED wafer 410, but it is also possible to make a plurality of element hold members 420 to correspond to one LED wafer 410 as necessary.

The element array information 518 shown in FIG. 48(b) shows a rearranged element array with one pattern example of the array pattern data 491a. In the element array information 518, corresponding to X cell coordinates 518X and Y cell coordinates 518Y which identify array positions of the LED elements 405 set in the element holding member 420, the Bin code types of the LED elements 405 transferred to the respective array positions are prescribed. That is, in the pattern example shown here, only LED elements 405 corresponding to the same Bin code (here [1]) are arranged on one element holding member 420. The setting of the array pattern is arbitrary. A plurality of bin code types may be combined on the same element holding member 420, and other than the combination of bin codes, array direction, array pitch or the like can be arbitrarily set depending on the characteristics of the resin supplying device M404.

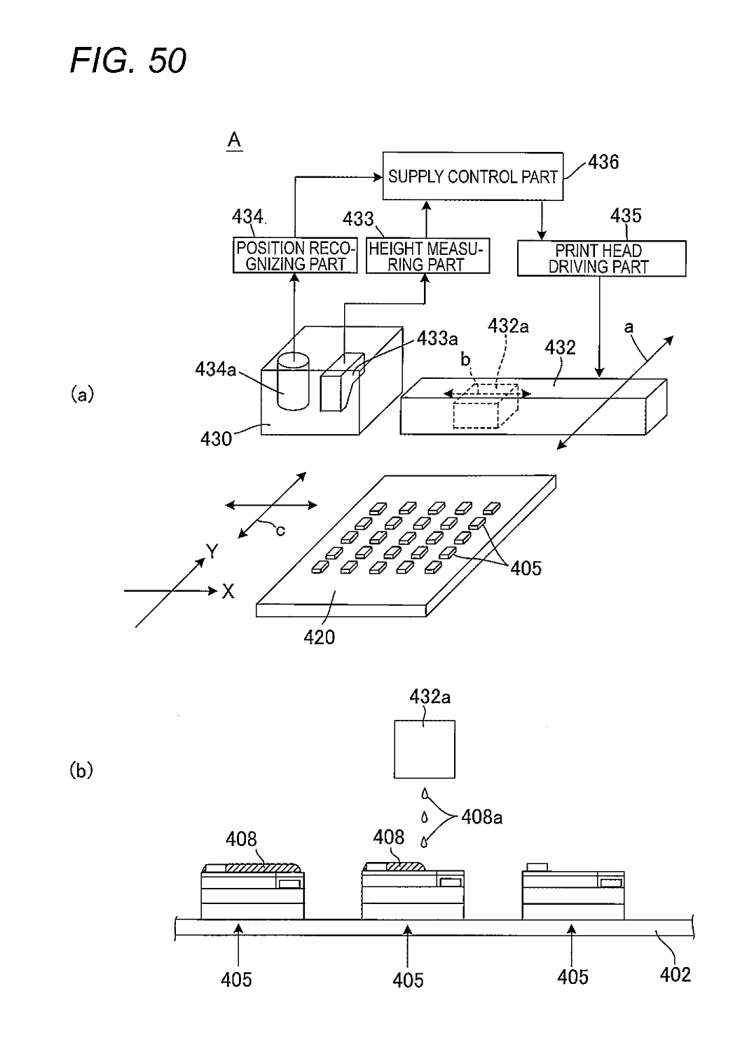

Next, with reference to FIGS. 49(a) to 50(b), a construction and functions of the resin supplying device M404 are described. The resin supplying device M404 has a function of supplying an appropriate resin supply quantity of resin 408 to obtain the prescribed light emission characteristics to each of the LED elements 405 which are held on the element holding surface 420a of the element holding member 420 based on the element array information 518 indicating the array of the LED elements 405 rearranged by the element rearranging device M403 and the resin supply information 419. As shown in a top view of FIG. 49(a), the resin supplying device M404 is constructed by disposing a resin supplying part 400A, which is shown in FIG. 49(b) with an A-A section, on a conveying mechanism 431 which conveys the element holding member 420 that holds LED elements 405 which are operation objects.

In this embodiment, a resin discharging device which discharges the resin 408 in an inkjet manner is used as the resin supplying part 400A. That is, the resin supplying part 400A is provided with a print head 432 whose longitudinal direction is towards the X direction (conveying direction in the conveying mechanism 431). As shown in FIG. 50(a), the print head 432 is provided with a built-in print nozzle unit 432a which discharges to supply a small droplet 408a of the resin 408 downwards in such a way that the discharging quantity is controllable, and when the print head 432 is driven by a print head driving part 435, the print head 432 is moved in the Y direction (arrow a) to above the element holding member 420 on which the LED elements 405 are arranged, and the print nozzle unit 432a is moved in the X direction (arrow b) in the print head 432. When the print head driving part 435 is controlled by a supply control part 436, the print nozzle unit 432a is moved to an arbitrary position in the X direction and in the Y direction, and the discharging quantity of the small droplet 408a from the print nozzle unit 432a can be controlled.

A measuring head 430 including a camera 434a and a height measuring unit 433a is disposed beside the print head 432 to be movable in the X and Y directions (arrow c). When the measuring head 430 is moved to above the element holding member 420 on which the LED elements 405 are arranged, and an image which is acquired by imaging the element holding member 420 with the camera 434a is recognized by a position recognizing part 434, the position of an individual LED element 405 in the element holding member 420 is recognized. The position recognition result is transmitted to the supply control part 436.

By aligning the height measuring unit 433a with a surface to be measured to perform a distance measuring operation with a laser beam, the height of the surface to be measured is measured. Herein, the top surface of the LED element 405 before the small droplet 408a is supplied by the print nozzle unit 432a becomes the surface to be measured, and the height measurement result by the height measuring part 433 is transmitted to the supply control part 436. When the small droplet 408a is supplied by the print nozzle unit 432a, the supply control part 436 performs a height measurement on the top surface of the LED element 405 with the height measuring part 433. When the print head 432 is controlled by the supply control part 436 in this way, as shown in FIG. 50(b), the small droplet 408a is discharged from the print nozzle unit 432a, and the resin 408 of an appropriate resin supply quantity prescribed in the resin supply information 419 is supplied to the top surface of each of the LED elements 405 which are arranged on the element holding member 420. That is, the resin supplying part 400A has functions of discharging a variable supply quantity of the resin 408, and supplying the resin 408 at any supply positions.

Beside the conveying mechanism 431, a test supplying and measuring unit 440 is placed in the movement range of the print head 432. The test supplying and measuring unit 440 has a function of determining whether the supply quantity of the resin 408 is appropriate before a supplying operation for practical production of supplying the resin 408 to the LED elements 405 which are arranged on the element holding member 420, by measuring the light emission characteristics of the resin 408 which is test supplied. That is, light emission characteristics when a light that a light source part 445 for measurement emits is irradiated on a light-passing member 443 where the resin 408 is test supplied by the resin supplying part 400A are measured by a light emission characteristic measuring part which includes a spectroscope 442 and a light emission characteristic measuring processor 439, and by comparing the measurement result with a threshold set beforehand, it is determined whether the set resin supply quantity prescribed in the resin supply information 419 shown in FIG. 47 is appropriate.

The composition and characteristic of the resin 408 containing fluorescent substance particles are not necessarily stable, and even if the appropriate resin supply quantities are set in the resin supply information 419 beforehand, it cannot be avoided that the density and the resin viscosity of the fluorescent substance fluctuate over time. Therefore, even if the resin 408 is discharged according to discharging parameters corresponding to the appropriate resin supply quantities set beforehand, it is possible that the resin supply quantity itself varies from the set appropriate value, or the resin supply quantity itself is appropriate but the supplied quantity of the fluorescent substance particles varies from what should be originally supplied due to density change.

In order to solve these problems, in the embodiment, a test supply for the purpose of detecting whether an appropriate supply quantity of fluorescent substance particles is supplied is performed by the resin supplying device M404 in a predetermined interval, and by performing the measurement of the light emission characteristic of the resin which is test supplied, the supply quantity of the fluorescent substance particles which meets the requirement of the original light emission characteristics is stabilized. Thus, the resin supplying part 400A included in the resin supplying device M404 shown in the present embodiment has a function of performing, at the same time, a supplying process for measurement in which the resin 408 is test supplied to the light-passing member 443 for the above-mentioned light emission characteristic measurement, and a supplying process for production in which the resin 408 is supplied to a plurality of LED elements 405 which are rearranged on the element holding surface 420a of the element holding surface 420 for practical production. Either of the supplying process for measurement and the supplying process for production is performed when the resin supplying part 400A is controlled by the supply control part 436.

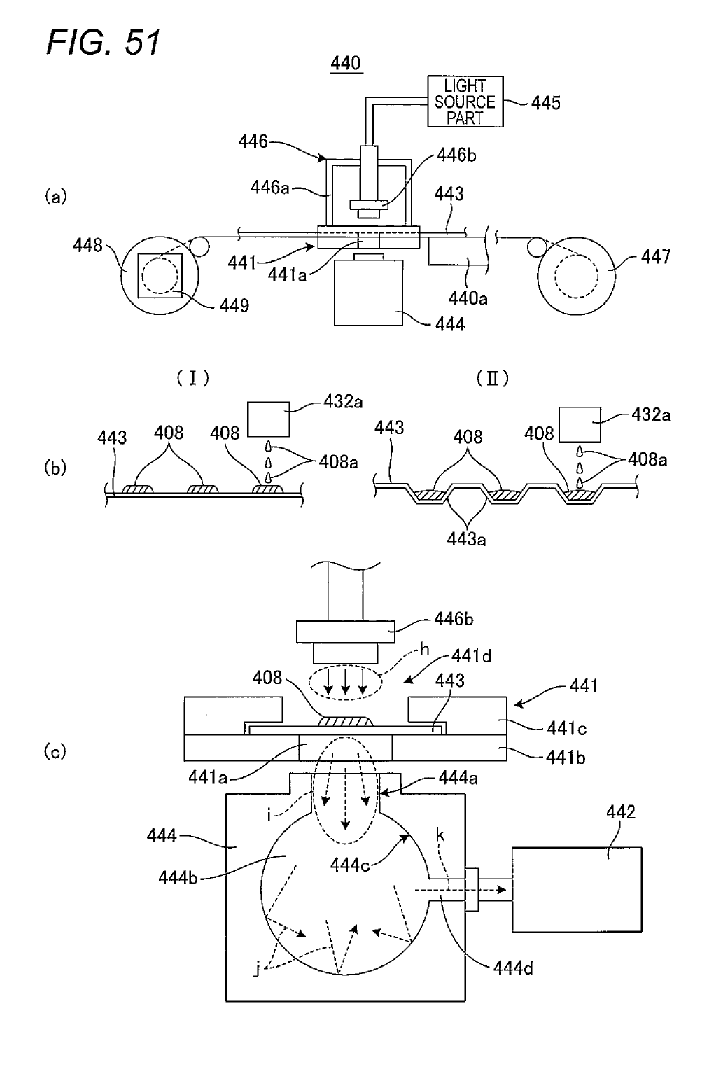

With reference to FIGS. 51(a) to 51(c), the detailed construction of the test supplying and measuring unit 440 is described. As shown in FIG. 51(a), the light-passing member 443 is supplied by being wound and accommodated in a supply reel 447, and after the light-passing member 443 is sent along the top surface of a test supplying stage 440a, the light-passing member 443 passes between a light-passing member carrying part 441 and an irradiating part 446, and is wound into a collecting reel 448 which is driven by a winding motor 449. Besides the collecting method of winding back into the collecting reel 448, various methods including a sending method in which the light-passing member 443 is sent into a collecting box by a sending mechanism can be adopted as a mechanism for collecting the light-passing member 443.

The irradiating part 446 has a function of irradiating measurement light emitted by the light source part 445 onto the light-passing member 443, and is constructed by disposing a light converging tool 446b, in which the measurement light which the light source part 45 emits is guided by fiber cables, in a shading box 446a which has the function of a simple dark box. The light source part 445 has a function of emitting excitation light to excite the fluorescent substance contained in the resin 408. In the present embodiment, the light source part 445 is placed above the light-passing member carrying part 441, and irradiates the measurement light to the light-passing member 443 from above through the light converging tool 446b.

Herein, tape material of a predetermined width formed of a planar sheet member of transparent resin, or the above tape material in which embossed parts 443a are protruded downwards from the bottom surface (emboss type), or the like are used as the light-passing member 443 (refer to FIG. 51(b)). In the process of sending the light-passing member 443 on the test supplying and measuring unit 440, the resin 8 is test supplied by the print head 432 onto the light-passing member 443. This test supply is performed as shown in FIG. 51(b), in which a prescribed supply quantity of the resin 408 in a form of the small droplet 408a is discharged (printed) by the print nozzle unit 432a to the light-passing member 443 which is supported by the test supplying stage 440a from below.

(I) of FIG. 51(b) shows that the resin 408 of the set appropriate discharging quantity prescribed in the resin supply information 419 is supplied onto the light-passing member 443 formed of the above-mentioned tape material. (II) of FIG. 51(b) shows that the resin 408 of the set appropriate discharging quantity is supplied similarly in the embossed parts 443a of the light-passing member 443 formed of the above-mentioned emboss type tape material. As described later, because the resin 408 which is supplied onto the test supplying stage 440a is test supplied to empirically determine whether the fluorescent substance supply quantity to the LED element 405 is appropriate, when the resin 408 is continuously supplied onto the light-passing member 443 at a plurality of points by the print head 432 with the same test supply movement, the supplying is performed by making the supply quantities to be different progressively based on the known data indicating the correlation of light emission characteristic measurement and the supply quantity.

After the resin 408 is test supplied in this way, white light emitted by the light source part 445 is irradiated from above through the light converging tool 446b to the light-passing member 443 which is led in the shading box 446a. The light that passes the resin 408 which is supplied onto the light-passing member 443 is received by an integrating sphere 444, which is disposed below the light-passing member carrying part 441, through a light-passing opening 441a which the light-passing member carrying part 441 is provided with. FIG. 51(c) shows structures of the light-passing member carrying part 441 and the integrating sphere 444. The light-passing member carrying part 441 is so constructed that an upper guide member 441c having a function of guiding two end surfaces of the light-passing member 443 is installed on the top surface of a lower support member 441b which supports the under surface of the light-passing member 443.

The light-passing member carrying part 441 has functions of guiding the light-passing member 443 at the time of conveying in the test supplying and measuring unit 440, and carrying and maintaining the position of the light-passing member 443 on which the resin 408 is test supplied in the supplying process for measurement. The integrating sphere 444 has functions of integrating the transmitted light which is irradiated from the light converging tool 446b (arrow h), and passes through the resin 408, and leading to the spectroscope 442. That is, the integrating sphere 444 has a spherical reflecting surface 444c inside, and the transmitted light (arrows i) which enters from an opening 444a located right under the light-passing opening 441a is incident in a reflection space 444b from the opening 444a which is provided at the top of the integrating sphere 444, leaves from an output part 444d as the measurement light (arrow k) in a process of repeating total reflection (arrows j) with the spherical reflecting surface 444c, and is received by the spectroscope 442.

In the above-mentioned construction, the white light emitted by a light emitting element package used for the light source part 445 is irradiated to the resin 408 which is test supplied onto the light-passing member 443. In this process, the blue light component included in the white light excites the fluorescent substance in the resin 408 to emit yellow light. The white light in which this yellow light and the blue light are added and mixed is irradiated upwards from the resin 408, and is received by the spectroscope 442 through the above-mentioned integrating sphere 444.

The received white light is analyzed by the light emission characteristic measuring processor 439 (FIG. 49(b)) to measure the light emission characteristics. Light emission characteristics such as color tone rank or beam of the white light are detected, and, as a detection result, deviations from prescribed light emission characteristics are detected out. The integrating sphere 444, the spectroscope 442 and the light emission characteristic measuring processor 439 construct a light emission characteristic measuring part which measures light emission characteristics of the light that the resin 408 emits when the excitation light (herein, white light emitted by a white LED) emitted by the light source part 445 is irradiated from above to the resin 408 which is supplied onto the light-passing member 443 by receiving the light that the resin 408 emits from below the light-passing member 443. In the present embodiment, the light emission characteristic measuring part is constructed by placing the integrating sphere 444 below the light-passing member 443 so that the light that the resin 408 emits is received through the opening 444a of the integrating sphere 444.

The effects that are described below are obtained by constructing the light emission characteristic measuring part as above. That is, for the supply shape of the resin 408 which is test supplied onto the light-passing member 443 shown in FIG. 51(b), because the bottom side always contacts with the top surface of the light-passing member 443 or the bottom surfaces of the embossed parts 443a, the bottom surface of the resin 408 always has a standard height that is prescribed by the light-passing member 443. Therefore, the height difference between the bottom surface of the resin 408 and the opening 444a of the integrating sphere 444 is always kept constant. On the other hand, for the top surface of the resin 408, due to disturbance such as supply condition of the print nozzle unit 432a, the same liquid surface shape and height may not be necessarily realized, and the interval between the top surface of the resin 408 and the light converging tool 446b will vary.

If stability is considered when the irradiation light irradiated to the top surfaces of the resin 408 and the transmitted light from the under surfaces of the resin 408 are compared, because the irradiation light irradiated to the resin 408 is irradiated through the light converging tool 446b, the convergence degree is high, and the influence that the variation in the intervals between the top surfaces of the resin 408 and the light converging tool 446b has on the light transmission can be ignored. On the other hand, because the transmitted light which passes through the resin 408 is the excited light because the fluorescent substance is excited inside the resin 408, the divergence degree is high, and the influence that the variation in the distances between the under surfaces of the resin 408 and the opening 444a has on the degree to which light is taken in by the integrating sphere 444 cannot be ignored.

In the test supplying and measuring unit 440 shown in the present embodiment, because such a construction is adopted that the light that the resin 408 emits when the excitation light emitted by the light source part 445 as constructed above is irradiated from above to the resin 408 is received by the integrating sphere 444 from below the light-passing member 443, it is possible to determine stable light emission characteristics. By using the integrating sphere 444, it is not necessary to separately provide a darkroom structure in the light receiving part, and it is possible to compactify the device and to reduce the device cost.

As shown in FIG. 49(b), the measurement result of the light emission characteristic measuring processor 439 is sent to a supply quantity deriving processor 438, and the supply quantity deriving processor 438 revises the appropriate resin supply quantity of the resin 408 based on the measurement result of the light emission characteristic measuring processor 439 and the light emission characteristics prescribed beforehand, and derives the appropriate resin supply quantity of the resin 408 which should be supplied onto the LED element 405 as what is used for practical production. The new appropriate discharging quantity derived by the supply quantity deriving processor 438 is sent to a production performing processor 437, and the production performing processor 437 orders the supply control part 436 with the newly derived appropriate resin supply quantity. Thereby, the supply control part 436 controls the print head 432 to make the print head 432 perform a supplying process for production to supply the resin 408 of the appropriate resin supply quantity onto the LED element 405 that is mounted on the board 414.

In the supplying process for production, first, the resin 408 of the appropriate resin supply quantity prescribed in the resin supply information 419 is really supplied, and the light emission characteristics are measured when the resin 408 is in an unhardened state. Based on the obtained measurement result, a quality item range of the light emission characteristic measurement value when the light emission characteristics of the resin 408 that is supplied in the supplying process for production are measured is set, and this quality item range is used as a threshold (refer to the threshold data 481a shown in FIG. 54) with which whether a quality item is obtained in the supplying process for production is determined.

That is, in the resin supplying method in the light emitting element manufacturing system shown in the present embodiment, while a white LED is used as the light source part 445 for the light emission characteristic measurement, a light emission characteristic, which deviates from the normal light emission characteristics which are obtained from a finished product when the resin which is supplied on the LED element 405 is in a hardened state for a light emission characteristic difference because the resin 408 is in an unhardened state, is used as the light emission characteristic prescribed beforehand which is the basis of setting the threshold with which whether a quality item is obtained in the supplying process for production is determined. Thereby, the control of the resin supply quantity in the process of supplying resin onto the LED element 405 can be performed based on the normal light emission characteristics on the finished product.

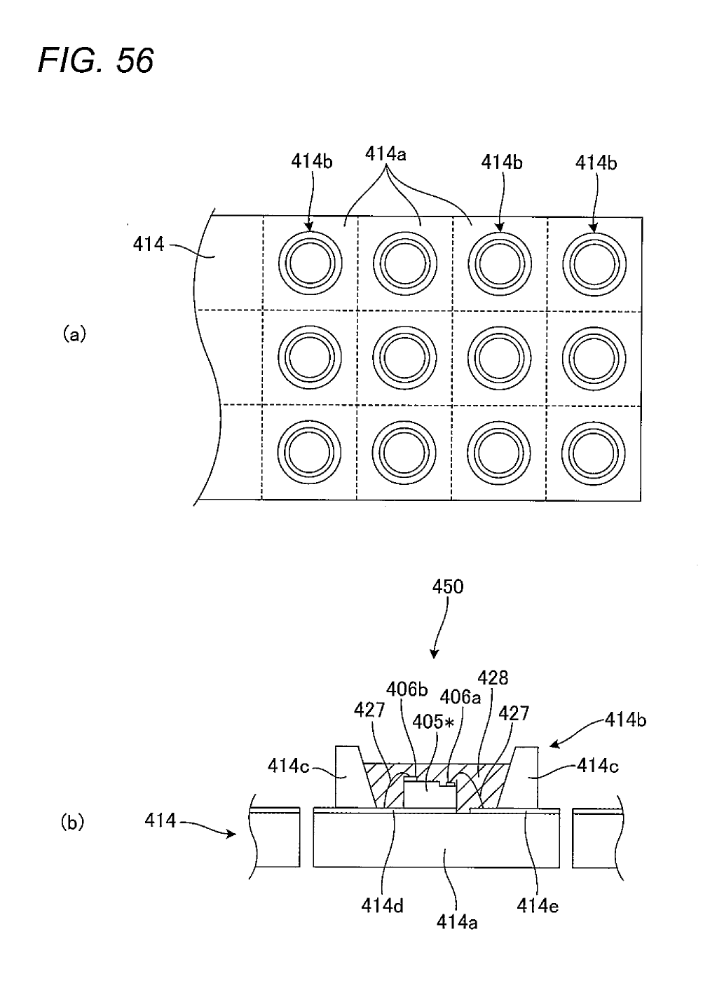

In the present embodiment, a light emitting element package 450 (refer to FIG. 56(b)) which emits white light is used as the light source part 445. Thereby, the light emission characteristic measurement of the test supplied resin 408 can be performed with a light of the same characteristic as the excitation light emitted in the light emitting element package 450 of the finished product, and a more reliable detection result can be obtained. It is not necessary to require using the same light emitting element package 450 as what is used in a finished product. In the light emission characteristic measurement, a light source device which can stably emits blue light of a constant wavelength (for example, a blue LED or a blue laser light source which emit blue light) can be used as a light source part for detection. However, by using the light emitting element package 450 which emits white light using the blue LED, there is an advantage that a light source device of stable quality can be chosen at a low cost. It is also possible to take out blue light of a predetermined wavelength by using a band pass filter.

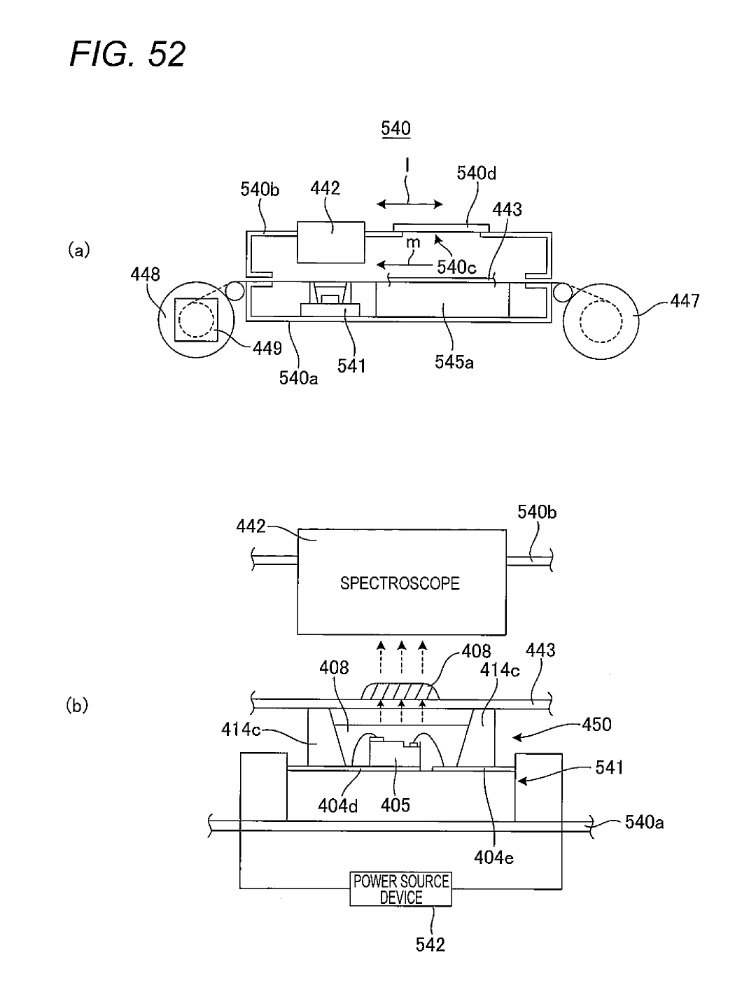

Instead of the test supplying and measuring unit 440 of the above-mentioned construction, a test supplying and measuring unit 540 of the construction shown in FIG. 52(a) may be used. That is, as shown in FIG. 52(a), the test supplying and measuring unit 540 has such an outside construction that a cover part 540b is disposed above a horizontal base 540a of a slim shape. The cover part 540b is provided with an opening 540c, and the opening 540c can be opened with a sliding window 540d which is used in supplying and is slidable (arrow 1). Inside the test supplying and measuring unit 540, a test supplying stage 545a which supports the light-passing member 443 from below, a light-passing member carrying part 541 which carries the light-passing member 443, and a spectroscope 442 which is disposed above the light-passing member carrying part 541 are provided.

The light-passing member carrying part 541 includes a light source device which emits excitation light to excite the fluorescent substance like the light source part 445 shown in FIG. 49(b). The excitation light is irradiated from below by the light source device to the light-passing member 443 on which the resin 408 is test supplied in a supplying process for measurement. Like the example shown in FIGS. 51(a) to 51(c), the light-passing member 443 is supplied by being wound and accommodated in the supply reel 447. After the light-passing member 443 is sent along the top surface of the test supplying stage 545a (arrow m), the light-passing member 443 passes between the light-passing member carrying part 541 and the spectroscope 442, and is wound into the collecting reel 448 which is driven by the winding motor 449.

When the sliding window 540d used in supplying is slid to an open state, the top surface of the test supplying stage 545a is exposed upwards, and it is possible for the print head 432 to test supply the resin 408 on the light-passing member 443 carried on the top surface. This test supplying is performed in which a prescribed supply quantity of small droplet 408a is discharged by the print nozzle unit 432a to the light-passing member 443 which is supported by the test supplying stage 545a from below.

FIG. 52(b) shows that by moving the light-passing member 443 on which the resin 408 is test supplied on the test supplying stage 545a, to make the resin 408 to be located above the light-passing member carrying part 541, and dropping the cover part 540b, a dark room for the light emission characteristic measurement is formed between the cover part 540b and the base 540a. The light emitting element package 450 emitting white light is used as a light source device in the light-passing member carrying part 541. In the light emitting element package 450, wiring layers 414e and 414d connected to the LED element 405 are connected to a power source device 542. By switching ON the power source device 542, electricity for light emission is supplied to the LED element 405 and thereby the light emitting element package 450 emits white light.

In the process that the white light is irradiated to the resin 408 test supplied on the light-passing member 443 after the white light passes through the resin 408, a white light, in which yellow light that the fluorescent substance in the resin 408, which is excited by the blue light included in the white light, emits and the blue light are added and mixed, is irradiated upwards from the resin 408. The spectroscope 442 is placed above the test supplying and measuring unit 540. The white light irradiated from the resin 408 is received by the spectroscope 442. The received white light is analyzed by the light emission characteristic measuring processor 439 to measure the light emission characteristic. Light emission characteristics such as color tone rank or beam of the white light are detected, and, as a detection result, deviations from prescribed light emission characteristics are detected out. That is, the light emission characteristic measuring processor 439 measures the light emission characteristic of the light that the resin 408, which is supplied onto the light-passing member 443, emits when the excitation light emitted from the LED element 405, which is the light source part, is irradiated to the resin 408. The measurement result of the light emission characteristic measuring processor 439 is sent to the supply quantity deriving processor 438, and the processes like the example shown in FIGS. 49(a) and 49(b) are performed.

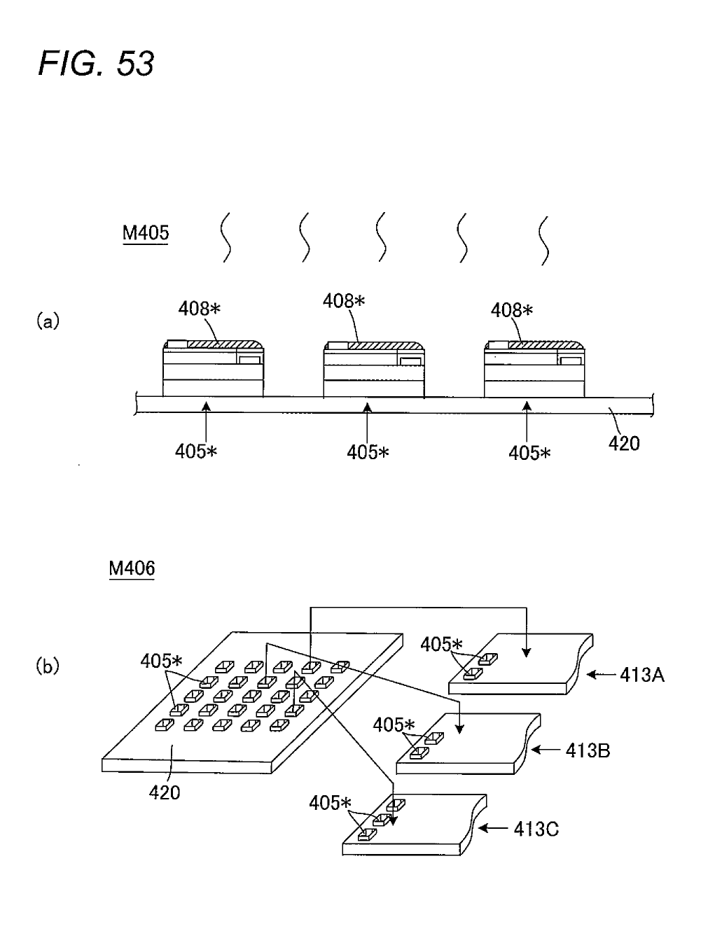

The LED elements 405 to which the resin is supplied in this way are sent to the curing device M405 in a state of being held on the element holding member 420. As shown in FIG. 53(a), the resin 408 is hardened by heating the LED elements 405. Thereby, the top surfaces of the LED elements 405 are covered with a resin film 408* formed when the resin 408 containing the fluorescent substance is hardened, and light emitting elements 405* are formed. Then, the element holding member 420 on which the light emitting elements 405* are held is sent to the sorting device M406 where the light emission characteristics of the plurality of light emitting elements 405* are measured again. Based on a result of the measurement, as shown in FIG. 53(b), the plurality of light emitting elements 405* which are held on the element holding member 420 are ranked into individual predetermined characteristic ranges and respectively transferred to the plurality of element holding sheets 413A, 413B, 413C and the like. Whether the sorting device M406 in the light emitting element manufacturing system 401 is necessary is determined in consideration of the precision of the light emission characteristics demanded from a finished product and/or the precision of the resin supply quantity revision of the resin supplying device M404, and the process of the sorting device M406 is not necessarily required.

Next, with reference to FIG. 54, the construction of a control system of the light emitting element manufacturing system 401 is described. Among the component elements of the devices that construct the light emitting element manufacturing system 401, those component elements that are related to the transmission/reception and update processing of the element characteristic information 412, the resin supply information 419, the map data 418, the element array information 518 and the threshold data 481a are shown in the administrative computer 403, the element characteristic measuring device M402, the element rearranging device M403 and the resin supplying device M404.

In FIG. 54, the administrative computer 403 includes a system control part 460, a storage part 461 and a communication part 462. The system control part 460 collectively controls light emitting element package manufacturing operations of the light emitting element manufacturing system 401. Besides programs and data necessary for control processes of the system control part 460, the element characteristic information 412, the resin supply information 419, and, as needed, the map data 418, threshold data 481a and the element array information 518, are stored in the storage part 461. The communication part 462 is connected to other devices through the LAN system 402 and delivers control signals and data. The resin supply information 419 are transmitted from outside through the LAN system 402 and the communication part 462 or through an independent storage medium such as a CD ROM, a USB memory storage, or a SD card, and are stored in the storage part 461.

The element characteristic measuring device M402 includes a measurement control part 470, a storage part 471, a communication part 472, the characteristic measurement processor 411 and a map making processor 474. The measurement control part 470 controls all parts described below based on various programs and data stored in the storage part 471 to perform element characteristic measuring operations of the element characteristic measuring device M402. Besides programs and data necessary for the control processes of the measurement control part 470, element position information 471a and the element characteristic information 412 are stored in the storage part 471. The element position information 471a is data indicating the arranged positions of the LED elements 405 in the LED wafer 410. The element characteristic information 412 is data of the result of a measurement by the characteristic measurement processor 411.

The communication part 472 is connected to other devices through the LAN system 402, and delivers control signals and data. The map making processor 474 (map data making part) performs the process of making the map data 418 for every LED wafer 410 which associate the element position information 471a stored in the storage part 471 with the element characteristic information 412 on the LED element 405. The map data 418 such made are transmitted to the element rearranging device M403 as forward feeding data through the LAN system 402. The map data 418 may be transmitted to the element rearranging device M403 from the element characteristic measuring device M402 via the administrative computer 403. In this case, as shown in FIG. 54, the map data 418 are stored in the storage part 461 of the administrative computer 403.

The element rearranging device M403 includes a rearrangement control part 493, a storage part 491, the element transferring mechanism 494, and a communication part 492. The rearrangement control part 493 controls the element transferring mechanism 494 to perform an element rearranging process to take out LED elements 405 from a LED wafer 410 and rearrange the LED elements 405 onto the element holding member 420. At this time, the array pattern data 491a and the map data 418 stored in the storage part 491 are referred to. In the element rearranging process, the element array information 518 shown in FIG. 48(b) is made by the rearrangement control part 493 and stored in the storage part 491.

The resin supplying device M404 includes the supply control part 436, a storage part 481, a communication part 482, the production performing processor 437, the supply quantity deriving processor 438, and the light emission characteristic measuring processor 439. The supply control part 436, by controlling the print head driving part 435 which forms the resin supplying part 400A, the position recognizing part 434, the height measuring part 433 and the test supplying and measuring unit 440, performs processes to make the supplying process for measurement in which the resin 408 is test supplied onto the light-passing member 443 used for light emission characteristic measurement, and the supplying process for production in which the resin 408 is supplied onto the LED element 405 for practical production to be performed.

Besides programs and data necessary for control processes of the supply control part 436, the resin supply information 419, the element array information 518, the threshold data 481a and supply quantities for practical production 481b are stored in the storage part 481. The resin supply information 419 is transmitted from the administrative computer 403 through the LAN system 402, and the element array information 518 is transmitted from the element rearranging device M403 through the LAN system 402 similarly. The communication part 482 is connected to other devices through the LAN system 402 and delivers control signals and data.

The light emission characteristic measuring processor 439 performs processes to measure the light emission characteristics of the light that the resin 408 emits when the excitation light emitted from the light source part 445 is irradiated to the resin 8 which is supplied onto the light-passing member 443. The supply quantity deriving processor 438 performs calculating processes to derive the appropriate resin supply quantity of the resin 408 which should be supplied onto the LED element 405 for practical production by revising the appropriate resin supply quantity based on the measurement result of the light emission characteristic measuring processor 439 and the light emission characteristic prescribed beforehand. The production performing processor 437 makes the supplying process for production, in which the resin of the appropriate resin supply quantity is supplied on the LED element 405, to be performed by ordering the supply control part 436 with the appropriate resin supply quantity derived by the supply quantity deriving processor 438.

In the construction shown in FIG. 54, processing functions except those functions to perform the operations specific to the devices, for example, the function of the map making processor 474 which the element characteristic measuring device M402 is provided with and the function of the supply quantity deriving processor 438 which the resin supplying device M404 are provided with, are not necessarily included in the devices. For example, it is also possible that the functions of the map making processor 474 and the supply quantity deriving processor 438 may be covered by the calculation processing function that the system control part 460 of the administrative computer 403 has, and necessary signal transmission and reception may be performed through the LAN system 402.

In the construction of the above-mentioned light emitting element manufacturing system 401, each of the element characteristic measuring device M402, the element rearranging device M403 and the resin supplying device M404 is connected to the LAN system 402. Thus, the administrative computer 403 in which the resin supply information 419 is stored in the storage part 461 and the LAN system 402 become a resin information providing unit that provides the information, which makes the appropriate resin supply quantity of the resin 408 to correspond to the element characteristic information to obtain a light emitting element that possesses the prescribed light emission characteristics, as the resin supply information 419 to the resin supplying device M404.

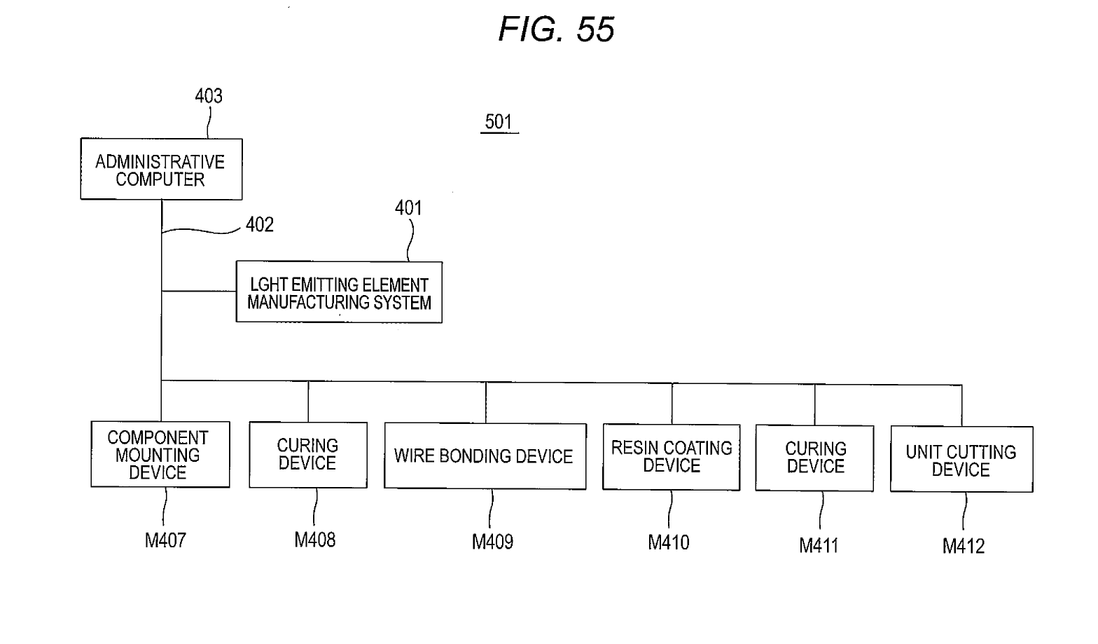

Next, with reference to FIG. 55, the construction of a light emitting element package manufacturing system 501, which manufactures light emitting element packages using the light emitting elements manufactured by the light emitting element manufacturing system 401 is described. The light emitting element package manufacturing system 501 is constructed by combining a component mounting device M407, a curing device M408, a wire bonding device M409, a resin coating device M410, a curing device M411 and a piece-cutting device M412 into the light emitting element manufacturing system 401 of the construction shown in FIG. 43.

The component mounting device M407 mounts light emitting element elements 405* manufactured by the light emitting element manufacturing system 401 by bonding the light emitting elements 5* to a board 414 (refer to FIGS. 56(a) and 56(b)), which becomes a base of LED packages, with resin adhesive. The curing device M408 hardens the resin adhesive, which is used in the bonding at the time of the mounting, by heating the board 414 after the light emitting elements 405* are mounted. The wire bonding device M409 connects electrodes of the light emitting elements 405* to electrodes of the board 414 with bonding wires. The resin coating device M410 coats transparent resin for sealing on each of the light emitting elements 405* on the board 414 after the wire bonding. The curing device M411 hardens the transparent resin, which is coated to cover the light emitting elements 405*, by heating the board 414 after the resin coating. The piece-cutting device M412 cuts the board 414 after the resin is hardened for each of the light emitting elements 405* to separate into individual light emitting element packages. Thereby, the light emitting element packages which are separated into individual pieces are completed.

In FIG. 55, an example in which the devices from the component mounting device M407 to the piece-cutting device M412 are placed in a line to construct a manufacturing line is shown. However, the light emitting element package manufacturing system 501 does not necessarily adopt such a line construction, but may be so constructed that the procedural steps are sequentially performed respectively by the devices that are dispersedly placed. It is also possible to place a plasma processing device which performs a plasma processing for the purpose of cleaning electrodes prior to the wire bonding, and a plasma processing device which performs a plasma processing for the purpose of surface reforming to improve coherency of the resin after the wire bonding and prior to the resin coating, before and after the wire bonding device M409.

With reference to FIGS. 56(a) and 56(b), the board 414, on which operations are performed, the light emitting elements 405* and a light emitting element package 450 as a finished product in the light emitting element package manufacturing system 501, are described. As shown in FIG. 56(a), the board 414 is a multiple-pieces-connected board in which a plurality of individual boards 414a, each of which becomes the base of one light emitting element package 450 in a finished product, are elaborated, and one LED mounting part 414b, where the light emitting element 405* is mounted, is formed on each of the individual boards 414a. The LED package 450 shown in FIG. 56(b) is completed by mounting the light emitting element 405* in the light emitting element mounting part 414b for each of the individual boards 414a, then coating the transparent resin 428 for sealing in the LED mounting part 414b to cover the light emitting element 405*, and, after the resin 428 is hardened, cutting the board 414, whose steps have been completed, for each of the individual boards 414a.

As shown in FIG. 56(b), the individual board 414a is provided with a reflective part 414c of a cavity shape which has, for example, a circular or an elliptic ring-like bank to form the LED mounting part 414b. An N-type part electrode 406a and a P-type part electrode 406b of the light emitting element 405* which is loaded inside the reflective part 414c are connected to wiring layers 414e and 414d which are formed on the top surface of the individual board 414a with bonding wires 427, respectively. The resin 428 is coated at a predetermined thickness inside the reflective part 414c to cover the light emitting element 405* in this state, and white light that is emitted from the light emitting element 405* is irradiated to pass through the transparent resin 428.

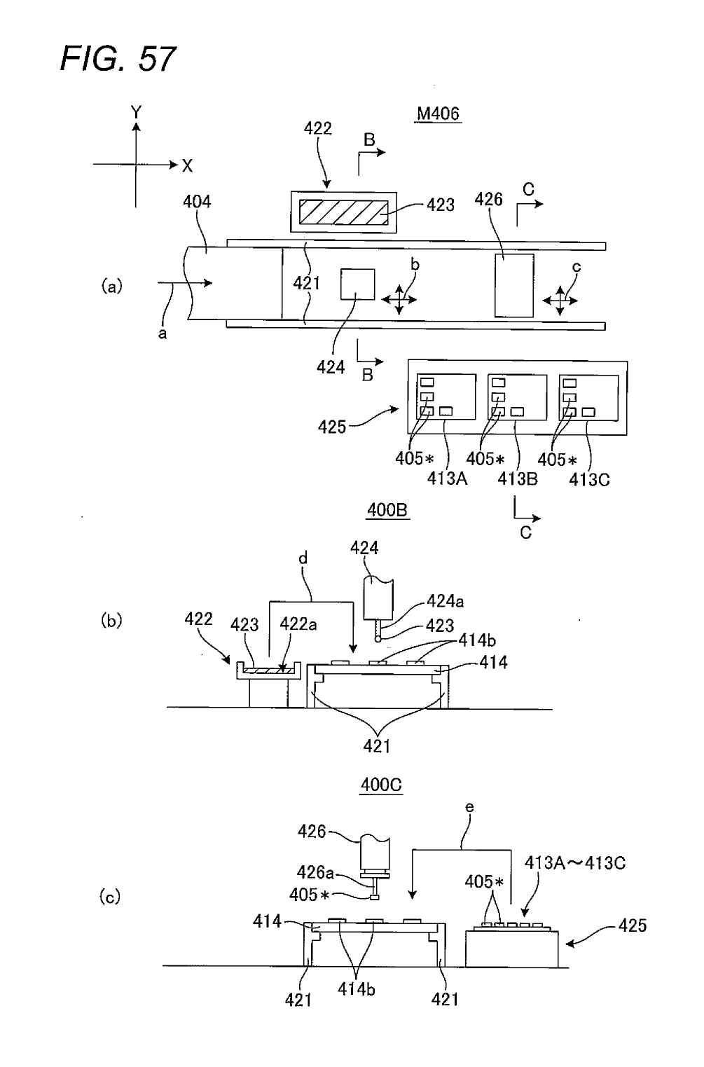

Next, with reference to FIGS. 57(a) to 57(c), a construction and functions of the component mounting device M407 are described. As shown in the top view of FIG. 57(a), the component mounting device M407 includes a board conveying mechanism 421 which conveys a board 414, which is an operation object, supplied from upstream towards the board conveying direction (arrow a). To the board conveying mechanism 421, an adhesive supplying part 400B shown in FIG. 57(b) with a B-B section, and a component mounting part 400C shown in FIG. 57(c) with a C-C section are disposed sequentially from upstream. The adhesive supplying part 400B includes an adhesive supplying part 422 which is placed beside the board conveying mechanism 421, and which supply resin adhesive 423 in the form of a coating of a predetermined film thickness, and an adhesive transferring mechanism 424 which is movable in the horizontal direction (arrow b) above the board conveying mechanism 421 and the adhesive supplying part 422. The component mounting part 400C includes a component supplying mechanism 425 which is placed beside the board conveying mechanism 421 and which holds the element holding sheets 413A, 413B, 413C and the like as shown in FIG. 53(b), and a component mounting mechanism 426 which is movable in the horizontal direction (arrow c) above the board conveying mechanism 421 and the component supplying mechanism 425.

As shown in FIG. 57(b), the board 414 imported into the board conveying mechanism 421 is positioned in the adhesive supplying part 400B, and the resin adhesive 423 is supplied on the LED mounting part 414b formed on each of the individual boards 414a. That is, first, by moving the adhesive transferring mechanism 424 to above the adhesive supplying part 422, a transferring pin 424a is made to touch a coating of the resin adhesive 423 formed on a transferring surface 422a, and the resin adhesive 423 is attached. Then, by moving the adhesive transferring mechanism 424 to above the board 414, and dropping the transferring pin 424a to the LED mounting part 414b (arrow d), the resin adhesive 423 which is attached to the transferring pin 424a is supplied to an element mounting position in the LED mounting part 414b with the transferring.

Then, the board 414 after the adhesive is supplied is conveyed downstream and is positioned in the component mounting part 400C as shown in FIG. 57(C), and a light emitting element 405* is mounted on each of the LED mounting parts 414b after the adhesive is supplied. That is, first, by moving the component mounting mechanism 426 to above the component supplying mechanism 425, and dropping a mounting nozzle 426a relative to either of the element holding sheets 413A, 413B, 413C and the like which are held on the component supplying mechanism 425, and a light emitting element 405* is held and taken out by the mounting nozzle 426a. Then, by moving the component mounting mechanism 426 to above the LED mounting part 414b of the board 414, and dropping the mounting nozzle 426a (arrow e), the light emitting element 405* held in the mounting nozzle 426a is mounted to the element mounting position where the adhesive is supplied in the LED mounting part 414b.

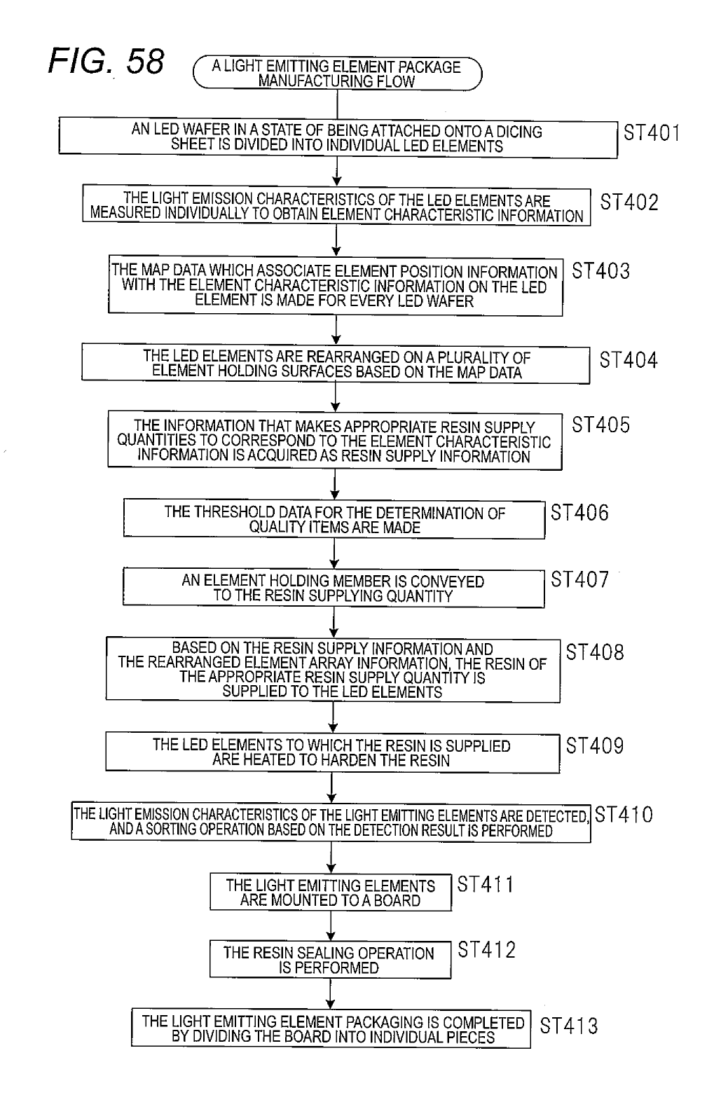

Next, light emitting element package manufacturing processes performed by the light emitting element package manufacturing system 501 are described with reference to the figures along a flow of FIG. 58. Herein, the light emitting element packages 450 which are constructed by mounting light emitting elements 405* in which the top surfaces of LED elements 405 are coated with the resin 408 containing the fluorescent substance beforehand on the board 414 are manufactured.

First, an LED wafer 410, which is an operation object, is imported into the dicing device M401, and as shown in FIG. 45(a), the LED wafer 410 in a state that a plurality of LED elements 405 are elaborated and attached onto a dicing sheet 410a is divided for each of the LED elements 405 (ST401) (dicing step). Then, the LED wafer 410 is imported into the element characteristic measuring device M402, and as shown in FIG. 45(b), an element characteristics measurement is performed. That is, the light emission characteristics of the individually divided LED elements 405 in a state of being attached and held onto the dicing sheet 410a are measured individually to obtain the element characteristic information indicating the light emission characteristics of the LED elements 405 (ST402) (element characteristic measuring step).

Then, map data 418 are made by the map making processor 474 of the element characteristic measuring device M402. That is, the map data 418 (refer to FIG. 46(b)) which associate the element position information indicating the position in the LED wafer 410 of the individual divided LED element 405 with the element characteristic information on the LED element 405 is made for every LED wafer 410 (ST403) (map data making step). Then, the LED wafer 410 is conveyed to the element rearranging device M403 where the LED elements 405 are taken out from the LED wafer 410 and rearranged with a predetermined array on the element holding surface 420a based on the array pattern data 491a and the map data 418 (ST404) (element rearranging step). The information that makes appropriate resin supply quantities of the resin 408 to correspond to the element characteristic information to obtain light emitting elements 405* which possess the prescribed light emission characteristics is acquired from the administrative computer 403 through the LAN system 402 as the resin supply information 419 (refer to FIG. 47) (ST405) (resin information acquiring step).

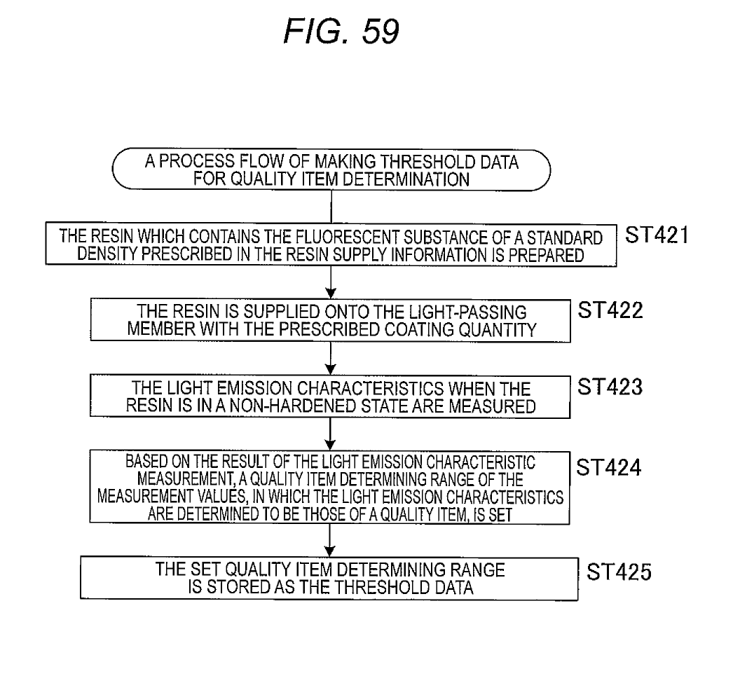

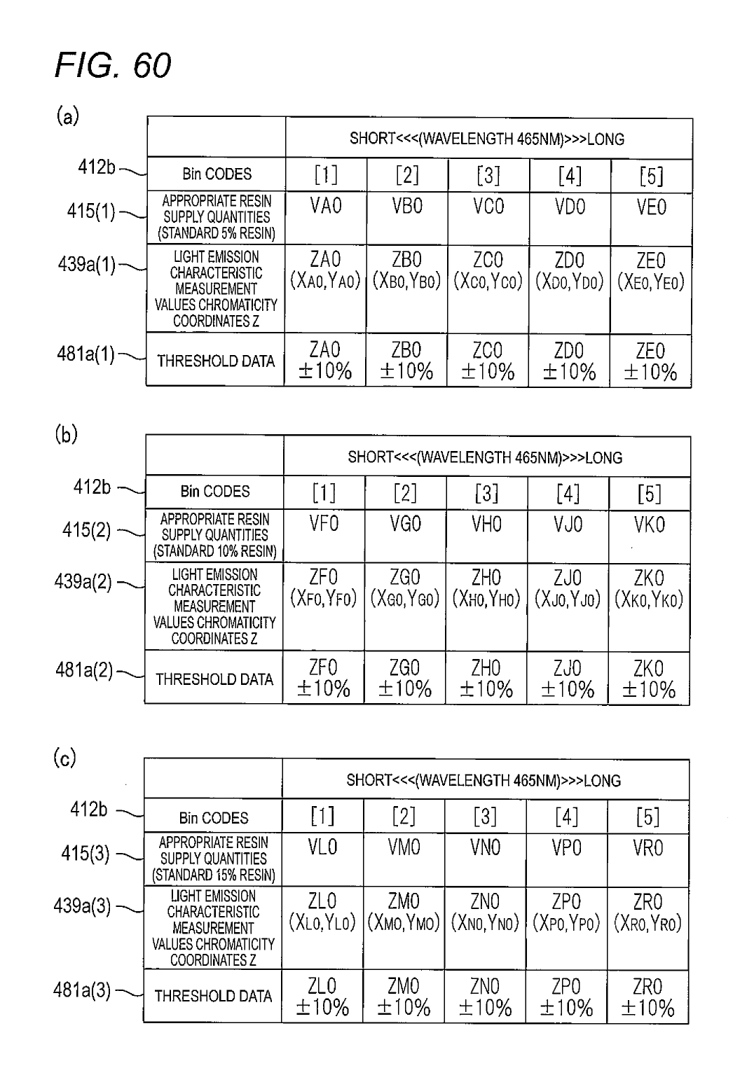

Then, the threshold data making process for the determination of quality items is performed (ST406). This process is performed to set the threshold (refer to the threshold data 481a shown in FIG. 54) to determine whether quality items are obtained in the supplying for production, and is performed repeatedly for the supplying for production corresponding to each of the Bin codes [1], [2], [3], [4] and [5]. The threshold data making process is described in detail with reference to FIGS. 59 and 60(a) to 60(c) and the above FIG. 18. In FIG. 59, first, the resin 408 which contains the fluorescent substance of standard densities prescribed in the resin supply information 419 is prepared (ST421).

After having set the resin 408 in the print head 432, the print nozzle unit 432a is moved to the test supplying stage 440a of the test supplying and measuring unit 440, and the resin 408 is supplied onto the light-passing member 443 with the prescribed supply quantity (appropriate resin supply quantity) shown in the resin supply information 419 (ST422). Then, the resin 408 supplied onto the light-passing member 443 is moved onto the light-passing member carrying part 441, the LED element 405 is made to emit light, and the light emission characteristics when the resin 408 is in an unhardened state are measured by the light emission characteristic measuring part of the above-mentioned construction (ST423). Based on light emission characteristic measurement values 439a which are the measurement result of the light emission characteristics measured by the light emission characteristic measuring part, quality item determining ranges of the measurement values, in which the light emission characteristic is determined to be that of a quality item, are set (ST424). The set quality item determining ranges are stored as the threshold data 481a in the storage part 481, and are transferred to the administrative computer 403 and stored in the storage part 461 (ST425).

FIGS. 60(a) to 60(c) show the threshold data made in this way, namely, the light emission characteristic measurement values obtained when the resin is in an unhardened state after having supplied the resin 408 that contains fluorescent substance of standard densities, and the quality item determining ranges (the thresholds) of the measurement values to determine whether the light emission characteristic is that of a quality item. FIGS. 60(a), 60(b) and 60(c) show thresholds corresponding to the Bin codes [1], [2], [3], [4] and [5] when the fluorescent substance densities in the resin 408 are 5%, 10% and 15%, respectively.

For example, as shown in FIG. 60(a), when the fluorescent substance density of the resin 408 is 5%, the supply quantity shown in each of the appropriate resin supply quantities 415(1) corresponds to each of the Bin codes 412b, and the measurement results after the light emission characteristics of the light that the resin 408 emits by irradiating blue light of the LED element 405 to the resin 408 coated with each of the supply quantities are measured by the light emission characteristic measuring part are shown in the light emission characteristic measurement values 439a (1). Based on each of the light emission characteristic measurement values 439a (1), the threshold data 481a (1) are set.

For example, the measurement result after the light emission characteristics of the resin 408 which is supplied with the appropriate resin supply quantity VA0 corresponding to the Bin code [1] are measured is represented by a chromaticity coordinate point ZA0 (XA0, YA0) in the chromaticity table shown in the above FIG. 18. Around the chromaticity coordinate point ZA0, a predetermined range of the X coordinate and the Y coordinate in the chromaticity table (for example, +−10%) is set as the quality item determining range (threshold). For the appropriate resin supply quantities corresponding to other Bin codes [2] to [5], similarly, the quality item determining ranges (thresholds) are set based on the light emission characteristic measurement results (refer to the chromaticity coordinate points ZB0 to ZE0 in the chromaticity table shown in FIG. 18). Herein, the predetermined range set as the threshold is appropriately set depending on the demanded precision level of the light emission characteristics of the light emitting element package 450 as a product.

Likewise, FIGS. 60(b) and 60(c) show the light emission characteristic measurement values and the quality item determining ranges (thresholds) when the fluorescent substance densities of the resin 408 are 10% and 15%, respectively. In FIGS. 60(b) and 60(c), the appropriate resin supply quantities 415(2) and the appropriate resin supply quantities 415(3) respectively show the appropriate resin supply quantities when the fluorescent substance densities are 10% and 15%, respectively. The light emission characteristic measurement values 439a (2) and the light emission characteristic measurement values 439a (3) respectively show the light emission characteristic measurement values when the fluorescent substance densities are 10% and 15%, respectively, and the threshold data 481a (2) and the threshold data 481a (3) respectively show the quality item determining ranges (thresholds) when the fluorescent substance densities are 10% and 15%, respectively.

The threshold data made in this way can be used properly in the supplying operation for production based on the Bin code 412b which an LED element 405, on which the coating operation is performed, falls into. The threshold data making process shown in (ST406) may be performed as an off-line operation by an independent detecting device provided separately from the light emitting element package manufacturing system 501, and the threshold data 481a that are stored in the administrative computer 403 beforehand may be transmitted to the resin supplying device M404 via the LAN system 402 and used.

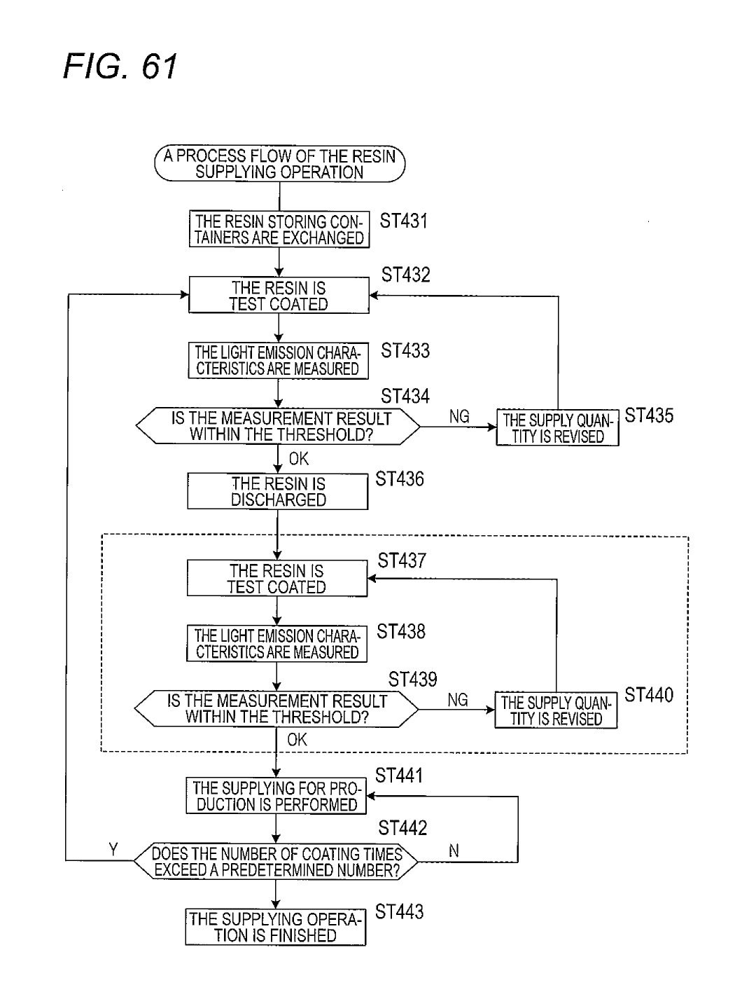

After resin supplying operations become possible in this way, the element holding member 420 which holds the LED element 405 is conveyed to the resin supplying device M404 (ST407). Based on the resin supply information 419 and the rearranged element array information 518, the resin 408 of the appropriate resin supply quantity to obtain the prescribed light emission characteristics is supplied to each of the LED elements 405 which are held on the element holding surface 420a of the element holding member 420 (ST408) (resin supplying step). The resin supplying operation is described in detail with reference to FIG. 61 and the above FIG. 20.

First, when the resin supplying operation is started, the exchange of resin storing containers is performed as needed (ST431). That is, the resin cartridge mounted into the print head 432 is exchanged with a resin cartridge which accommodates the resin 408 of the fluorescent substance density selected in response to the characteristics of the LED element 405. Then, the resin 408 for light emission characteristic measurement is test supplied on the light-passing member 443 by the resin supplying part 400A which discharges a variable supply quantity of the resin 408 (supplying step for measurement) (ST432). That is, the resin 408 of the appropriate resin supply quantity (VA0 to VE0) for either of the Bin codes 412b prescribed in the resin supply information 419 shown FIG. 47 is supplied onto the light-passing member 443 which is led out to the test supplying stage 440a in the test supplying and measuring unit 440. At this time, even if the print head 432 is ordered with discharging parameters corresponding to the appropriate resin supply quantity (VA0 to VE0), the real resin supply quantity that is discharged by the print nozzle unit 432a and supplied onto the light-passing member 443 is not necessarily the above appropriate resin supply quantity because, for example, the character of the resin 408 changes over time. As shown in FIG. 61(a), the real resin supply quantity becomes VA1 to VE1 which are somewhat different from VA0 to VE0.

Then, by sending the light-passing member 443 in the test supplying and measuring unit 440, the light-passing member 443, on which the resin 408 is test supplied, is sent and carried on the light-passing member carrying part 441 (light-passing member carrying step). The excitation light to excite the fluorescent substance is emitted from the light source part 445 which is placed above the light-passing member carrying part 441. The light that the resin 408 emits, when the excitation light is irradiated to the resin 408 which is supplied on the light-passing member 443 from above, is received by the spectroscope 442 through the integrating sphere 444 from below the light-passing member 443, and the light emission characteristics of the light are measured by the light emission characteristic measuring processor 439 (light emission characteristic measuring step) (ST433).

Thereby, as shown in the above FIG. 20(b), the light emission characteristic measurement values represented in chromaticity coordinate points Z (refer to the above FIG. 18) are provided. This measurement result does not necessarily correspond to the light emission characteristic prescribed beforehand, namely, the standard chromaticity coordinate points ZA0 to ZE0 at the time of supplying the appropriate resin shown in FIG. 60(a) because of, for example, the deviation of the above-mentioned supply quantity and the density change of the fluorescent substance particles of the resin 408. Therefore, the deviations (ΔXA, ΔYA) to (ΔXE, ΔYE) indicating the differences in the X and Y coordinates between the obtained chromaticity coordinate points ZA1 to ZE1 and the standard chromaticity coordinate points ZA0 to ZE0 at the time of supplying the appropriate resin shown in FIG. 60(a) are obtained, and it is determined whether it is necessary to revise to obtain a desired light emission characteristic.

It is determined whether or not the measurement result is within the threshold (ST434). As shown in the above FIG. 20(c), by comparing the deviations obtained in (ST433) and the thresholds, it is determined whether the deviations (ΔXA, ΔYA) to (ΔXE, ΔYE) are within +−10% of ZA0 to ZE0. If the deviation is within the threshold, the discharging parameters corresponding to the set appropriate resin supply quantities VA0 to VE0 are just maintained. On the other hand, when the deviation exceeds the threshold, the supply quantity is revised (ST435).

That is, the deviation between the measurement result in the light emission characteristic measuring step and the light emission characteristic prescribed beforehand is obtained, and as shown in FIG. 20(d), based on the obtained deviation, a process of deriving new appropriate resin supply quantities (VA2 to VE2) for practical production with which the resin 8 should be supplied onto the LED element 405 is performed by the supply quantity deriving processor 438 (supply quantity deriving step). In other words, by revising the appropriate resin supply quantities based on the measurement result in the light emission characteristic measurement step and the light emission characteristics prescribed beforehand, new appropriate resin supply quantities for practical production are derived.

The revised appropriate resin supply quantities (VA2 to VE2) are values updated by adding revision amounts respectively corresponding to the deviations to the set appropriate resin supply quantities VA0 to VE0. The relation of the deviations and the revision amounts is recorded in the resin supply information 419 as accompanied data known beforehand. Based on the revised appropriate resin supply quantities (VA2 to VE2), the processes of (ST432), (ST433), (ST434) and (ST435) are performed repeatedly. By recognizing that the deviation between the measurement result in (ST434) and the light emission characteristics prescribed beforehand is within the threshold, the appropriate resin supply quantities for practical production are determined. That is, in the above-mentioned resin supplying method, by repeatedly performing the supplying step for measurement, the light-passing member carrying step, the excitation light emitting step, the light emission characteristic measuring step and the supply quantity deriving step, the appropriate resin supply quantities are derived with certainty. The determined appropriate resin supply quantities are stored in the storage part 481 as the supply quantities 481b for practical production.

After this, the flow shifts to the next step to perform the discharging (ST436). By making the resin 408 of the predetermined quantity to be discharged from the print nozzle unit 432a, resin flow state in the resin discharge course is improved, and the movement of the print head 432 is stabilized. The processes of (S437), (ST438), (ST439) and (ST440) shown with a broken line frame in FIG. 61 are performed similarly to the processes shown in (ST432), (ST433), (ST434) and (ST435). The processes of (ST437), (ST438), (ST439) and (ST440) are performed when it is necessary to carefully recognize that a desired light emission characteristic is completely ensured, and are not necessarily items that must be performed.

In this way, if the appropriate resin supply quantity to give the desired light emission characteristic is determined, the supplying operation for production is performed (ST441). That is, when the production performing processor 437 orders the supply control part 436, which controls the print head 432, with the appropriate resin supply quantity that is derived by the supply quantity deriving processor 438 and is stored as the supply quantity 481b for practical production, the supplying process for production, which individually supplies the resin 408 of this appropriate resin quantity on the LED element 405 in a wafer state is performed (production performing step).

In the process of repeatedly performing the supplying process for production, the number of times the print head 432 supplies is counted, and it is monitored whether the number of times of supplying exceeds a predetermined number that is set beforehand (ST442). That is, until this predetermined number is reached, the changes of the characteristic of the resin 408 and the fluorescent substance density are judged to be small, and the supplying process for production (ST441) is repeated while the same supply quantity 481b for practical production is maintained. If it is recognized that the predetermined number is surpassed in (ST442), it is judged that there is a possibility that the character of the resin 408 or the fluorescent substance density changes, and the flow returns to (ST432). Then, the same measurement of the light emission characteristics and the supply quantity revising process based on the measurement result are performed repeatedly.

Next, returning to the flow of FIG. 58, the element holding member 420 on which the LED elements 405 are held is conveyed to the curing device M405, as shown in FIG. 53(a), the resin 408 is hardened by heating the LED elements 405 to which the resin 408 is supplied (ST408) (curing step). Thereby, the top surfaces of the LED elements 405 are covered with a resin film 408* formed when the resin 408 is hardened. In the curing step, instead of heating to harden the resin 408, a method of promoting the hardening by irradiating UV (ultraviolet rays), or a method of just placing the resin as it is to be naturally hardened may be used. Then, the element holding member 420 on which the light emitting elements 405* are held is conveyed to the sorting device M406 where the light emission characteristics of the light emitting elements 405* are detected, and as shown in FIG. 53(b), a sorting operation of separating the light emitting elements 405* into the element holding sheets 413A, 413B and the like based on the detection result is performed (ST410).

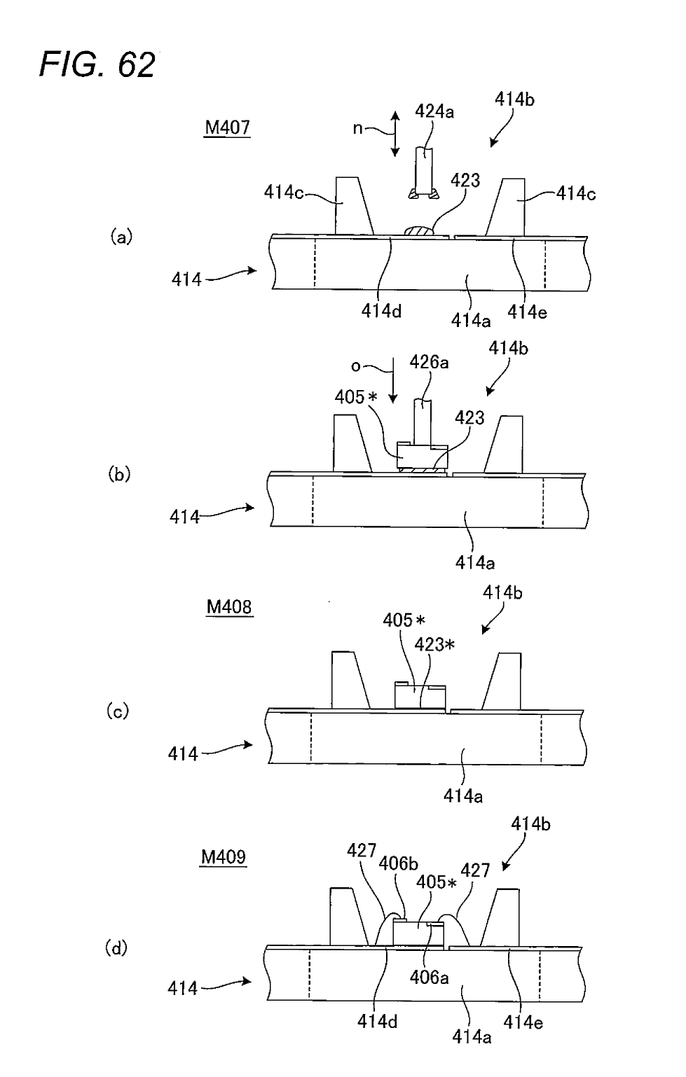

Then, the light emitting elements 405* manufactured in this way are mounted to the board 414 (ST411) (component mounting step). That is, the light emitting elements 405* separated depending on light emission characteristics are sent to the component mounting device M407 in a state of being attached onto the element holding sheets 413A, 413B and the like. After the resin adhesive 423 has been supplied to the element mounting position in the LED mounting part 414b by elevating the transferring pin 424a of the adhesive transferring mechanism 424 (arrow n), as shown in FIG. 62(a), the light emitting element 405* which is held in the mounting nozzle 426a of the component mounting mechanism 426 is dropped (arrow o) and mounted in the LED mounting part 414b of the board 414 through the resin adhesive 423, as shown in FIG. 62(b).

Then, the board 414 after the component mounting is sent to the curing device M408 where the board 14 is heated so that, as shown in FIG. 62(c), the resin adhesive 423 is thermally hardened and becomes the resin adhesive 423* and the light emitting element 405* is adhered to the individual board 414a. Then, the board 414 after the resin curing is sent to the wire bonding device M409, and the wiring layers 414e and 414d of the individual board 414a are connected to the N-type part electrode 406a and the P-type part electrode 406b of the light emitting element 405* with bonding wires 427, respectively, as shown in FIG. 62 (d).

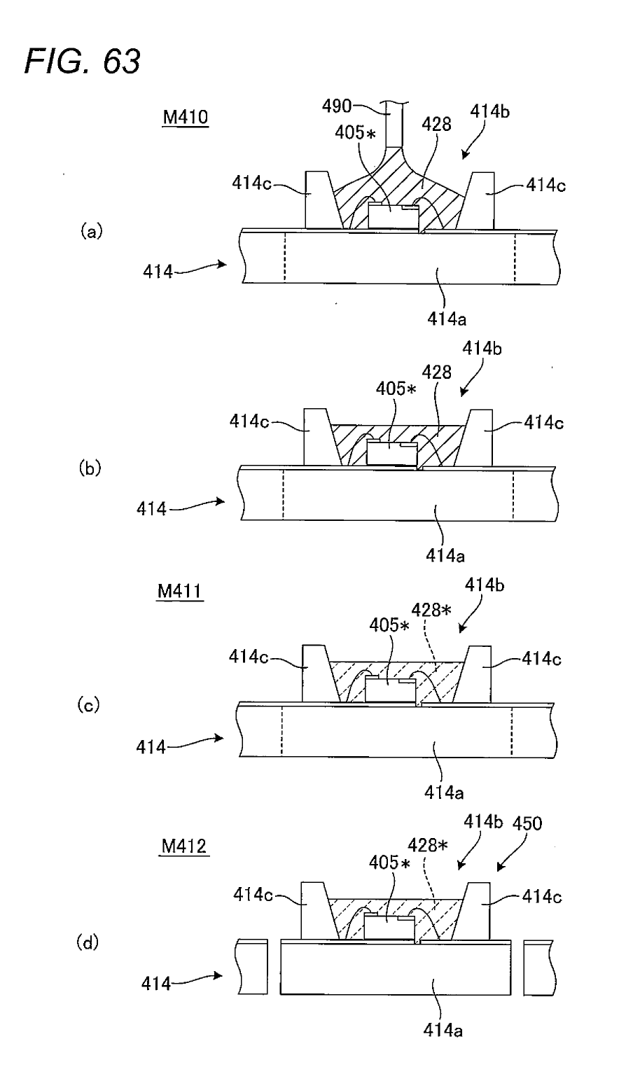

Then, the board 414 after the wire bonding is conveyed to the resin coating device M410, and the resin sealing operation is performed (ST412). That is, as shown in FIG. 63(a), inside the LED mounting part 414b surrounded by the reflective part 414c, the transparent resin 428 for sealing is discharged from a discharging nozzle 490 to cover the light emitting element 405*. When the resin supplying operation on one board 414 is finished in this way, the board 414 is sent to the curing device M411 and the resin 428 is hardened by heating the board 414. Thereby, as shown in FIG. 63(c), the resin 428 which is supplied to cover the light emitting element 405* is thermally hardened to become the solid resin 428*, and seals the light emitting element 405* which is in an adhered state in the LED mounting part 414b.

Then, the board 414 after the resin curing is sent to the piece-cutting device M412, and by cutting the board 414 for each of the individual boards 414a, as shown in FIG. 63 (d), the board 4 and the like are divided into individual light emitting element packages 450 (ST413). Thereby, the light emitting element package 450 in which the light emitting element 405*, which is made by covering the LED element 405 with the resin 408, is mounted on the individual board 414a is completed.

As described above, with the light emitting element manufacturing system 401 and the light emitting element package manufacturing system 501 shown in the present embodiment, in manufacturing light emitting elements 405* by coating the top surfaces of LED elements 405 with the resin 408 containing the fluorescent substance, in the resin supplying operation of discharging to supply the resin 408 onto the LED elements 405 which are taken out from the LED wafer 410 and rearranged with a predetermined array on the element holding surface 420a of the element holding member 420, the light emission characteristics of the light that the resin 408 emits when the excitation light from the light source part 445 is irradiated onto the light-passing member 443 on which the resin 408 is test supplied for light emission characteristic measurement are measured, and the appropriate resin supply quantity is revised based on the result of the measurement and the light emission characteristics prescribed beforehand to derive an appropriate resin supply quantity of the resin 408 which should be supplied to the LED elements for practical production. Therefore, even if the light emission wavelength of the individual LED element 405 varies, by equalizing the light emission characteristics of the light emitting element 405*, production yield can be improved.

Because the resin 408 is supplied onto the elements 405 which are taken out from the LED wafer 410 and rearranged with a predetermined array on the element holding surface 420a of the element holding member 420, the area of resin supply objects can be confined. Thereby, in comparison with a related method of supplying resin after having mounted to a board including a plurality of individual boards, the exclusive area of resin supplying devices can be decreased, and the area productivity of manufacturing devices can be improved. Furthermore, the LED elements 405 whose positions are fixed in the wafer state can be rearranged into a desirable array for resin supplying, and the resin supplying device M404 can perform the resin supplying operations more efficiently.

Although the present invention is described in detail with reference to the embodiments, it is apparent that various modifications and amendments may be made by those skilled in the art without departing from the spirit and scope of the invention.

This application is based on the Japanese patent applications (patent application No. 2011-202642, patent application No. 2011-202643 and patent application No. 2011-202644) filed on Sep. 16, 2011, whose contents are incorporated herein by reference.

### INDUSTRIAL APPLICABILITY

The light emitting element manufacturing systems and manufacturing methods and light emitting element package manufacturing systems and manufacturing methods, which manufacture light emitting element packages which are constructed by mounting light emitting elements on boards, of the invention have effects that even if the light emission wavelength of the individual LED element varies, production yield can be improved and the area productivity of manufacturing devices can be improved by equalizing light emission characteristics of light emitting element packages, and are applicable in manufacturing light emitting element packages of the construction that an LED element is covered with resin that contains fluorescent substance.

### EXPLANATIONS OF THE LETTERS OF NUMERALS

1 light emitting element manufacturing system
2 LAN system
5 LED element
5* light emitting element
8 resin
10 LED wafer
10a dicing sheet
12 element characteristic information
13A, 13B and 13C element holding sheet
14 board
14a individual board
14b LED mounting part
14c reflective part
18 map data
19 resin supply information
23 resin adhesive
24 adhesive transferring mechanism
25 component supplying mechanism
26 component mounting mechanism
28 resin
32 print head
32a print nozzle unit
40 and 140 test supplying and measuring unit
40a test supplying stage
41 and 141 light-passing member carrying part
42 spectroscope
43 light-passing member
44 integrating sphere
46 irradiating part
50 light emitting element package
101 light emitting element package manufacturing system
201 light emitting element manufacturing system
202 LAN system
205 LED element
205* light emitting element
208 resin
210 LED wafer
210a dicing sheet
212 element characteristic information
213A, 213B and 213C element holding sheet
214 board
214a individual board
214b LED mounting part
214c reflective part
218 map data
219 resin supply information
223 resin adhesive
224 adhesive transferring mechanism
225 component supplying mechanism
226 component mounting mechanism
228 resin
232 print head
232a print nozzle unit
240 and 340 test supplying and measuring unit
240a test supplying stage
241 and 341 light-passing member carrying part
242 spectroscope
243 light-passing member
244 integrating sphere
246 irradiating part
250 light emitting element package
301 light emitting element package manufacturing system
401 light emitting element manufacturing system
402 LAN system
405 LED element
405* light emitting element
408 resin
410 LED wafer
410a dicing sheet
412 element characteristic information
414 board
414a individual board
414b LED mounting part
414c reflective part
418 map data
419 resin supply information
420 element holding member
420a element holding surface
423 resin adhesive
424 adhesive transferring mechanism
425 component supplying mechanism
426 component mounting mechanism
428 resin
432 print head
432a print nozzle unit
440 and 540 test supplying and measuring unit
440a test supplying stage
441 and 541 light-passing member carrying part
442 spectroscope
443 light-passing member
444 integrating sphere
446 irradiating part
450 light emitting element package
501 light emitting element package manufacturing system
518 element array information

1. A light emitting element manufacturing system which manufactures light emitting elements by coating the top surfaces of LED elements with a resin containing a fluorescent substance, comprising
a dicing device which divides a LED wafer in which a plurality of the LED elements are elaborated and attached onto a dicing sheet into individual LED elements;
an element characteristic measuring part which individually measures the light emission characteristics of the individually divided LED elements in a state of being attached and held onto the dicing sheet to obtain element characteristic information indicating the light emission characteristics of the LED elements;
a map data making part which makes map data which associate element position information indicating the position in the LED wafer of the divided LED element with the element characteristic information on the LED element for each of the LED wafers;
a resin information supplying unit which supplies information that makes appropriate resin supply quantities of the resin to correspond to the element characteristic information to obtain LED elements which possess prescribed light emission characteristics as resin supply information;
a resin supplying device which supplies the resin of appropriate resin supply quantities to obtain prescribed light emission characteristics to the LED elements in a wafer state of being attached onto the dicing sheet, based on the map data and the resin supply information; and
a curing device which hardens the resin supplied to the LED elements; wherein the resin supplying device comprises a resin supplying part which discharges the resin in a variable supply quantity to supply to any supply object positions;
a supply control part which controls the resin supplying part to make a supplying process for measurement in which the resin is test supplied onto a light-passing member for light emission characteristic measurement, and a supplying process for production in which the resin is supplied onto the LED elements for practical production to be performed;
a light source part which emit excitation light to excite the fluorescent substance, a light-passing member carrying part on which a light-passing member on which the resin is test supplied in the supplying process for measurement is carried;
a light emission characteristic measuring part which measures the light emission characteristics of the light that the resin, which is supplied onto the light-passing member, emits when the excitation light emitted from the light source part is irradiated to the resin;
a supply quantity deriving processor which derives an appropriate resin supply quantity with which the resin should be supplied onto the LED elements for practical production by revising the appropriate resin supply quantity based on the measurement result of the light emission characteristic measuring part and light emission characteristics prescribed beforehand, and
a production performing processor which orders the supply control part with the derived appropriate resin supply quantity to make the supplying process for production in which the appropriate resin supply quantity of the resin is supplied on the LED elements to be performed.

2. The light emitting element manufacturing system according to claim 1, wherein the resin supplying part is a resin discharging device which discharges the resin in an ink-jet manner.

3. A light emitting element manufacturing method which manufactures light emitting elements by coating the top surfaces of LED elements with resin containing a fluorescent substance, comprising
a dicing step which divides a LED wafer in which a plurality of the LED elements are elaborated and attached onto a dicing sheet into individual LED elements;
an element characteristic measuring step which individually measures the light emission characteristics of the individually divided LED elements in a state of being attached and held onto the dicing sheet to obtain element characteristic information indicating the light emission characteristics of the LED elements;
a map data making step which makes map data which associate element position information indicating the position in the LED wafer of the divided LED element with the element characteristic information on the LED element for each of the LED wafers;
a resin information acquiring step which acquires information that makes appropriate resin supply quantities of the resin to correspond to the element characteristic information to obtain light emitting elements which possess prescribed light emission characteristics as resin supply information,
a resin supplying step which supplies the resin of appropriate resin supply quantities to obtain prescribed light emission characteristics to the LED elements in a wafer state of being attached onto the dicing sheet, based on the map data and the resin supply information; and
a curing step which hardens the resin supplied to the LED elements;
wherein the resin supplying step comprises a supplying step for measurement in which the resin is test supplied on a light-passing member for light emission characteristic measurement by a resin supplying part which discharges the resin in a variable supply quantity;
a light-passing member carrying step of carrying the light-passing member onto which the resin is test supplied on a light-passing member carrying part;
a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin;
a supply quantity deriving step which derives an appropriate resin supply quantity with which the resin should be supplied onto the LED elements for practical production by revising the appropriate resin supply quantity based on the measurement result of the light emission characteristic measuring step and light emission characteristics prescribed beforehand; and
a production performing step which orders a supply control part, which control the resin supplying part, with the derived appropriate resin supply quantity to make a supplying process for production in which the appropriate resin supply quantity of the resin is supplied on the LED elements to be performed.

4. The light emitting element manufacturing method according to claim 3, wherein in the resin supplying step, the resin is discharged in an ink-jet manner.

5. A light emitting element package manufacturing system which manufactures light emitting element packages which are constructed by mounting light emitting elements, which are made by coating the top surfaces of LED elements with resin containing a fluorescent substance beforehand, on boards, comprising
a dicing device which divides a LED wafer in which a plurality of the LED elements are elaborated and attached onto a dicing sheet into individual LED elements;
an element characteristic measuring part which individually measures the light emission characteristics of the individually divided LED elements in a state of being attached and held onto the dicing sheet to obtain element characteristic information indicating the light emission characteristics of the LED elements;
a map data making part which makes map data which associate element position information indicating the position in the LED wafer of the divided LED element with the element characteristic information on the LED element for each of the LED wafers, a resin information supplying unit which supplies information that makes appropriate resin supply quantities of the resin to correspond to the element characteristic information to obtain LED elements which possess prescribed light emission characteristics as resin supply information;
a resin supplying device which supplies the resin of appropriate resin supply quantities to obtain prescribed light emission characteristics to the LED elements in a wafer state of being attached onto the dicing sheet, based on the map data and the resin supply information;
a curing device which makes the light emitting elements to be finished by hardening the resin supplied to the LED elements; and
a component mounting device which mounts the light emitting elements on boards;
wherein the resin supplying device comprises a resin supplying part which discharges the resin in a variable supply quantity to supply to any supply object positions,
a supply control part which controls the resin supplying part to make a supplying process for measurement in which the resin is test supplied onto a light-passing member for light emission characteristic measurement, and a supplying process for production in which the resin is supplied onto the LED elements for practical production to be performed,
a light source part which emit excitation light to excite the fluorescent substance, a light-passing member carrying part on which a light-passing member on which the resin is test supplied in the supplying process for measurement is carried,
a light emission characteristic measuring part which measures the light emission characteristics of the light that the resin, which is supplied onto the light-passing member, emits when the excitation light emitted from the light source part is irradiated to the resin,
a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and
a production performing processor which orders the supply control part with the derived appropriate resin supply quantity to make the supplying process for production in which the appropriate resin supply quantity of the resin is supplied on the LED elements to be performed.

6. A light emitting element package manufacturing method which manufactures light emitting element packages which are constructed by mounting light emitting elements, which are made by coating the top surfaces of LED elements with resin containing a fluorescent substance beforehand, on boards, comprising:
a dicing step which divides a LED wafer in which a plurality of the LED elements are elaborated and attached onto a dicing sheet into individual LED elements;
an element characteristic measuring step which individually measures the light emission characteristics of the individually divided LED elements in a state of being attached and held onto the dicing sheet to obtain element characteristic information indicating the light emission characteristics of the LED elements;
a map data making step which makes map data which associate element position information indicating the position in the LED wafer of the divided LED element with the element characteristic information on the LED element for each of the LED wafers;
a resin information acquiring step which acquires information that makes appropriate resin supply quantities of the resin to correspond to the element characteristic information to obtain light emitting elements which possess prescribed light emission characteristics as resin supply information,
a resin supplying step which supplies the resin of appropriate resin supply quantities to obtain prescribed light emission characteristics to the LED elements in a wafer state of being attached onto the dicing sheet, based on the resin supply information and the map data; and
a curing step which hardens the resin supplied to the LED elements and a component mounting step which mounts the light emitting elements on boards;
wherein the resin supplying step comprises a supplying step for measurement in which the resin is test supplied on a light-passing member for light emission characteristic measurement by a resin supplying part which discharges the resin in a variable supply quantity,
a light-passing member carrying step of carrying the light-passing member onto which the resin is test supplied on a light-passing member carrying part,
a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin,
a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and
a production performing step which orders a supply control part, which control the resin supplying part, with the derived appropriate resin supply quantity to make a supplying process for production in which the appropriate resin supply quantity of the resin is supplied on the LED elements to be performed.

7. A light emitting element manufacturing system which manufactures light emitting elements by coating the top surfaces of LED elements with resin containing a fluorescent substance, comprising:
a half cutting device which divides only semiconductor layers constructing the LED elements in an LED wafer in which a plurality of the LED elements are elaborated and attached onto a dicing sheet into individual LED element pieces;
an element characteristic measuring part which individually measures the light emission characteristics of the individually divided LED elements in a half cut state that only the semiconductor layers are divided into individual pieces to obtain element characteristic information indicating the light emission characteristics of the LED elements,
a map data making part which makes map data which associate element position information indicating the position in the LED wafer of the half cut LED element with the element characteristic information on the LED element for each of the LED wafers;
a resin information supplying unit which supplies information that makes appropriate resin supply quantities of the resin to correspond to the element characteristic information to obtain LED elements which possess prescribed light emission characteristics as resin supply information;
a resin supplying device which supplies the resin of appropriate resin supply quantities to obtain prescribed light emission characteristics to the LED elements in a half cut state, based on the map data and the resin supply information;
a curing device which hardens the resin supplied to the LED elements; and
a dicing device which divides the LED wafer after the resin is hardened into individual LED elements;
wherein the resin supplying device comprises a resin supplying part which discharges the resin in a variable supply quantity to supply to any supply object positions,
a supply control part which controls the resin supplying part to make a supplying process for measurement in which the resin is test supplied onto a light-passing member for light emission characteristic measurement, and a supplying process for production in which the resin is supplied onto the LED elements for practical production to be performed,
a light source part which emit excitation light to excite the fluorescent substance, a light-passing member carrying part on which a light-passing member on which the resin is test supplied in the supplying process for measurement is carried,
a light emission characteristic measuring part which measures the light emission characteristics of the light that the resin, which is supplied onto the light-passing member, emits when the excitation light emitted from the light source part is irradiated to the resin,
a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and
a production performing processor which orders the supply control part with the derived appropriate resin supply quantity to make the supplying process for production in which the appropriate resin supply quantity of the resin is supplied on the LED elements to be performed.

8. The light emitting element manufacturing system according to claim 7, wherein the resin supplying part is a resin discharging device which discharges the resin in an ink-jet manner.

9. A light emitting element manufacturing method which manufactures light emitting elements by coating the top surfaces of LED elements with resin containing a fluorescent substance, comprising:
a half cutting step which divides only semiconductor layers constructing the LED elements in an LED wafer in which a plurality of the LED elements are elaborated and attached onto a dicing sheet into individual LED element pieces;
an element characteristic measuring step which individually measures the light emission characteristics of the individually divided LED elements in a half cut state that only the semiconductor layers are divided into individual pieces to obtain element characteristic information indicating the light emission characteristics of the LED elements,
a map data making step which makes map data which associate element position information indicating the position in the LED wafer of the half cut LED element with the element characteristic information on the LED element for each of the LED wafers;
a resin information acquiring step which acquires information that makes appropriate resin supply quantities of the resin to correspond to the element characteristic information to obtain light emitting elements which possess prescribed light emission characteristics as resin supply information,
a resin supplying step which supplies the resin of appropriate resin supply quantities to obtain prescribed light emission characteristics to the LED elements in a half cut state, based on the resin supply information and the map data;
a curing step which hardens the resin supplied to the LED elements; and
a dicing step which divides the LED wafer after the resin is hardened into individual LED elements;
wherein the resin supplying step comprises a supplying step for measurement in which the resin is test supplied on a light-passing member for light emission characteristic measurement by a resin supplying part which discharges the resin in a variable supply quantity,
a light-passing member carrying step of carrying the light-passing member onto which the resin is test supplied on a light-passing member carrying part,
a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin,
a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and
a production performing step which orders a supply control part, which control the resin supplying part, with the derived appropriate resin supply quantity to make a supplying process for production in which the appropriate resin supply quantity of the resin is supplied on the LED elements to be performed.

10. The light emitting element manufacturing method according to claim 9, wherein in the resin supplying step, the resin is discharged in an ink-jet manner.

11. A light emitting element package manufacturing system which manufactures light emitting element packages which are constructed by mounting light emitting elements, which are made by coating the top surfaces of LED elements with resin containing a fluorescent substance beforehand, on boards, comprising:
a half cutting device which divides only semiconductor layers constructing the LED elements in an LED wafer in which a plurality of the LED elements are elaborated and attached onto a dicing sheet into individual LED element pieces;
an element characteristic measuring part which individually measures the light emission characteristics of the individually divided LED elements in a half cut state that only semiconductor layers are divided into individual pieces to obtain element characteristic information indicating the light emission characteristics of the LED elements;
a map data making part which makes map data which associate element position information indicating the position in the LED wafer of the half cut LED element with the element characteristic information on the LED element for each of the LED wafers;
a resin information supplying unit which supplies information that makes appropriate resin supply quantities of the resin to correspond to the element characteristic information to obtain LED elements which possess prescribed light emission characteristics as resin supply information;
a resin supplying device which supplies the resin of appropriate resin supply quantities to obtain prescribed light emission characteristics to the LED elements in a half cut state, based on the map data and the resin supply information;
a curing device which hardens the resin supplied to the LED elements;
a dicing device which divides the LED wafer after the resin is hardened into individual light emitting elements; and
a component mounting device which mounts the individual light emitting elements on boards;
wherein the resin supplying device comprises a resin supplying part which discharges the resin in a variable supply quantity to supply to any supply object positions,
a supply control part which controls the resin supplying part to make a supplying process for measurement in which the resin is test supplied onto a light-passing member for light emission characteristic measurement, and a supplying process for production in which the resin is supplied onto the LED elements for practical production to be performed,
a light source part which emit excitation light to excite the fluorescent substance, a light-passing member carrying part on which a light-passing member on which the resin is test supplied in the supplying process for measurement is carried,
a light emission characteristic measuring part which measures the light emission characteristics of the light that the resin, which is supplied onto the light-passing member, emits when the excitation light emitted from the light source part is irradiated to the resin,
a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and
a production performing processor which orders the supply control part with the derived appropriate resin supply quantity to make the supplying process for production in which the appropriate resin supply quantity of the resin is supplied on the LED elements to be performed.

12. A light emitting element package manufacturing method which manufactures light emitting element packages which are constructed by mounting light emitting elements, which are made by coating the top surfaces of LED elements with resin containing a fluorescent substance beforehand, on boards, comprising
a half cutting step which divides only semiconductor layers constructing the LED elements in an LED wafer in which a plurality of the LED elements are elaborated and attached onto a dicing sheet into individual LED element pieces;
an element characteristic measuring step which individually measures the light emission characteristics of the individually divided LED elements in a half cut state that only the semiconductor layers are divided into individual pieces to obtain element characteristic information indicating the light emission characteristics of the LED elements;
a map data making step which makes map data which associate element position information indicating the position in the LED wafer of the half cut LED element with the element characteristic information on the LED element for each of the LED wafers;
a resin information acquiring step which acquires information that makes appropriate resin supply quantities of the resin to correspond to the element characteristic information to obtain light emitting elements which possess prescribed light emission characteristics as resin supply information,
a resin supplying step which supplies the resin of appropriate resin supply quantities to obtain prescribed light emission characteristics to the LED elements in a half cut state, based on the resin supply information and the map data;
a curing step which hardens the resin supplied to the LED elements,
a dicing step which divides the LED wafer after the resin is hardened into individual light emitting elements; and
a component mounting step which mounts the individual light emitting elements on boards;
wherein the resin supplying step comprises a supplying step for measurement in which the resin is test supplied on a light-passing member for light emission characteristic measurement by a resin supplying part which discharges the resin in a variable supply quantity,
a light-passing member carrying step of carrying the light-passing member onto which the resin is test supplied on a light-passing member carrying part,
a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin,
a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and
a production performing step which orders a supply control part, which control the resin supplying part, with the derived appropriate resin supply quantity to make a supplying process for production in which the appropriate resin supply quantity of the resin is supplied on the LED elements to be performed.

13. A light emitting element manufacturing system which manufactures light emitting elements by coating the top surfaces of LED elements with resin containing a fluorescent substance, comprising:
a dicing device which divides a LED wafer in which a plurality of the LED elements are elaborated and attached onto a dicing sheet into individual LED elements;
an element characteristic measuring part which individually measures the light emission characteristics of the individually divided LED elements in a state of being attached and held onto the dicing sheet to obtain element characteristic information indicating the light emission characteristics of the LED elements;
a map data making part which makes map data which associate element position information indicating the position in the LED wafer of the divided LED element with the element characteristic information on the LED element for each of the LED wafers;
an element rearranging part which rearranges the LED elements with a predetermined array based on the map data onto an element holding surface,
a resin information supplying unit which supplies information that makes appropriate resin supply quantities of the resin to correspond to the element characteristic information to obtain LED elements which possess prescribed light emission characteristics as resin supply information;
a resin supplying device which supplies the resin of appropriate resin supply quantities to obtain prescribed light emission characteristics to the LED elements held on the element holding surface, based on element array information indicating the array of the LED elements rearranged by the element rearranging part and the resin supply information; and
a curing device which hardens the resin supplied to the LED elements;
wherein the resin supplying device comprises a resin supplying part which discharges the resin in a variable supply quantity to supply to any supply object positions,
a supply control part which controls the resin supplying part to make a supplying process for measurement in which the resin is test supplied onto a light-passing member for light emission characteristic measurement, and a supplying process for production in which the resin is supplied onto the LED elements for practical production to be performed, a light source part which emit excitation light to excite the fluorescent substance, a light-passing member carrying part on which a light-passing member on which the resin is test supplied in the supplying process for measurement is carried,
a light emission characteristic measuring part which measures the light emission characteristics of the light that the resin, which is supplied onto the light-passing member, emits when the excitation light emitted from the light source part is irradiated to the resin,
a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and
a production performing processor which orders the supply control part with the derived appropriate resin supply quantity to make the supplying process for production in which the appropriate resin supply quantity of the resin is supplied on the LED elements to be performed.

14. The light emitting element manufacturing system according to claim 13, wherein the resin supplying part is a resin discharging device which discharges the resin in an ink-jet manner.

15. A light emitting element manufacturing method which manufactures light emitting elements by coating the top surfaces of LED elements with resin containing a fluorescent substance, comprising:
a dicing step which divides a LED wafer in which a plurality of the LED elements are elaborated and attached onto a dicing sheet into individual LED elements;
an element characteristic measuring step which individually measures the light emission characteristics of the individually divided LED elements in a state of being attached and held onto the dicing sheet to obtain element characteristic information indicating the light emission characteristics of the LED elements;
a map data making step which makes map data which associate element position information indicating the position in the LED wafer of the divided LED element with the element characteristic information on the LED element for each of the LED wafers, an element rearranging step which rearranges the LED elements with a predetermined array based on the map data onto an element holding surface;
a resin information acquiring step which acquires information that makes appropriate resin supply quantities of the resin to correspond to the element characteristic information to obtain LED elements which possess prescribed light emission characteristics as resin supply information;
a resin supplying step which supplies the resin of appropriate resin supply quantities to obtain prescribed light emission characteristics to the LED elements held on the element holding surface, based on element array information indicating the array of the LED elements rearranged by the element rearranging step and the resin supply information; and
a curing step which hardens the resin supplied to the LED elements;
wherein the resin supplying step comprises a supplying step for measurement in which the resin is test supplied on a light-passing member for light emission characteristic measurement by a resin supplying part which discharges the resin in a variable supply quantity,
a light-passing member carrying step of carrying the light-passing member onto which the resin is test supplied on a light-passing member carrying part,
a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin,
a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and
a production performing step which orders a supply control part, which control the resin supplying part, with the derived appropriate resin supply quantity to make a supplying process for production in which the appropriate resin supply quantity of the resin is supplied on the LED elements to be performed.

16. The light emitting element manufacturing method according to claim 15, wherein in the resin supplying step, the resin is discharged in an ink-jet manner.

17. A light emitting element package manufacturing system which manufactures light emitting element packages which are constructed by mounting light emitting elements, which are made by coating the top surfaces of LED elements with resin containing a fluorescent substance beforehand, on boards, comprising
a dicing device which divides a LED wafer in which a plurality of the LED elements are elaborated and attached onto a dicing sheet into individual LED elements;
an element characteristic measuring part which individually measures the light emission characteristics of the individually divided LED elements in a state of being attached and held onto the dicing sheet to obtain element characteristic information indicating the light emission characteristics of the LED elements;
a map data making part which makes map data which associate element position information indicating the position in the LED wafer of the divided LED element with the element characteristic information on the LED element for each of the LED wafers;
an element rearranging part which rearranges the LED elements with a predetermined array based on the map data onto an element holding surface,
a resin information supplying unit which supplies information that makes appropriate resin supply quantities of the resin to correspond to the element characteristic information to obtain LED elements which possess prescribed light emission characteristics as resin supply information;
a resin supplying device which supplies the resin of appropriate resin supply quantities to obtain prescribed light emission characteristics to the LED elements held on the element holding surface, based on element array information indicating the array of the LED elements rearranged by the element rearranging part and the resin supply information;
a curing device which makes the light emitting elements to be finished by hardening the resin supplied to the LED elements; and
a component mounting device which mounts the light emitting elements on boards,
wherein the resin supplying device comprises a resin supplying part which discharges the resin in a variable supply quantity to supply to any supply object positions,
a supply control part which controls the resin supplying part to make a supplying process for measurement in which the resin is test supplied onto a light-passing member for light emission characteristic measurement, and a supplying process for production in which the resin is supplied onto the LED elements for practical production to be performed,
a light source part which emit excitation light to excite the fluorescent substance, a light-passing member carrying part on which a light-passing member on which the resin is test supplied in the supplying process for measurement is carried,
a light emission characteristic measuring part which measures the light emission characteristics of the light that the resin, which is supplied onto the light-passing member, emits when the excitation light emitted from the light source part is irradiated to the resin,
a supply quantity deriving processor which derives an appropriate resin supply quantity for practical production with which the resin should be supplied onto the LED elements by revising the appropriate resin supply quantity based on the measurement result of the light emission characteristic measuring part and light emission characteristics prescribed beforehand, and
a production performing processor which orders the supply control part with the derived appropriate resin supply quantity to make the supplying process for production in which the appropriate resin supply quantity of the resin is supplied on the LED elements to be performed.

18. A light emitting element package manufacturing method which manufactures light emitting element packages which are constructed by mounting light emitting elements, which are made by coating the top surfaces of LED elements with resin containing a fluorescent substance beforehand, on boards, comprising:
a dicing step which divides a LED wafer in which a plurality of the LED elements are elaborated and attached onto a dicing sheet into individual LED elements;
an element characteristic measuring step which individually measures the light emission characteristics of the individually divided LED elements in a state of being attached and held onto the dicing sheet to obtain element characteristic information indicating the light emission characteristics of the LED elements;
a map data making step which makes map data which associate element position information indicating the position in the LED wafer of the divided LED element with the element characteristic information on the LED element for each of the LED wafers;
an element rearranging step which rearranges the LED elements with a predetermined array based on the map data onto an element holding surface;
a resin information acquiring step which acquires information that makes appropriate resin supply quantities of the resin to correspond to the element characteristic information to obtain LED elements which possess prescribed light emission characteristics as resin supply information;
a resin supplying step which supplies the resin of appropriate resin supply quantities to obtain prescribed light emission characteristics to the LED elements held on the element holding surface, based on element array information indicating the array of the LED elements rearranged by the element rearranging step and the resin supply information;
a curing step which hardens the resin supplied to the LED elements; and
a component mounting step which mounts the light emitting elements on boards;
wherein the resin supplying step comprises a supplying step for measurement in which the resin is test supplied on a light-passing member for light emission characteristic measurement by a resin supplying part which discharges the resin in a variable supply quantity;
a light-passing member carrying step of carrying the light-passing member onto which the resin is test supplied on a light-passing member carrying part;
a light emission characteristic measuring step which measures the light emission characteristics of the light that the resin, which is supplied onto the light-passing member, emits when excitation light emitted from a light source part, which emits the excitation light to excite the fluorescent substance, is irradiated to the resin,
a supply quantity deriving step which derives an appropriate resin supply quantity for practical production with which the resin should be supplied onto the LED elements by revising the appropriate resin supply quantity based on the measurement result of the light emission characteristic measuring step and light emission characteristics prescribed beforehand, and
a production performing step which orders a supply control part, which control the resin supplying part, with the derived appropriate resin supply quantity to make a supplying process for production in which the appropriate resin supply quantity of the resin is supplied on the LED elements to be performed.
